(19) United States
(12) Patent Application Publication
(10) Pub. No.: US 2020/0183280 A1
(43) Pub. Date: Jun. 11, 2020

(54) ACTINIC RAY-SENSITIVE OR RADIATION-SENSITIVE RESIN COMPOSITION, RESIST FILM, PATTERN FORMING METHOD, METHOD FOR MANUFACTURING ELECTRONIC DEVICE

(71) Applicant: FUJIFILM Corporation, Tokyo (JP)

(72) Inventors: Michihiro OGAWA, Shizuoka (JP); Akihiro KANEKO, Shizuoka (JP); Takashi KAWASHIMA, Shizuoka (JP); Tomotaka TSUCHIMURA, Shizuoka (JP)

(73) Assignee: FUJIFILM Corporation, Tokyo (JP)

(21) Appl. No.: 16/794,442

(22) Filed: Feb. 19, 2020

Related U.S. Application Data
(63) Continuation of application No. PCT/JP2018/026910, filed on Jul. 18, 2018.

(30) Foreign Application Priority Data
Aug. 31, 2017 (JP) 2017-167780

(51) Int. Cl. G03F 7/039; G03F 7/004; G03F 7/038; C08L 33/06; C08L 33/16

(52) U.S. Cl. CPC G03F 7/0392; G03F 7/0045; C08L 33/16; C08L 33/066; G03F 7/0382

(57) ABSTRACT

An actinic ray-sensitive or radiation-sensitive resin composition is an actinic ray-sensitive or radiation-sensitive resin composition including a compound that generates an acid upon irradiation with actinic rays or radiation and a resin capable of increasing polarity by the action of an acid, in which the resin includes a repeating unit represented by General Formula (B-1) and at least one halogen atom selected from the group consisting of a fluorine atom and an iodine atom.

### CROSS-REFERENCE TO RELATED APPLICATIONS

This application is a Continuation of PCT International Application No. PCT/JP2018/026910 filed on Jul. 18, 2018, which claims priority under 35 U.S.C § 119(a) to Japanese Patent Application No. 2017-167780 filed on Aug. 31, 2017. Each of the above application(s) is hereby expressly incorporated by reference, in its entirety, into the present application.

### BACKGROUND OF THE INVENTION

### 1. Field of the Invention

The present invention relates to an actinic ray-sensitive or radiation-sensitive resin composition, a resist film, a pattern forming method, and a method for manufacturing an electronic device.

### 2. DESCRIPTION OF THE RELATED ART

In processes for manufacturing semiconductor devices such as an integrated circuit (IC) and a large scale integrated circuit (LSI) in the related art, microfabrication by lithography using a photoresist composition (hereinafter also referred to as an “actinic ray-sensitive or radiation-sensitive resin composition”) has been performed. In recent years, formation of an ultrafine pattern in a submicron region or a quarter-micron region has been demanded in accordance with realization of a high degree of integration for integrated circuits. With such a demand, a tendency that an exposure wavelength has been shifted from g-rays to i-rays, and further, as with KrF excimer laser light, the exposure wavelength becomes shorter is observed. Moreover, developments in lithography with electron beams, X-rays, or extreme ultraviolet rays (EUV), in addition to the excimer laser light, have also been currently proceeding.

For example, JP2007-094139A discloses a positive-tone resist composition which can be applied to EUV exposure and the like as an actinic ray-sensitive or radiation-sensitive resin composition.

### SUMMARY OF THE INVENTION

EUV light (wavelength: 13.5 nm) has a short wavelength, as compared with, for example, ArF excimer laser light (wavelength: 193 nm), and therefore, it may have a small number of incident photons with the same sensitivity upon exposure of a resist film. As a result, in lithography with EUV light, an effect of a “photon shot noise” that the number of photons becomes uneven stochastically is significant, which has become a major cause of deterioration in line edge roughness (LER).

In order to reduce the photon shot noise, it is effective to increase an exposure dose (in other words, lower the sensitivity) to increase the number of incident photons, which is, however, a trade-off with a recent demand for a higher sensitivity. In addition, it is effective to increase the film thickness of the resist film to increase the number of absorbed photons, but the aspect ratio of a pattern thus formed is increased, and accordingly, deterioration in collapse suppressing capability is likely to occur in a line/space (L/S) pattern.

Under the background, there is a demand for an actinic ray-sensitive or radiation-sensitive resin composition which has high sensitivity and can form a pattern having excellent LER and collapse suppressing capability in lithography with EUV light.

In recently years, the present inventors have discovered that by a method of introducing many elements having an EUV light absorbing efficiency, such as a fluorine atom and an iodine atom, into a resist film, the EUV light absorption efficiency is improved even in a case where the film thickness of the resist film is low. On the other hand, they have also confirmed that in a case where many fluorine atoms are included in a resin, collapse suppressing capability of a pattern thus formed is easily deteriorated.

Therefore, an object of the present invention is to provide an actinic ray-sensitive or radiation-sensitive resin composition which has high sensitivity and can form a pattern having excellent LER and collapse suppressing capability.

In addition, another object of the present invention is to provide a resist film, a pattern forming method, and a method for manufacturing an electronic device, each using the actinic ray-sensitive or radiation-sensitive resin composition.

The present inventors have conducted extensive studies in order to achieve the objects, and as a result, they have found that the objects can be achieved by incorporating a resin including a repeating unit represented by General Formula (B-1) which will be described later and at least one halogen atom selected from the group consisting of a fluorine atom and an iodine atom into an actinic ray-sensitive or radiation-sensitive resin composition, thereby completing the present invention.

That is, the present inventors have found that the objects can be achieved by the following configurations.

[1] An actinic my-sensitive or radiation-sensitive resin composition comprising:

a compound that generates an acid upon irradiation with actinic rays or radiation, and

a resin capable of increasing polarity by the action of an acid,

in which the resin includes:

a repeating unit represented by General Formula (B-1) which will be described later, and

at least one halogen atom selected from the group consisting of a fluorine atom and an iodine atom.

[2] The actinic my-sensitive or radiation-sensitive resin composition as described in [1],

in which the halogen atom is included in the repeating unit represented by General Formula (B-1).

[3] The actinic ray-sensitive or radiation-sensitive resin composition as described in [1] or [2],

in which the repeating unit represented by General Formula (B-1) is a repeating unit represented by General Formula (B-2) which will be described later.

[4] The actinic my-sensitive or radiation-sensitive resin composition as described in [3],

in which a content of the halogen atom in the repeating unit represented by General Formula (B-2) is 10% by mass or more.

[5] The actinic ray-sensitive or radiation-sensitive resin composition as described in ([3] or [4],

in which the repeating unit represented by General Formula (B-2) is at least one repeating unit selected from the group consisting of the following repeating unit (A), the following repeating unit (B), and the following repeating unit (C),

Repeating unit (A): Repeating unit represented by General Formula (B-2), in which Rc represents a group including a lactone structure,

Repeating unit (B): Repeating unit represented by General Formula (B-2), in which Rc represents a group that decomposes by the action of an acid to leave, and

Repeating unit (C): Repeating unit represented by General Formula (B-2), in which Rd represents an acid group.

[6] The actinic ray-sensitive or radiation-sensitive resin composition as described in [5],

in which the resin includes at least two or more repeating units selected from the group consisting of the repeating unit (A), the repeating unit (B), and the repeating unit (C) as the repeating unit represented by General Formula (B-2).

[7] The actinic ray-sensitive or radiation-sensitive resin composition as described in any one of [1] to [6],

in which a weight-average molecular weight of the resin is 2,500 to 30,000.

[8]A resist film formed with the actinic ray-sensitive or radiation-sensitive resin composition as described in any one of [1] to [7].

[9] A pattern forming method comprising:

a resist film forming step of forming a resist film with the actinic ray-sensitive or radiation-sensitive resin composition as described in any one of [1] to [7];

an exposing step of exposing the resist film; and

a developing step of developing the exposed resist film with a developer.

[10] A method for manufacturing an electronic device, the method comprising the pattern forming method as described in [9].

According to the present invention, it is possible to provide an actinic ray-sensitive or radiation-sensitive resin composition which has high sensitivity and can form a pattern having excellent LER and collapse suppressing capability.

In addition, according to the present invention, it is possible to provide a resist film, a pattern forming method, and a method for manufacturing an electronic device, each using the actinic ray-sensitive or radiation-sensitive resin composition.

### DESCRIPTION OF THE PREFERRED EMBODIMENTS

Hereinafter, the present invention will be described in detail.

Description of configuration requirements described below may be made on the basis of representative embodiments of the present invention in some cases, but the present invention is not limited to such embodiments.

“Actinic rays” or “radiation” in the present specification means, for example, a bright line spectrum of a mercury lamp, far ultraviolet rays typified by an excimer laser, extreme ultraviolet rays (EUV rays), X-rays, electron beams (EB), or the like. “Light” in the present specification means actinic rays or radiation.

“Exposure” in the present specification encompasses, unless otherwise specified, not only exposure by a bright line spectrum of a mercury lamp, far ultraviolet rays typified by an excimer laser, extreme ultraviolet rays, X-rays, EUV rays, or the like, but also writing by particle rays such as electron beams and ion beams.

In the present specification, a numerical range expressed using “to” is used in a meaning of a range that includes the preceding and succeeding numerical values of “to” as the lower limit value and the upper limit value, respectively.

In the present specification, “(meth)acrylate” represents acrylate and methacrylate, and (meth)acrylic acid represents acrylic acid and methacrylic acid.

In citations for a group (atomic group) in the present specification, in a case where the group is cited without specifying whether it is substituted or unsubstituted, the group includes both a group having no substituent and a group having a substituent. For example, an “alkyl group” includes not only an alkyl group having no substituent (unsubstituted alkyl group), but also an alkyl group having a substituent (substituted alkyl group). In addition, an “organic group” in the present specification refers to a group including at least one carbon atom.

Furthermore, in the present specification, in a case of referring to an expression, “a substituent may be contained”, the types of substituents, the positions of the substituents, and the number of the substituents are not particularly limited. The number of the substituents may be, for example, one, two, three, or more. Examples of the substituent include a monovalent non-metal atomic group except for a hydrogen atom, and the substituent can be selected from, for example, the following substituent group T.

(Substituent T)

Examples of the substituent T include halogen atoms such as a fluorine atom, a chlorine atom, a bromine atom, and an iodine atom; alkoxy groups such as a methoxy group, an ethoxy group, and a tert-butoxy group; aryloxy groups such as a phenoxy group and a p-tolyloxy group; alkoxycarbonyl groups such as a methoxycarbonyl group, a butoxycarbonyl group, and a phenoxycarbonyl group; acyloxy groups such as an acetoxy group, a propionyloxy group, and a benzoyloxy group; acyl groups such as an acetyl group, a benzoyl group, an isobutyryl group, an acryloyl group, a methacryloyl group, and a methoxalyl group; alkylsulfanyl groups such as a methylsulfanyl group and a tert-butylsulfanyl group; arylsulfanyl groups such as a phenylsulfanyl group and a p-tolylsulfanyl group; an alkyl group; a cycloalkyl group; an aryl group; a heteroaryl group; a hydroxyl group; a carboxy group; a formyl group; a sulfo group; a cyano group; an alkylaminocarbonyl group; an arylaminocarbonyl group; a sulfonamido group; a silyl group; an amino group; a monoalkylamino group; a dialkylamino group; an arylamino group; and a combination thereof.

Actinic Ray-Sensitive or Radiation-Sensitive Resin Composition

The actinic my-sensitive or radiation-sensitive resin composition of the embodiment of the present invention (hereinafter also referred to as “the composition of the embodiment of the present invention”) may include a resin including a repeating unit represented by General Formula (B-1) which will be described later and at least one halogen atom selected from the group consisting of a fluorine atom and an iodine atom.

The present inventors have discovered that in a case where many fluorine atoms are included in the resin, the glass transition temperature (Tg) of the resin is lowered, which causes the collapse suppressing capability of a pattern thus formed to be easily deteriorated.

In contrast, by incorporating the repeating unit represented by General Formula (B-1) into the resin included in the composition of the embodiment of the present invention, the glass transition temperature (Tg) is high, which also makes the collapse suppressing capability excellent. In addition, by incorporating at least one halogen atom selected from the group consisting of a fluorine atom and an iodine atom into the resin, the EUV light absorption efficiency of a resist film (a coating film of the actinic ray-sensitive or radiation-sensitive resin composition) is improved. That is, the resist film has an excellent sensitivity, and the LER of a pattern formed by exposure and development is excellent.

By the action mechanism, the composition of the embodiment of the present invention which has a high sensitivity and can form a pattern having excellent LER and collapse suppressing capability.

Hereinafter, the components included in the composition of the embodiment of the present invention will be described in details. Incidentally, the composition of the embodiment of the present invention is a so-called resist composition, and may be either a positive-tone resist composition or a negative-tone resist composition. In addition, the composition may be either a resist composition for alkali development or a resist composition for organic solvent development. Among those, the positive-tone resist composition, which is a resist composition for alkali development, is preferable.

The composition of the embodiment of the present invention is typically a chemically amplified resist composition.

<Resin>

(Resin (X))

The composition of the embodiment of the present invention includes a resin capable of increasing polarity by the action of an acid (hereinafter also referred to as a “resin (X)”), which satisfies the following conditions [1] and [2].

Condition [1]: Including a repeating unit represented by General Formula (B-1) which will be described later.

Condition [2]: Including at least one halogen atom selected from the group consisting of a fluorine atom and an iodine atom.

Moreover, the resin (X) is a resin capable of increasing polarity by the action of an acid as described above. Accordingly, in the pattern forming method of an embodiment of the present invention which will be described later, typically in a case where an alkali developer is adopted as the developer, a positive-tone pattern is suitably formed, and in a case where an organic developer is adopted as the developer, a negative-tone pattern is suitably formed.

Moreover, the resin (X) includes at least one halogen atom selected from the group consisting of a fluorine atom and an iodine atom (hereinafter also referred to as a “specific halogen atom”) (Condition [2]). A position in the resin (X) to which a specific halogen atom is introduced is not particularly limited, but above all, it is preferable that the specific halogen atom is included in the repeating unit represented by General Formula (B-1).

The content of the specific halogen atoms in the resin (X) is not particularly limited, but is preferably 2% by mass or more with respect to the total mass of the resin. In addition, an upper limit thereof is not particularly limited, but is, for example, 70% by mass.

Hereinafter, the repeating unit represented by General Formula (B-1) included in the resin (X), and the other repeating units which may be optionally included will be described in detail.

<<Repeating Unit Represented by General Formula (B-1)>>

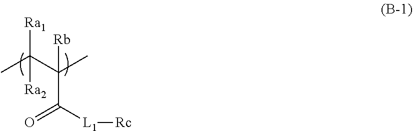

In General Formula (B-1). Ra₁ and Ra₂ each independently represent a hydrogen atom, an alkyl group, or an aryl group. It should be noted that one of Ra₁ or Ra₂ represents a hydrogen atom, and the other represents an alkyl group or an aryl group. Rb represents a hydrogen atom or a monovalent organic group. L₁ represents a divalent linking group selected from the group consisting of —O—, and —N(R_{A})—. R_{A} represents a hydrogen atom or a monovalent organic group. Rc represents a monovalent organic group.

The alkyl group represented by each of Ra₁ and Ra₂ is not particularly limited, but from the viewpoint that the sensitivity is higher and a pattern having more excellent LER and collapse suppressing capability can be formed, an alkyl group (which may be in any form of linear, branched, and cyclic forms) having 1 to 8 carbon atoms is preferable, and examples thereof include a methyl group, an ethyl group, a propyl group, an n-butyl group, a sec-butyl group, a hexyl group, and an octyl group. Among those, a linear or branched alkyl group having 1 to 4 carbon atoms is more preferable.

The aryl group represented by each of Ra₁ and Ra₂ is not particularly limited, but from the viewpoint that the sensitivity is higher and a pattern having more excellent LER and collapse suppressing capability can be formed, an aryl group (which may be in any form of linear, branched, and cyclic forms) having 6 to 10 carbon atoms is preferable. Examples of the aryl group include a phenyl group, a naphthyl group, and an anthryl group, and the phenyl group is preferable.

It should be noted that in General Formula (B-1), one of Ra₁ and Ra₂ represents a hydrogen atom and the other represents an alkyl group or an aryl group. From the viewpoint that the sensitivity is higher and a pattern having more excellent LER and collapse suppressing capability can be formed, it is preferable that one of Ra₁ and Ra₂ represents a hydrogen atom and the other represents an aryl group.

Ra₁ and Ra₂ may further have a substituent.

The substituent as each of Ra₁ and Ra₂ is not particularly limited, and examples thereof include the groups exemplified as the above-mentioned substituent group T, and more specifically, a halogen atom (a fluorine atom, a chlorine atom, a bromine atom, and an iodine atom), a cyano group, an alkyl group having 1 to 10 carbon atoms (for example, a methyl group, an ethyl group, and a propyl group), an alkoxy group having 1 to 10 carbon atoms (for example, a methoxy group and an ethoxy group), an acyl group having 1 to 10 carbon atoms (for example, a formyl group and an acetyl group), an alkoxycarbonyl group having 1 to 10 carbon atoms (for example, a methoxycarbonyl group and an ethoxycarbonyl group), an acyloxy group having 1 to 10 carbon atoms (for example, an acetyloxy group and a propionyloxy group), a nitro group, an alkyl group substituted with at least one fluorine atom (the alkyl group substituted with at least one fluorine atom is intended to mean an alkyl group in which a hydrogen atom is substituted with at least one fluorine atom; the number of carbon atoms of the alkyl group is preferably 1 to 10, and more preferably 1 to 6; and at least one or more fluorine atoms only need to be substituted, but a perfluoroalkyl group is preferable), and an acid group (a hydroxyl group, a carboxy group, a hexafluoroisopropanol group, and a sulfonic acid group).

Among those, the fluorine atom, the iodine atom, the alkyl group substituted with at least one fluorine atom, or the acid group is preferable, and the fluorine atom, the iodine atom, the perfluoroalkyl group having 1 to 6 carbon atoms, or the acid group is more preferable.

The monovalent organic group represented by Rb is not particularly limited, and examples thereof include the groups exemplified as the above-mentioned substituent group T, and more specifically, an alkyl group, an aryl group, a halogen atom (a fluorine atom, a chlorine atom, a bromine atom, and an iodine atom), and a hydroxyl group.

The alkyl group and the aryl group represented by Rb have the same definitions as the alkyl group and the aryl group represented by Ra₁, respectively, and suitable aspects thereof are also the same.

Among those, as Rb, the hydrogen atom is preferable.

L₁ represents a divalent linking group selected from the group consisting of —O— and —N(R_{A})—.

R_{A} represents a hydrogen atom or a monovalent organic group. The monovalent organic group represented by R_{A} is not particularly limited, and examples thereof include an alkyl group having 1 to 10 carbon atoms, which may have a substituent (for example, the groups exemplified as the above-mentioned substituent group T), with an alkyl group having 1 to 6 carbon atoms, which may have a substituent (for example, the groups exemplified as the above-mentioned substituent group T) being preferable. Examples of R_{A} include a methyl group, an ethyl group, a propyl group, an n-butyl group, a sec-butyl group, a hexyl group, and an octyl group.

Among those, the hydrogen atom is preferable as R_{A}.

The monovalent organic group represented by Rc is not particularly limited, and examples thereof include the groups exemplified as the above-mentioned substituent group T. and more specifically, a halogen atom (a fluorine atom, a chlorine atom, a bromine atom, and an iodine atom), an alkyl group, an alkyl group substituted with at least one fluorine atom, an aralkyl group, a group that decomposes by the action of an acid to leave (hereinafter also referred to as a “leaving group”), and a group including a lactone structure.

The alkyl group is not particularly limited, but an alkyl group having 1 to 8 carbon atoms, which may have a substituent (for example, the groups exemplified as the above-mentioned substituent group T), is preferable, and examples thereof include a methyl group, an ethyl group, a propyl group, an n-butyl group, a sec-butyl group, a hexyl group, and an octyl group. Among those, a linear or branched alkyl group having 1 to 4 carbon atoms is more preferable.

The alkyl group substituted with at least one fluorine atom is intended to mean an alkyl group in which a hydrogen atom is substituted with at least one fluorine atom. The number of carbon atoms of the alkyl group is preferably 1 to 10, more preferably 1 to 6, and still more preferably 1 to 3. In addition, a perfluoroalkyl group is preferable as the alkyl group substituted with at least one fluorine atom.

The aralkyl group is not particularly limited, but for example, the number of carbon atoms of the alkyl group in the aralkyl group is preferably 1 to 6, and more preferably 1 to 3. Examples of the aralkyl group include a benzyl group and a phenethyl group.

Examples of the leaving group include —C(R₃₆)(R₃₇)(R₃₈), —C(R₃₆)(R₃₇)(OR₃₉), and —C(R₀₁)(R₀₂)(OR₃₉).

In the formulae, R₃₆ to R₃₉ each independently represent an alkyl group, a cycloalkyl group, an aryl group, an aralkyl group, or an alkenyl group. R₃₆ and R₃₇ may be bonded to each other to form a ring.

R₀₁ and R₀₂ each independently represent a hydrogen atom, an alkyl group, a cycloalkyl group, an aryl group, an aralkyl group, or an alkenyl group.

As the alkyl group as each of R₃₆ to R₃₉, R₀₁, and R₀₂, an alkyl group having 1 to 8 carbon atoms is preferable, and examples thereof include a methyl group, an ethyl group, a propyl group, an n-butyl group, a sec-butyl group, a hexyl group, and an octyl group.

The cycloalkyl group as each of R₃₆ to R₃₉, R₀₁, and R₀₂ may be either a monocycle or polycycle. As the monocyclic cycloalkyl group, a cycloalkyl group having 3 to 8 carbon atoms is preferable, and examples thereof include a cyclopropyl group, a cyclobutyl group, a cyclopentyl group, a cyclohexyl group, and a cyclooctyl group. As the polycyclic cycloalkyl group, a cycloalkyl group having 6 to 20 carbon atoms is preferable, and examples thereof include an adamantyl group, a norbornyl group, an isobornyl group, a camphanyl group, a dicyclopentyl group, an α-pinel group, a tricyclodecanyl group, a tetracyclododecyl group, and an androstanyl group. Further, at least one carbon atom in the cycloalkyl group may be substituted with heteroatoms such as an oxygen atom.

The aryl group as each of R₃₆ to R₃₉, R₀₁, and R₀₂ is preferably an aryl group having 6 to 10 carbon atoms, and examples thereof include a phenyl group, a naphthyl group, and an anthryl group.

The aralkyl group as each of R₃₆ to R₃₉, R₀₁, and R₀₂ is preferably an aralkyl group having 7 to 12 carbon atoms, and examples thereof include a benzyl group, a phenethyl group, and a naphthylmethyl group.

The alkenyl group as each of R₃₆ to R₃₉, R₀₁, and R₀₂ is preferably an alkenyl group having 2 to 8 carbon atoms, and examples thereof include a vinyl group, an allyl group, a butenyl group, and a cyclohexenyl group.

The ring formed by the bonding of R₃₆ and R₃₇ is preferably a (monocyclic or polycyclic) cycloalkyl group. As the cycloalkyl group, monocyclic cycloalkyl groups such as a cyclopentyl group and a cyclohexyl group, and polycyclic cycloalkyl groups such as a norbornyl group, a tetracyclodecanyl group, a letracyclododecanyl group, and an adamantyl group are preferable.

The above-mentioned aralkyl group and leaving group may have a substituent. The substituent is not particularly limited, but for example, substituents as the substituent of each of Ra₁ and Ra₂ are preferable, and among these, the fluorine atom, the iodine atom, or the alkyl group substituted with at least one fluorine atom is more preferable, and the fluorine atom, the iodine atom, or the perfluoroalkyl group having 1 to 6 carbon atoms is still more preferable.

The group including a lactone structure is not particularly limited as long as it includes a lactone structure.

As the lactone structure, a 5- to 7-membered ring lactone structure is preferable, and a 5- to 7-membered ring lactone structure to which another ring structure is fused so as to form a bicyclo structure or spiro structure is more preferable.

As the lactone structure, lactone structures represented by General Formulae (LC1-1) to (LC1-17) are preferable, and among these, a group represented by General Formula (LC1-1), General Formula (LC1-4), General Formula (LC1-5), General Formula (LC1-6), General Formula (LC1-13), or General Formula (LC1-14) is more preferable. By removing any one of hydrogen atoms from the lactone structure, a group including the lactone structure is derived.

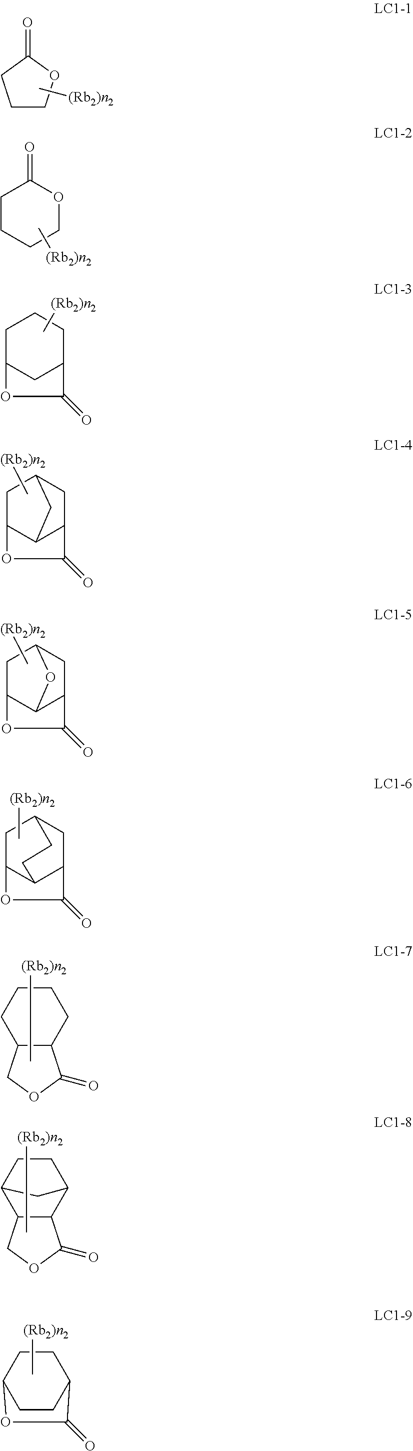

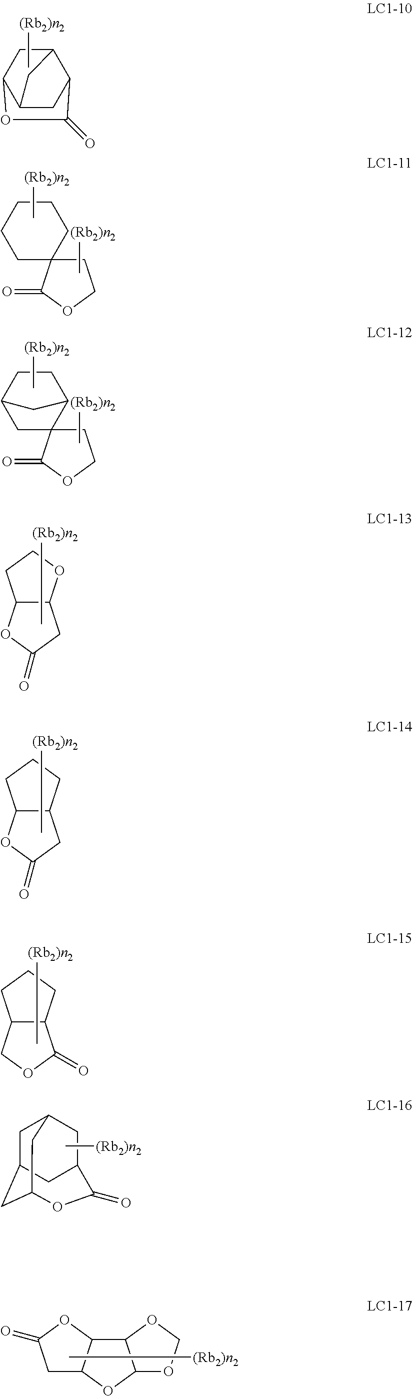

The lactone structural moiety may have a substituent (Rb₂). Examples of the substituent (Rb₂) include an alkyl group having 1 to 8 carbon atoms, a cycloalkyl group having 4 to 7 carbon atoms, an alkoxy group having 1 to 8 carbon atoms, an alkoxycarbonyl group having 2 to 8 carbon atoms, a carboxy group, a halogen atom, a hydroxyl group, a cyano group, and an acid-decomposable group, and an alkyl group having 1 to 4 carbon atoms, a cyano group, or an acid-decomposable group is preferable. n₂ represents an integer of 0 to 4. In a case where n₂ is 2 or more, the substituents (Rb₂) which are present in plural number may be the same as or different from each other. Further, the substituents (Rb₂) which are present in plural number may be bonded to each other to form a ring.

In a case where Rc includes the lactone structure, it is preferable that Rc is represented by General Formula (A1).

-L₂-Rc₁ General Formula (A1):

In General Formula (A1), L₂ represents a single bond or a divalent linking group, and Rc₁ represents a group formed by removing any one of hydrogen atoms from the lactone structure.

The divalent linking group is not particularly limited, but examples thereof include —CO—, —O—, —N(R_{B})—, an alkylene group (preferably having 1 to 6 carbon atoms), a cycloalkylene group (preferably having 3 to 15 carbon atoms), an alkenylene group (preferably having 2 to 6 carbon atoms), and a divalent linking group formed by combination of a plurality of these groups. R_{B} represents a hydrogen atom or a monovalent organic group. The monovalent organic group represented by R_{B} is not particularly limited, but represents, for example, an alkyl group having 1 to 10 carbon atoms.

The group formed by removing any one of hydrogen atoms from the lactone structure, represented by Rc₁, is the same as described above.

Among those, L₂ is preferably a single bond.

Among those, from the viewpoint that the sensitivity is higher and a pattern having more excellent LER and collapse suppressing capability can be formed, in particular, the repeating unit represented by General Formula (B-1) is preferably a repeating unit represented by General Formula (B-2).

<<Repeating Unit Represented by General Formula (B-2)>>

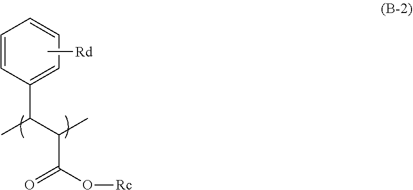

In General Formula (B-2), Rc represents a monovalent organic group. Rd represents a hydrogen atom or a monovalent organic group.

In General Formula (B-2), the monovalent organic group represented by Rc has the same definition as Rc in General Formula (B-1), and suitable aspects thereof are also the same.

Examples of the monovalent organic group represented by Rd include the same ones the substituents of each of Ra₁ and Ra₂ as described above, and suitable aspects thereof are also the same.

Specific examples of the repeating unit represented by General Formula (B-1) are set for the below, but the present invention is not limited to these specific examples.

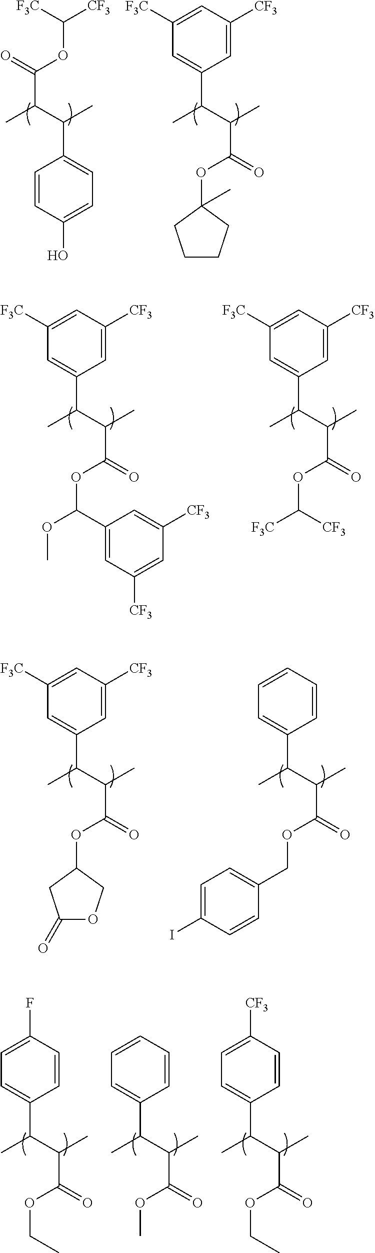

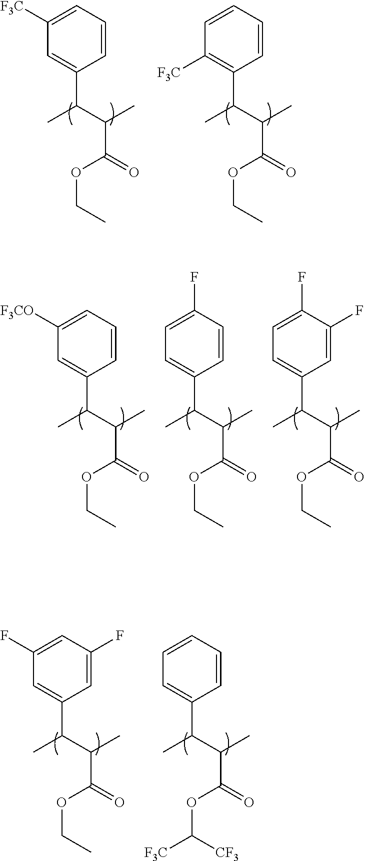

Among those, from the viewpoint that the sensitivity is higher and a pattern having more excellent LER and collapse suppressing capability can be formed, the repeating unit represented by General Formula (B-2) in which the content of the halogen atom selected from the group consisting of a fluorine atom and a halogen atom (hereinafter also referred to as a “content of a specific halogen atom”) is 10% by mass or more is preferable. From the viewpoint that the sensitivity is higher and a pattern having more excellent LER and collapse suppressing capability can be formed, the content of the specific halogen atoms is more preferably 12% by mass or more, still more preferably 25% by mass or more, and particularly preferably 30% by mass or more. In addition, an upper limit value thereof is not particularly limited, but is, for example, 80% by mass or less.

The repeating unit represented by General Formula (B-2) is preferably at least one repeating unit selected from the group consisting of the following repeating unit (A), the following repeating unit (B), and the following repeating unit (C).

Repeating unit (A): Repeating unit represented by General Formula (B-2), in which Rc represents a group including a lactone structure.

Repeating unit (B): Repeating unit represented by General Formula (B-2), in which Rc represents a group that decomposes by the action of an acid to leave (leaving group).

Repeating unit (C): Repeating unit represented by General Formula (B-2), in which Rd represents an acid group.

Furthermore, the group including a lactone structure represented by Rc, the leaving group represented by Rc, and the acid group represented by Rd are each the same as described above.

Among those, from the viewpoint that the sensitivity is higher and a pattern having more excellent LER and collapse suppressing capability can be formed, the content of the specific halogen atoms in any of the repeating unit (A), the repeating unit (B), and the repeating unit (C) is preferably 10% by mass or more, more preferably 12% by mass or more, still more preferably 25% by mass or more, and particularly preferably 30% by mass or more, and is also preferably 80% by mass or less. In addition, in a case where a specific halogen atom is introduced into the repeating unit (B), from the viewpoint that the sensitivity is higher and a pattern having more excellent LER and collapse suppressing capability can be formed, the specific halogen atom is preferably introduced into a position other than the leaving group.

Among those, from the viewpoint that the sensitivity is higher and a pattern having more excellent LER and collapse suppressing capability can be formed, the resin (X) preferably includes at least two or more repeating units selected from the group consisting of the repeating unit (A), the repeating unit (B), and the repeating unit (C), and more preferably includes all of the repeating unit (A), the repeating unit (B), and the repeating unit (C).

<<Other Repeating Units>>

The resin (X) may further include other repeating units, in addition to the repeating unit represented by General Formula (B-1). In addition, the content of the repeating unit represented by General Formula (B-1) in the resin (X) is not particularly limited, but is, for example, 5% to 100% by mass with respect to all the repeating units in the resin (X).

Such other repeating units which can be included in the resin (X) will be described in detail.

In a case where the resin (X) includes such other repeating units, the content of the repeating unit represented by General Formula (B-1) is preferably 5% to 80%/A by mass, more preferably 5% to 70% by mass, and still more preferably 10% to 60% by mass, with respect to all the repeating units in the resin (X).

In the resin (X), the total amount of the repeating unit (corresponding to, for example, the above-mentioned repeating unit (B) and a repeating unit Y1 which will be described later) including the acid-decomposable group is preferably 10% by mass or more, and more preferably 15% by mass or more, and is also preferably 50% by mass or less, and more preferably 40% by mass or less, with respect to all the repeating units in the resin (X).

In the resin (X), the total amount of the repeating units (corresponding to, for example, the above-mentioned repeating unit (C), a repeating unit Y3 which will be described later, and a repeating unit Y4 which will be described later) including an acid group is preferably 20% by mass or more, and more preferably 30% by mass or more, and is also preferably 80% by mass or less, and more preferably 70% by mass or less, with respect to all the repeating units in the resin (X).

Repeating Unit Having Acid-Decomposable Group

The resin (X) may further include another repeating unit having an acid-decomposable group (hereinafter also referred to as a “repeating unit Y1”), in addition to the repeating unit represented by General Formula (B-1).

The acid-decomposable group preferably has a structure in which a polar group is protected with a group that decomposes by the action of an acid to leave (leaving group).

Examples of the polar group include an acidic group (a group which dissociates in a 2.38%-by-mass aqueous tetramethylammonium hydroxide solution), such as a carboxy group, a phenolic hydroxyl group, a fluorinated alcohol group, a sulfonic acid group, a sulfonamido group, a sulfonylimido group, an (alkylsulfonyl)(alkylcarbonyl)methylene group, an (alkylsulfonyl)(alkylcarbonyl)imido group, a bis(alkylcarbonyl)methylene group, a bis(alkylcarbonyl)imido group, a bis(alkylsulfonyl)methylene group, a bis(alkylsulfonyl)imido group, a tris(alkylcarbonyl)methylene group, and a tris(alkylsulfonyl)methylene group, and an alcoholic hydroxyl group.

Moreover, the alcoholic hydroxyl group refers to a hydroxyl group bonded to a hydrocarbon group, which is a hydroxyl group other than a hydroxyl group (phenolic hydroxyl group) directly bonded to an aromatic ring, from which an aliphatic alcohol (for example, a hexafluoroisopropanol group) having the α-position substituted with an electron withdrawing group such as a fluorine atom is excluded as a hydroxyl group. The alcoholic hydroxyl group is preferably a hydroxyl group having an acid dissociation constant (pKa) from 12 to 20.

Preferred examples of the polar group include a carboxy group, a fluorinated alcohol group (preferably a hexafluoroisopropanol group), and a sulfonic acid group.

A group which is preferable as the acid-decomposable group is a group in which a hydrogen atom is substituted with a group that leaves by the action of an acid (leaving group).

The leaving group has the same definition as the leaving group represented by Rc, and suitable aspects thereof are also the same.

As the repeating unit Y1, a repeating unit represented by General Formula (AI) is preferable.

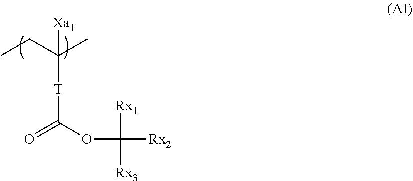

In General Formula (AI),

Xa₁ represents a hydrogen atom, a halogen atom, or an alkyl group which may have a substituent.

T represents a single bond or a divalent linking group.

Rx₁ to Rx₃ each independently represent an (linear or branched) alkyl group or a (monocyclic or polycyclic) cycloalkyl group. It should be noted that in a case where all of Rx₁ to Rx₃ are (linear or branched) alkyl groups, it is preferable that at least two of Rx₁, . . . , or Rx₃ are methyl groups.

Two of Rx₁ to Rx₃ may be bond to each other to form a (monocyclic or polycyclic) cycloalkyl group.

Examples of the alkyl group which may have a substituent, represented by Xa₁, include a methyl group or a group represented by —CH₂—R₁₁. R₁₁ represents a halogen atom (a fluorine atom and the like), a hydroxyl group, or a monovalent organic group, for example, an alkyl group having 5 or less carbon atoms and an acyl group having 5 or less carbon atoms; the alkyl group having 3 or less carbon atoms is preferable; and the methyl group is more preferable.

Examples of the halogen atom represented by Xa₁ include a fluorine atom, a chlorine atom, a bromine atom, and an iodine atom, and the fluorine atom or the iodine atom is preferable.

As Xa₁, a hydrogen atom, a fluorine atom, an iodine atom, a methyl group, a trifluoromethyl group, or a hydroxymethyl group is preferable.

Examples of the divalent linking group represented by T include an alkylene group, an arylene group, a —COO-Rt-group, and a —O-Rt-group. In the formulae, Rt represents an alkylene group or a cycloalkylene group.

T is preferably a single bond or a —COO-Rt-group. In a case where T represents a —COO-Rt-group, Rt is preferably an alkylene group having 1 to 5 carbon atoms, and more preferably a —CH₂— group, a —(CH₂)₂— group, or a —(CH₂)₃— group.

As the alkyl group represented by each of Rx₁ to Rx₃, an alkyl group having 1 to 4 carbon atoms, such as a methyl group, an ethyl group, an n-propyl group, an isopropyl group, an n-butyl group, an isobutyl group, and a t-butyl group, is preferable.

As the cycloalkyl group represented by each of Rx₁ to Rx₃, a monocyclic cycloalkyl group such as a cyclopentyl group and a cyclohexyl group, or a polycyclic cycloalkyl group such as a norbornyl group, a tetracyclodecanyl group, a tetracyclododecanyl group, and an adamantyl group is preferable.

As the cycloalkyl group formed by the bonding of two of Rx₁ to Rx₃, a monocyclic cycloalkyl group such as a cyclopentyl group and a cyclohexyl group is preferable, and in addition, a polycyclic cycloalkyl group such as a norbornyl group, a tetracyclodecanyl group, a tetracyclododecanyl group, and an adamantyl group is also preferable. Among those, a monocyclic cycloalkyl group having 5 or 6 carbon atoms is preferable.

In the cycloalkyl group formed by the bonding of two of Rx₁ to Rx₃ for example, one of the methylene groups constituting the ring may be substituted with a heteroatom such as an oxygen atom, or a group having a heteroatom, such as a carbonyl group.

In a case where each of the groups has a substituent, examples of the substituent include an alkyl group (having 1 to 4 carbon atoms), a halogen atom, a hydroxyl group, an alkoxy group (having 1 to 4 carbon atoms), a carboxy group, and an alkoxycarbonyl group (having 2 to 6 carbon atoms). The number of carbon atoms in the substituent is preferably 8 or less.

Specific examples of the repeating unit Y1 are set forth below, but the present invention is not particularly limited to these specific examples.

In the specific examples, Rx represents a hydrogen atom, a fluorine atom, an iodine atom, CH₃, CF₃, or CH₂OH. Rxa and Rxb each represent an alkyl group having 1 to 4 carbon atoms. Z represents a substituent including a polar group, and in a case where Z's are present in plural number, Z's are independent. p represents 0 or a positive integer. Examples of the substituent including a polar group represented by Z include a linear or branched alkyl group or alicyclic group, which has a hydroxyl group, a cyano group, an amino group, an alkylamido group, or a sulfonamido group, and an alkyl group having a hydroxyl group is preferable. As the branched alkyl group, an isopropyl group is preferable.

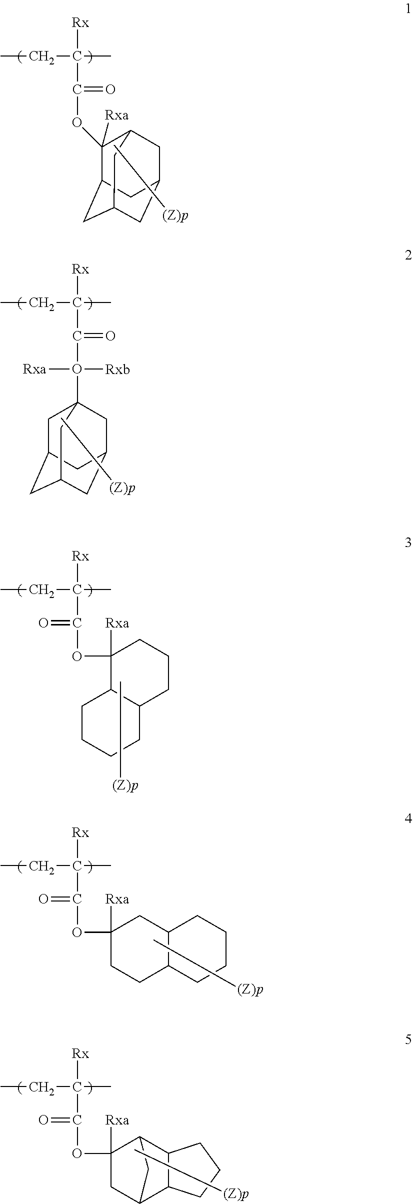

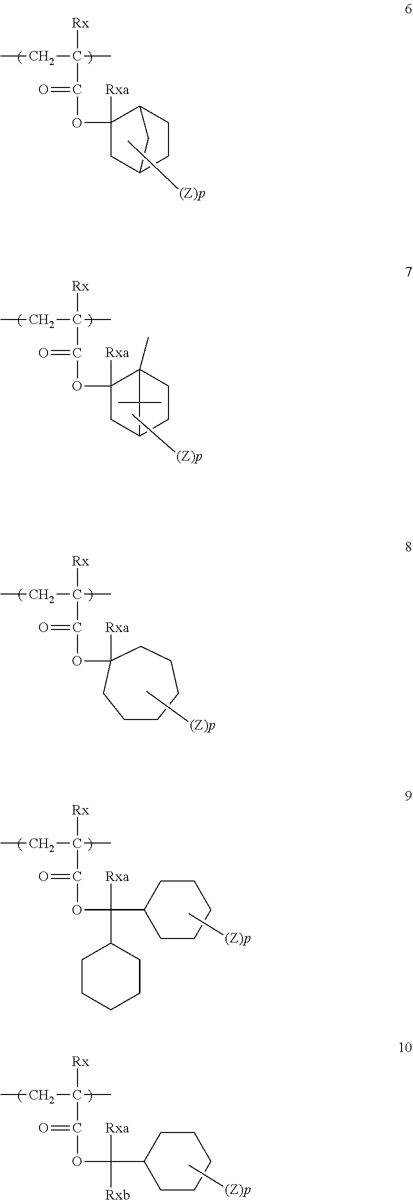

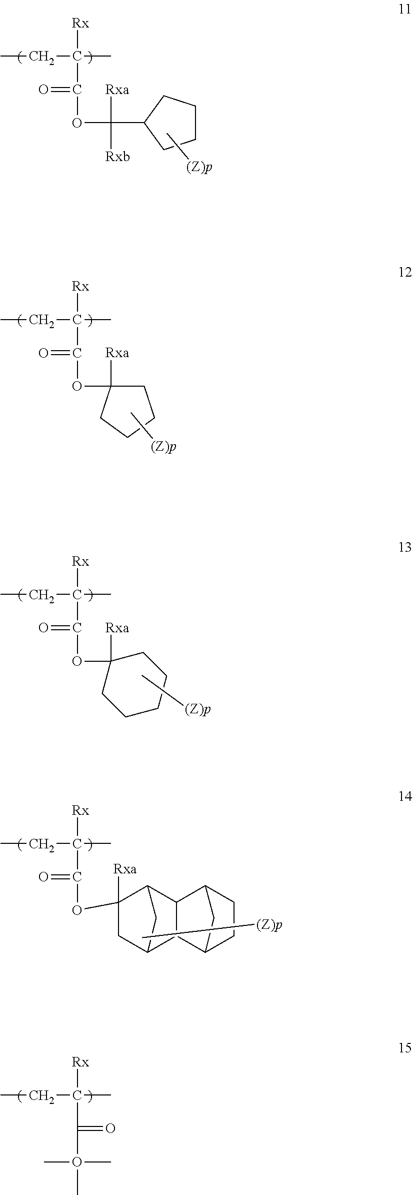

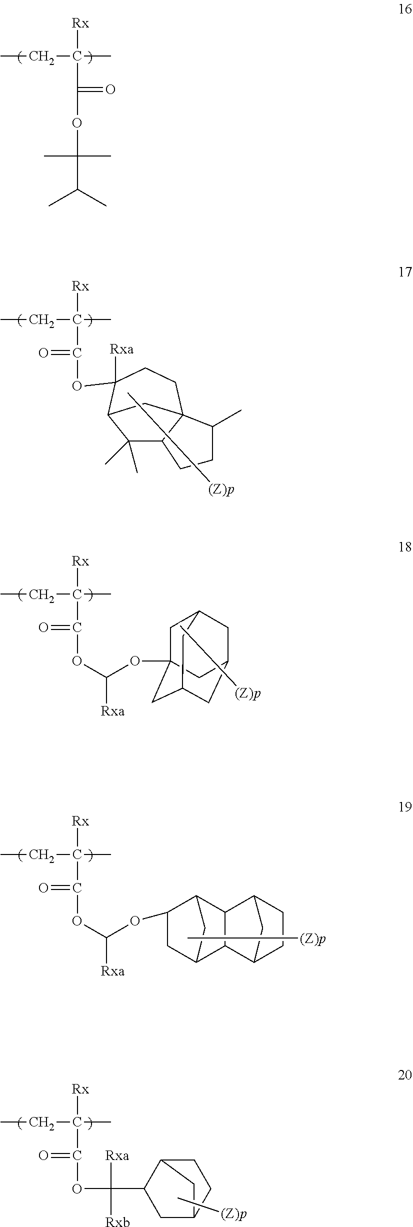

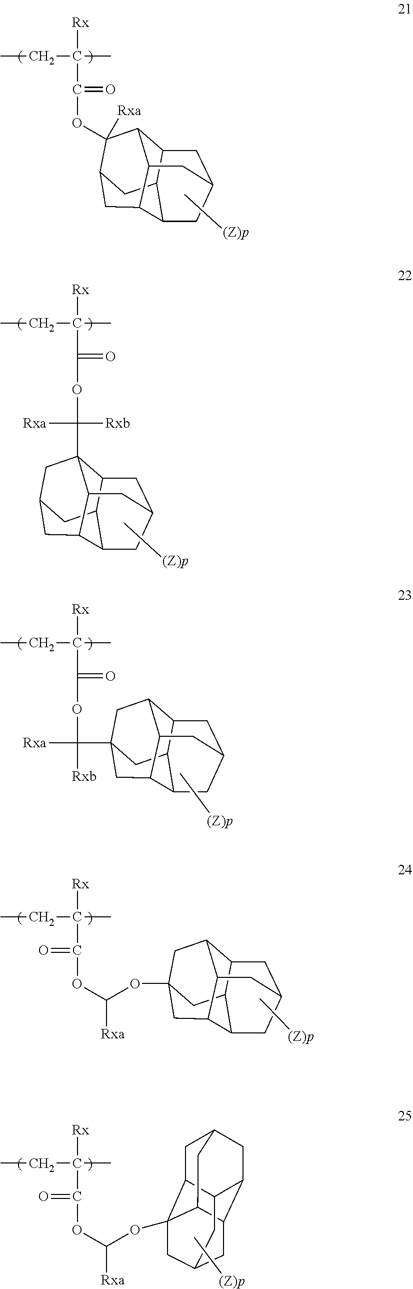

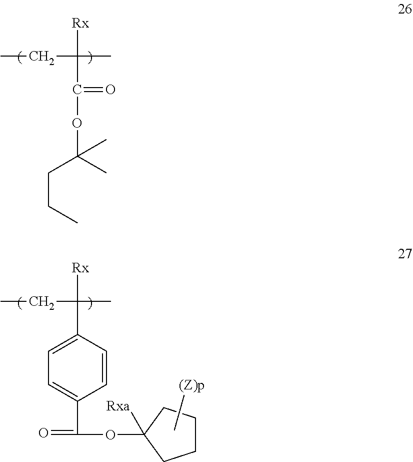

In a case where the resin (X) includes a repeating unit Y1, the content of the repeating unit Y1 is preferably 5% to 80% by mass, more preferably 5% to 70% by mass, and still more preferably 10% to 60% by mass, with respect to all the repeating units in the resin (X).

Other Repeating Unit Having Lactone Structure

The resin (X) may further include another repeating unit (hereinafter also referred to as a “repeating unit Y2”) having a lactone structure, in addition to the repeating unit represented by General Formula (B-1).

Examples of repeating unit Y2 include a repeating unit represented by General Formula (AI).

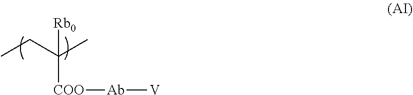

In General Formula (AI), Rb₀ represents a hydrogen atom, a halogen atom, or an alkyl group having 1 to 4 carbon atoms.

The alkyl group of Rb₀ may have a substituent, and examples of the substituent include a hydroxyl group and a halogen atom (a fluorine atom, a chlorine atom, a bromine atom, and an iodine atom). Among those, Rb₀ is preferably a hydrogen atom or a methyl group.

In General Formula (AI), Ab represents a single bond, an alkylene group, a divalent linking group having a monocyclic or polycyclic alicyclic hydrocarbon structure, an ether group, an ester group, a carbonyl group, a carboxy group, or a divalent group formed by combination thereof. Among those, the single bond or a linking group represented by -Ab₁-COO— is preferable. Ab, is a linear or branched alkylene group, or a monocyclic or polycyclic cycloalkylene group, and is preferably a methylene group, an ethylene group, a cyclohexylene group, an adamantylene group, or a norbornylene group.

V represents a group represented by any one of General Formula (LC1-1), . . . , or General Formula (LC1-17) which has the above-mentioned lactone structure.

Optical isomers of the repeating unit Y2 are typically present, but any of the optical isomers may be used. In addition, one optical isomer may be used singly or a mixture of a plurality of the optical isomers may be used. In a case where one optical isomer is mainly used, the optical purity (ee) thereof is preferably 90 or more, and more preferably 95 or more.

Specific examples of the repeating unit Y2 are set forth below, but the present invention is not particularly limited to these specific examples. In the specific examples, Rx represents a hydrogen atom, a —CH₃ group, a —CH₂OH group, or a —CF₃ group.

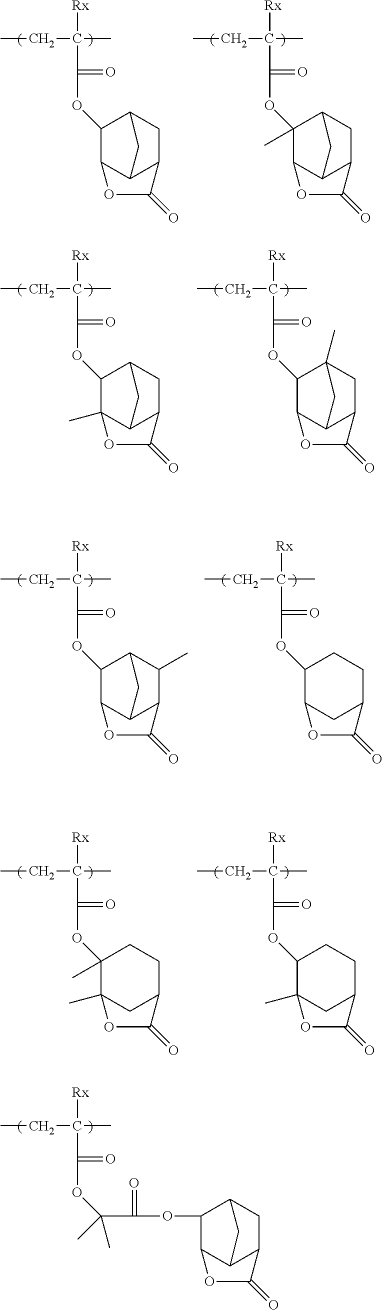

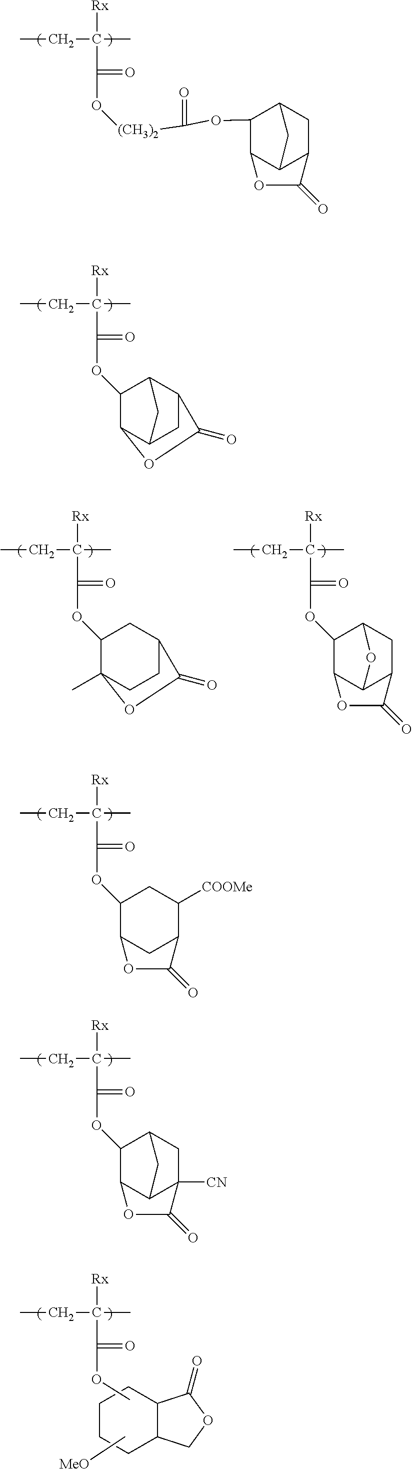

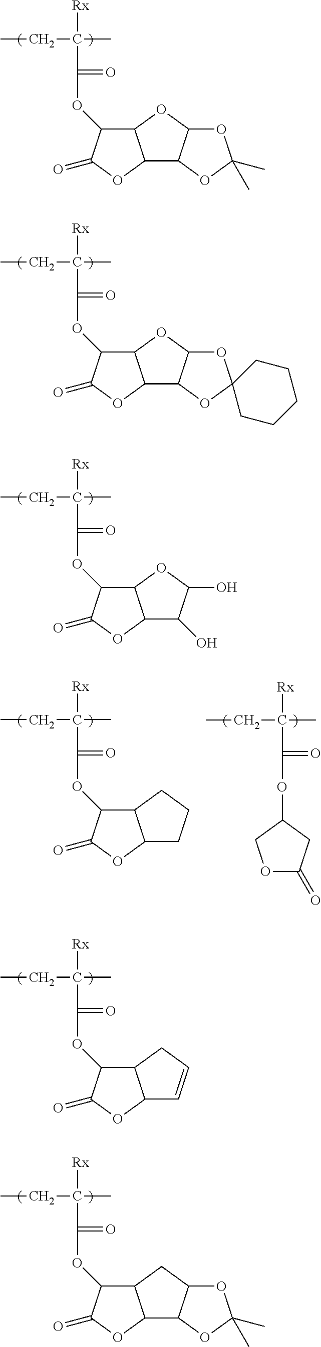

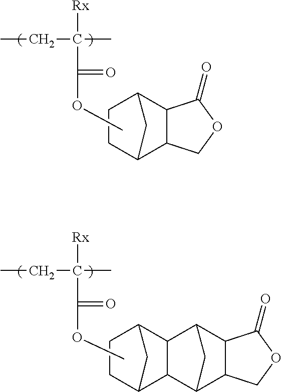

In a case where the resin (X) includes the repeating unit Y2 the content of the repeating unit Y2 is preferably 5% to 80% a by mass, more preferably 5% to 70% by mass, and still more preferably 10% to 60% by mass, with respect to all the repeating units in the resin (X).

Repeating Unit Having Phenolic Hydroxyl Group

The resin (X) may further include another repeating unit having a phenolic hydroxyl group (hereinafter also referred to as a “repeating unit Y3”), in addition to the repeating unit represented by General Formula (B-1).

Examples of the repeating unit Y3 include a repeating unit represented by General Formula (I).

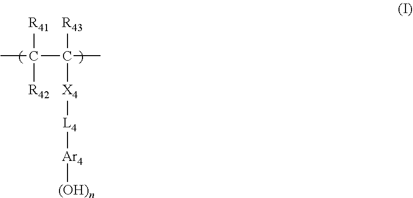

In the formula, R₄, R₄₂, and R₄₃ each independently represent a hydrogen atom, an alkyl group, a cycloalkyl group, a halogen atom, a cyano group, or an alkoxycarbonyl group. It should be noted that R₄₂ may be bonded to Ar₄ to form a ring, and in this case. R₄₂ represents a single bond or an alkylene group.

X₄ represents a single bond, —COO—, or —CONR₆₄—, and R₆₄ represents a hydrogen atom or an alkyl group.

L₄ represents a single bond or a divalent linking group.

Ar₄ represents an (n+1)-valent aromatic hydrocarbon group, and in a case where Ar₄ is bonded to R₄₂ to form a ring, Ar₄ represents an (n+2)-valent aromatic hydrocarbon group. n represents an integer of 1 to 5.

For the purpose of increasing the polarity of the repeating unit represented by General Formula (I), it is preferable that n is an integer of 2 or more, or X₄ is —COO— or —CONR₆₄—.

As the alkyl group represented by each of R₄₁, R₄₂, and R₄₃ in General Formula (I), an alkyl group having 20 or less carbon atoms, such as a methyl group, an ethyl group, a propyl group, an isopropyl group, an n-butyl group, a sec-butyl group, a hexyl group, a 2-ethylhexyl group, an octyl group, and a dodecyl group, each of which may have a substituent, is preferable, an alkyl group having 8 or less carbon atoms is more preferable, and an alkyl group having 3 or less carbon atoms is still more preferable.

The cycloalkyl group represented by each of R₄₁, R₄₂, and R₄₃ in General Formula (I) may be either a monocycle or a polycycle. A monocyclic cycloalkyl group having 3 to 8 carbon atoms, such as a cyclopropyl group, a cyclopentyl group, and a cyclohexyl group, each of which may have a substituent, is preferable.

Examples of the halogen atom represented by each of R₄₁, R₄₂, and R₄₃ in General Formula (I) include a fluorine atom, a chlorine atom, a bromine atom, and an iodine atom, and the fluorine atom is preferable.

As the alkyl group included in the alkoxycarbonyl group represented by each of R₄₁, R₄₂, and R₄₃ in General Formula (I), the same ones as the alkyl group in each of R₄₁, R₄₂, and R₄₃ are preferable.

Preferred examples of the substituent in each of the groups include an alkyl group, a cycloalkyl group, an aryl group, an amino group, an amido group, an ureido group, an urethane group, a hydroxyl group, a carboxyl group, a halogen atom, an alkoxy group, a thioether group, an acyl group, an acyloxy group, an alkoxycarbonyl group, a cyano group, and a nitro group, and the number of carbon atoms of the substituent is preferably 8 or less.

Ar₄ represents an (n+1)-valent aromatic hydrocarbon group. The divalent aromatic hydrocarbon group in a case where n is 1 may have a substituent, and for example, an arylene group having 6 to 18 carbon atoms, such as a phenylene group, a tolylene group, a naphthylene group, and an anthracenylene group, or an aromatic hydrocarbon group including a heterocycle such as thiophene, furan, pyrrole, benzothiophene, benzofuran, benzopyrrole, triazine, imidazole, benzimidazole, triazole, thiadiazole, and thiazole is preferable.

Specific examples of the (n+1)-valent aromatic hydrocarbon group in a case where n is an integer of 2 or more include groups formed by excluding any (n−1) hydrogen atoms from the above-mentioned specific examples of the divalent aromatic hydrocarbon group.

The (n+1)-valent aromatic hydrocarbon group may further have a substituent.

Examples of the substituent which can be contained in the above-mentioned alkyl group, cycloalkyl group, alkoxycarbonyl group, alkylene group, and (n+1)-valent aromatic hydrocarbon group include the alkyl groups listed in R₄₁, R₄₂, and R₄₃ in General Formula (I); alkoxy groups such as a methoxy group, an ethoxy group, a hydroxyethoxy group, a propoxy group, a hydroxypropoxy group, and a butoxy group; and aryl groups such as a phenyl group.

Examples of the alkyl group of R₆₄ in —CONR₆₄— (R₆₄ represents a hydrogen atom or an alkyl group) represented by X₄ include an alkyl group having 20 or less carbon atoms, such as a methyl group, an ethyl group, a propyl group, an isopropyl group, an n-butyl group, a sec-butyl group, a hexyl group, a 2-ethylhexyl group, an octyl group, and a dodecyl group, and the alkyl group is preferably an alkyl group having 8 or less carbon atoms.

As X₄, a single bond, —COO—, or —CONH— is preferable, and the single bond or —COO— is more preferable.

As the divalent linking group as L₄, an alkylene group is preferable, and as the alkylene group, an alkylene group having 1 to 8 carbon atoms, such as a methylene group, an ethylene group, a propylene group, a butylene group, a hexylene group, and an octylene group, each of which may have a substituent, is preferable.

As Ar₄, an aromatic hydrocarbon group having 6 to 18 carbon atoms, which may have a substituent, is preferable, and a benzene ring group, a naphthalene ring group, or a biphenylene ring group is more preferable. Among those, the repeating unit represented by General Formula (I) is preferably a repeating unit derived from hydroxystyrene. That is, Ar₄ is preferably a benzene ring group.

Specific examples of the repeating unit Y3 are set forth below, but the present invention is not limited to these specific examples. In the formulae, a represents 1 or 2.

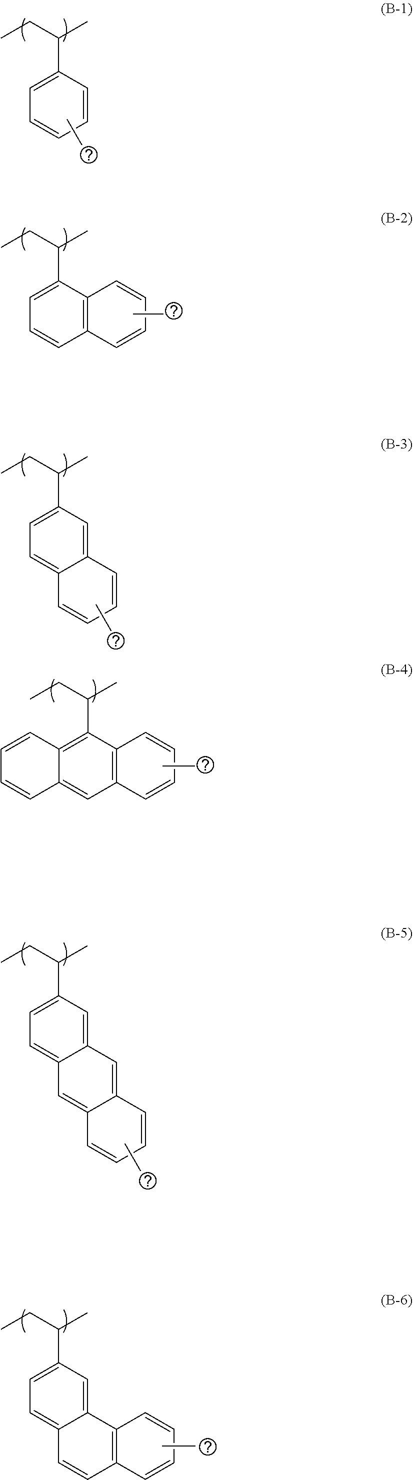

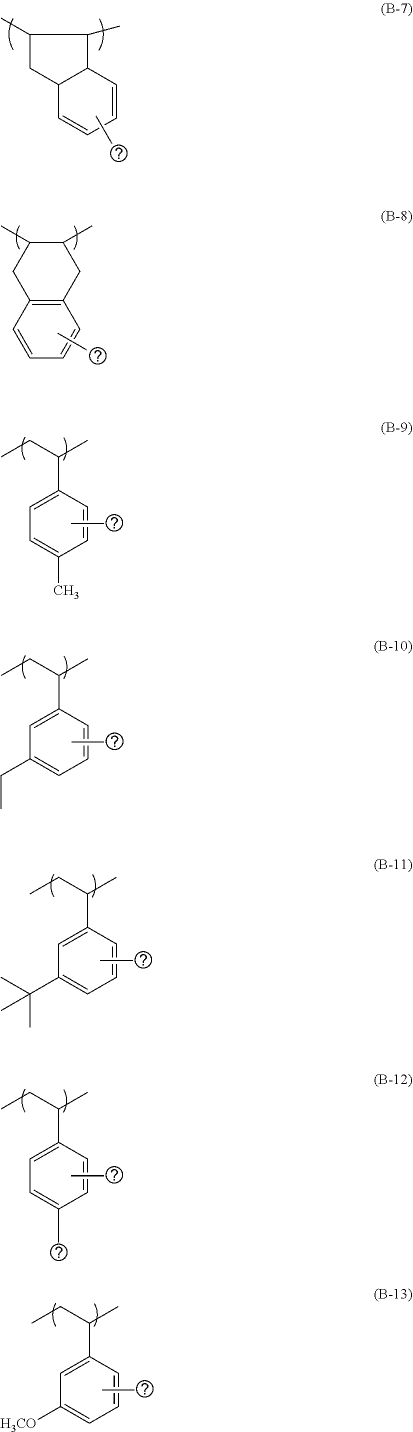

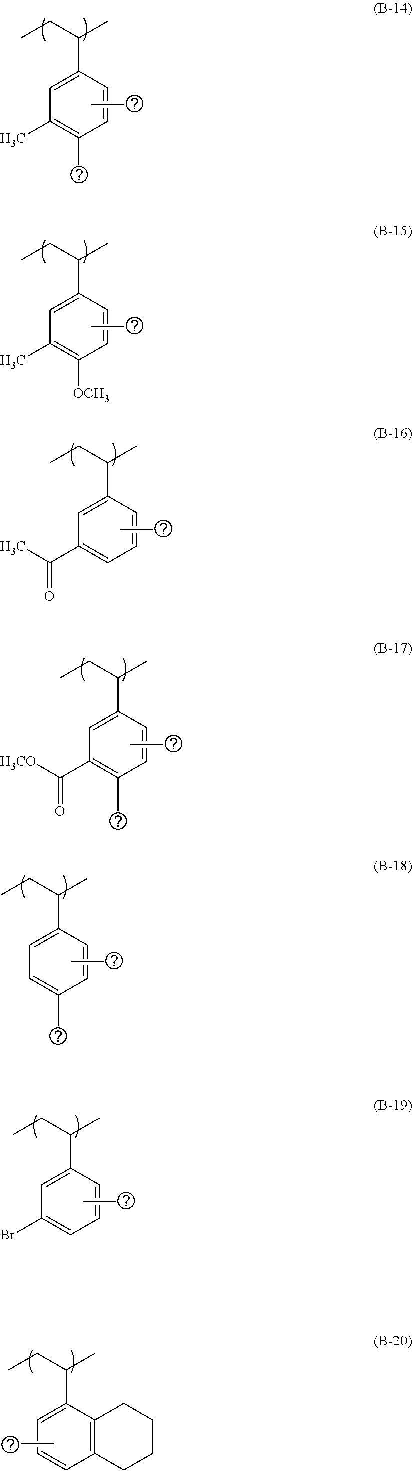

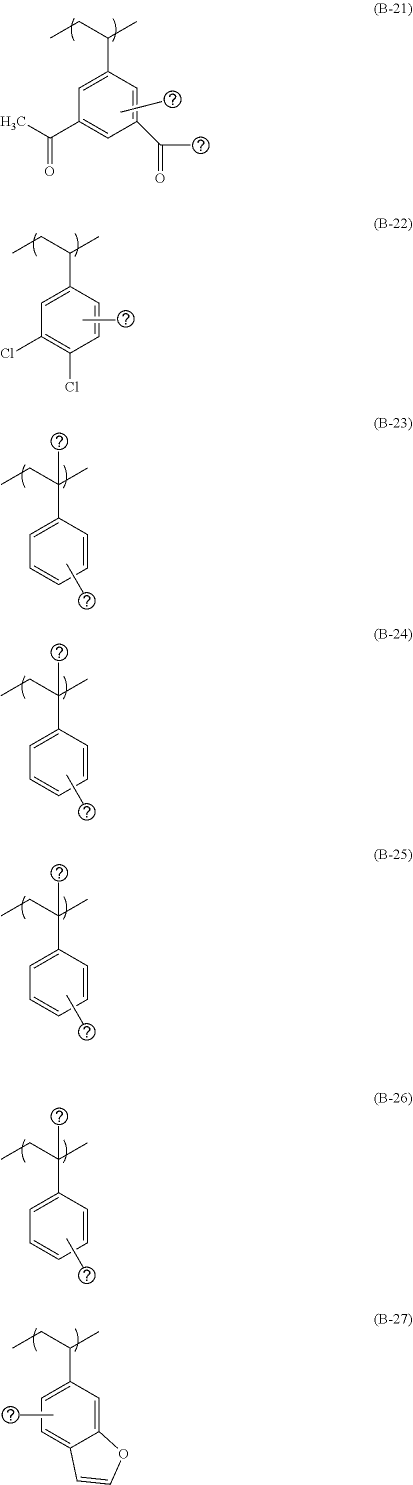

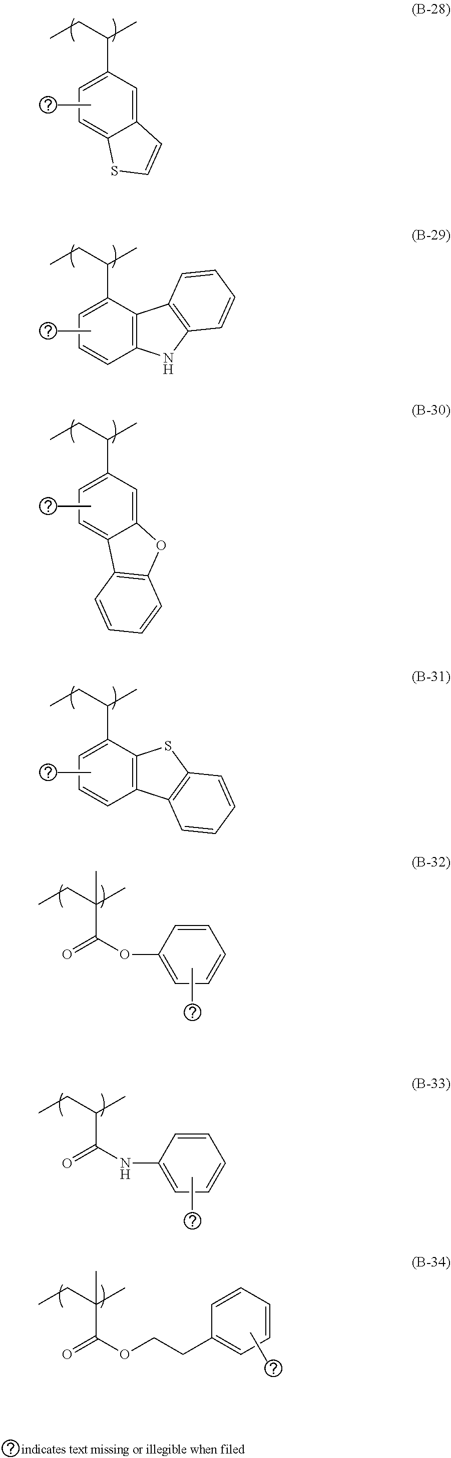

In a case where the resin (X) includes the repeating unit Y3, the content of the repeating unit Y3 is preferably 5% to 80% by mass, more preferably 5% to 7 by mass, and still more preferably 10% to 60% by mass, with respect to all the repeating units in the resin (X).

Repeating Unit Acid Group

The resin (X) may further include another repeating unit having an acid group (hereinafter also referred to as a “repeating unit Y4”), in addition to the repeating unit represented by General Formula (B-1) and the repeating unit Y3.

Examples of the acid group included in the repeating unit Y4 include a phenolic hydroxyl group, a carboxylic acid group, a fluorinated alcohol group, a sulfonic acid group, a sulfonamido group, a sulfonylimido group, an (alkylsulfonyl)(alkylcarbonyl)methylene group, an (alkylsulfonylXalkylcarbonyl)imido group, a bis(alkylcarbonyl)methylene group, a bis(alkylcarbonyl)imido group, a bis(alkylsulfonyl)methylene group, a bis(alkylsulfonyl)imido group, a tris(alkylcarbonyl)methylene group, and a tris(alkylsulfonyl)methylene group.

As the acid group, the fluorinated alcohol group (preferably hexafluoroisopropanol), the sulfonimido group, or the bis(alkylcarbonyl)methylene group is preferable.

The skeleton of the repeating unit Y4 is not particularly limited, but the repeating unit Y4 is preferably a (meth)acylate-based repeating unit or a styrene-based repeating unit.

Specific examples of the repeating unit Y4 are set forth below, but the present invention is not limited to these specific examples. In the formulae, Rx represents a hydrogen atom, CH₃, CF₃, or CH₂OH.

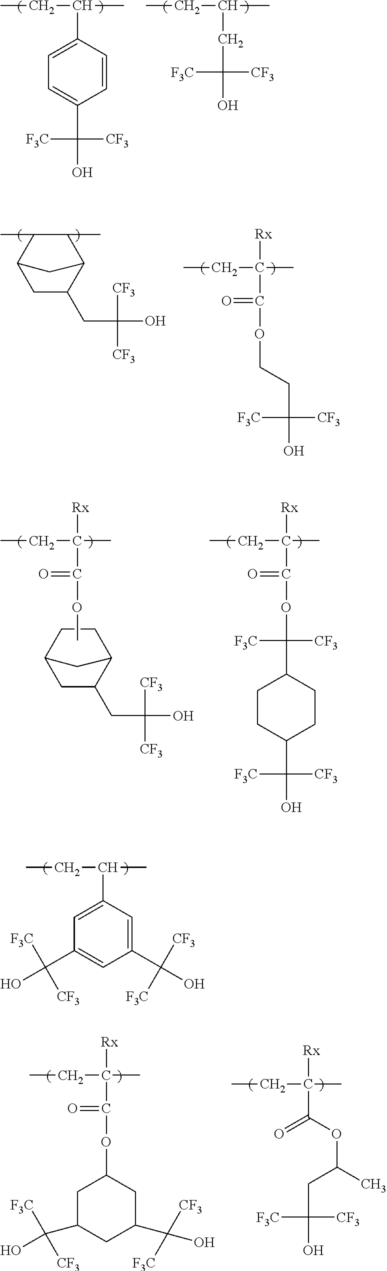

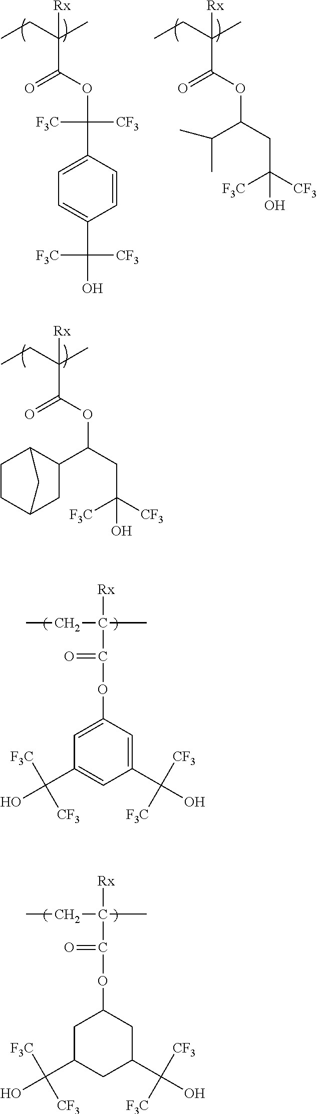

In a case where the resin (X) includes the repeating unit Y4, the content of the repeating unit Y4 is preferably 5% to 80% by mass, more preferably 5% to 70% by mass, and still more preferably 10% to 60% by mass, with respect to all the repeating units in the resin (X).

The resin (X) can be synthesized in accordance with an ordinary method (for example, radical polymerization).

The weight-average molecular weight of the resin (X) is preferably 2,500 to 30,000), more preferably 3,500 to 25,000, still more preferably 4,000 to 10,000, and particularly preferably 4,000) to 8,000. The dispersity (Mw/Mn) is usually 1.0 to 3.0, preferably 1.0 to 2.6, more preferably 1.0 to 2.0, and still more preferably 1.1 to 2.0.

The resin (X) may be used singly or in combination of two or more kinds thereof.

The content of the resin (X) in the composition of the embodiment of the present invention is generally 20% by mass or more in many cases, and is preferably 40% by mass or more, more preferably 50% by mass or more, and still more preferably 60% by mass or more, with respect to the total solid content. An upper limit thereof is not particularly limited, but is preferably 99.9% by mass or less, more preferably 99.5% by mass or less, and still more preferably 99.0% by mass or less.

<Compound that Generates Acid Upon Irradiation with Actinic Rays or Radiation>

The composition of the embodiment of the present invention includes a compound that generates an acid upon irradiation with actinic rays or radiation (hereinafter also referred to as a “photoacid generator”).

The photoacid generator may be in a form of a low molecular compound or a form incorporated into a part of a polymer. Further, a combination of the form of a low molecular compound and the form incorporated into a part of a polymer may also be used.

In a case where the photoacid generator is in the form of the low molecular compound, the molecular weight is preferably 3,000 or less, more preferably 2,000 or less, and still more preferably 1,000 or less.

In a case where the photoacid generator is included in a part of a polymer, it may be included in a part of the resin (X) or in a resin other than the resin (X).

Among those, the photoacid generator is preferably in the form of the low molecular compound.

The photoacid generator is not particularly limited as long as it is a known photoacid generator, but is preferably a compound that generates an organic acid upon irradiation with actinic rays or radiation (preferably electron beams or extreme ultraviolet rays).

As the organic acid, for example, at least one of sulfonic acid, bis(alkylsulfonyl)imide, or tris(alkylsulfonyl)methide is preferable.

As the photoacid generator, a compound represented by General Formula (ZI), General Formula (ZII), or General Formula (ZIII) is preferable.

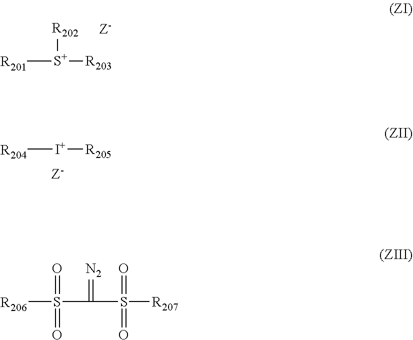

In General Formula (ZI), R₂₀₁, R₂₀₂, and R₂₀₃ each independently represent an organic group.

The number of carbon atoms in the organic group as each of R₂₀₁, R₂₀₂, and R₂₀₃ is generally 1 to 30, and preferably 1 to 20.

In addition, two of R₂₀₁, to R₂₀₃ may be bonded to each other to form a ring structure, and the ring may include an oxygen atom, a sulfur atom, an ester bond, an amide bond, or a carbonyl group. Examples of the group formed by the bonding of two of R₂₀₁ to R₂₀₃ include an alkylene group (for example, a butylene group and a pentylene group).

Z represents a non-nucleophilic anion (anion having an extremely low ability to cause a nucleophilic reaction).

Examples of the organic group of each of R₂₀₁, R₂₀₂, and R₂₀₃ include an aryl group, an alkyl group, and a cycloalkyl group.

It is preferable that at least one of R₂₀₁, R₂₀₂, or R₂₀₃ is an aryl group, and it is more preferable that all of R₂₀₁, R₂ₒ₂, or R₂₀₃ represent an aryl group. As the aryl group, not only a phenyl group, a naphthyl group, or the like but also a heteroaryl group such as an indole residue and a pyrrole residue can also be used.

As the alkyl group of each of R₂₀₁ to R₂₀₃, a linear or branched alkyl group having 1 to 10 carbon atoms is preferable, and a methyl group, an ethyl group, an n-propyl group, an i-propyl group, an n-butyl group, or the like is more preferable.

As the cycloalkyl group of each of R₂₀₁ to R₂₀₃, a cycloalkyl group having 3 to 10 carbon atoms is preferable, and a cyclopropyl group, a cyclobutyl group, a cyclopentyl group, a cyclohexyl group, or a cycloheptyl group is more preferable.

Examples of the substituent which may be contained in these groups include a nitro group, a halogen atom such as a fluorine atom, a carboxy group, a hydroxyl group, an amino group, a cyano group, an alkoxy group (preferably having 1 to 15 carbon atoms), a cycloalkyl group (preferably having 3 to 15 carbon atoms), an aryl group (preferably having 6 to 14 carbon atoms), an alkoxycarbonyl group (preferably having 2 to 7 carbon atoms), an acyl group (preferably having 2 to 12 carbon atoms), and an alkoxycarbonyloxy group (preferably having 2 to 7 carbon atoms).

Examples of the non-nucleophilic anion include a sulfonate anion (an aliphatic sulfonate anion, an aromatic sulfonate anion, a camphor sulfonate anion, and the like), a carboxylate anion (an aliphatic carboxylate anion, an aromatic carboxylae anion, an aralkyl carboxylate anion, and the like), a sulfonylimide anion, a bis(alkylsulfonyl)imide anion, and a tris(alkylsulfonyl)methide anion.

The aliphatic moiety in the aliphatic sulfonate anion and the aliphatic carboxylate anion may be either an alkyl group or a cycloalkyl group, and is preferably a linear or branched alkyl group having 1 to 30 carbon atoms or a cycloalkyl group having 3 to 30 carbon atoms.

As the aromatic group in the aromatic sulfonate anion and the aromatic carboxylate anion, an aryl group having 6 to 14 carbon atoms is preferable, and examples thereof include a phenyl group, a tolyl group, and a naphthyl group.

The alkyl group, the cycloalkyl group, and the aryl group exemplified above may have a substituent. The substituent is not particularly limited, but specific examples of the substituent include a nitro group, a halogen atom such as fluorine atom, a carboxy group, a hydroxyl group, an amino group, a cyano group, an alkoxy group (preferably having 1 to 15 carbon atoms), an alkyl group (preferably having 1 to 10 carbon atoms), a cycloalkyl group (preferably having 3 to 15 carbon atoms), an aryl group (preferably having 6 to 14 carbon atoms), an alkoxycarbonyl group (preferably having 2 to 7 carbon atoms), an acyl group (preferably having 2 to 12 carbon atoms), an alkoxycarbonyloxy group (preferably having 2 to 7 carbon atoms), an alkylthio group (preferably having 1 to 15 carbon atoms), an alkylsulfonyl group (preferably having 1 to 15 carbon atoms), an alkyliminosulfonyl group (preferably having 1 to 15 carbon atoms), and an aryloxysulfonyl group (preferably having 6 to 20 carbon atoms).

As the aralkyl group in the aralkyl carboxylate anion, an aralkyl group having 7 to 14 carbon atoms is preferable, and examples thereof include a benzyl group, a phenethyl group, a naphthylmethyl group, a naphthylethyl group, and a naphthylbutyl group.

Examples of the sulfonylimide anion include a saccharin anion.

As the alkyl group in the bis(alkylsulfonyl)imide anion and the tris(alkylsulfonyl)methide anion, an alkyl group having 1 to 5 carbon atoms is preferable. Examples of the substituent of the alkyl group include a halogen atom, an alkyl group substituted with a halogen atom, an alkoxy group, an alkylthio group, an alkyloxysulfonyl group, an aryloxysulfonyl group, and a cycloalkylaryloxysulfonyl group, and the fluorine atom or the alkyl group substituted with a fluorine atom is preferable.

In addition, the alkyl groups in the bis(alkylsulfonyl)imide anion may be bonded to each other to form a ring structure. Thus, the acid strength is increased.

Other examples of the non-nucleophilic anion include fluorinated phosphorus (for example, PF₆⁻), fluorinated boron (for example, BF₄⁻), and fluorinated antimony (for example, SbF₆⁻).

As the non-nucleophilic anion, an aliphatic sulfonate anion substituted with a fluorine atom at least at the α-position of the sulfonic acid, an aromatic sulfonate anion substituted with a fluorine atom or a fluorine atom-containing group, a bis(alkylsulfonyl)imide anion in which the alkyl group is substituted with a fluorine atom, or a tris(alkylsulfonyl)methide anion in which the alkyl group is substituted with a fluorine atom is preferable. Among those, a perfluoroaliphatic sulfonate anion (more preferably having 4 to 8 carbon atoms) or a fluorine atom-containing benzenesulfonate anion is more preferable, and a nonafluorobutanesulfonate anion, a perfluorooctanesulfonate anion, a pentafluorobenzenesulfonate anion, or a 3,5-bis(trifluoromethyl)benzenesulfonate anion is still more preferable.

From the viewpoint of the acid strength, it is preferable that the pKa of the acid generated is −1 or less so as to improve the sensitivity.

Moreover, an anion represented by General Formula (AN1) is also preferable as the non-nucleophilic anion.

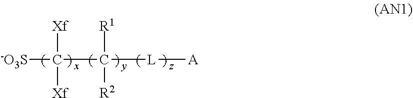

In the formula, Xf's each independently represent a fluorine atom or an alkyl group substituted with at least one fluorine atom.

R¹ and R² each independently represent a hydrogen atom, a fluorine atom, or an alkyl group, and in a case where R¹'s and R²'s are each present in plural number, R¹'s and R²'s may be the same as or different from each other.

L represents a divalent linking group, and in a case where L's are present in plural number, L's may be the same as or different from each other.

A represents a cyclic organic group.

x represents an integer of 1 to 20, y represents an integer of 0 to 10, and z represents an integer of 0 to 10.

General Formula (AN) will be described in more detail.

In an alkyl group substituted with a fluorine atom in Xf, the number of carbon atoms of the alkyl group is preferably 1 to 10, and more preferably 1 to 4. Further, as the alkyl group substituted with a fluorine atom of Xf, a perfluoroalkyl group is preferable.

As Xf, a fluorine atom or a perfluoroalkyl group having 1 to 4 carbon atoms is preferable. Examples of Xf include a fluorine atom, CF₃, C₂F₅, C₃F₇, C₄F₉, CH₁₂CF₃, CH₂CH₂CF₃, CH₂C₂F₅, CH₂CH₂C₂F₅, CH₂C₃F₇, CH₂CH₂C₃F₇, CH₂C₄F₉, and CH₂CH₂C₄F₉, and among these, the fluorine atom or CF₃ is preferable. In particular, it is preferable that both Xf's are fluorine atoms.

The alkyl group of each of R¹ and R² may contain a substituent (preferably a fluorine atom), and the number of carbon atoms is preferably 1 to 4. Among those, a perfluoroalkyl group having 1 to 4 carbon atoms is more preferable. In a case where R¹ and R² are each an alkyl group containing a substituent, examples thereof include CF₃, C₂F₅, C₃F₇, C₄F₉, C₅F₁₁, C₆F₁₃, C₇F₁₅, C₈F₁₇, CH₂CF₃, CH₂CH₂CF₃, CH₂C₂F₅, CH₂CH₂C₂F₅, CH₂C₃F₇, CH₂CH₂C₃F₇, CH₂C₄F₉, and CH₂CH₂C₄F₉, and among these, CF₃ is preferable.

As R¹ and R², a fluorine atom or CF₃ is more preferable.

x is preferably 1 to 10, and more preferably 1 to 5.

y is preferably 0 to 4, and more preferably 0.

z is preferably 0 to 5, and more preferably 0 to 3.

The divalent linking group of L is not particularly limited and examples thereof include —COO—, —OCO—, —CO—, —O—, —S—, —SO—, —SO₂—, an alkylene group, a cycloalkylene group, an alkenylene group, and a linking group formed by combination of a plurality of these groups. A linking group having a total number of carbon atoms of 12 or less is preferable. Among those, —COO—, —OCO—, —CO—, or —O— is preferable, and —COO— or —OCO— is more preferable.

The cyclic organic group of A is not particularly limited as long as it has a cyclic structure, and examples thereof include an alicyclic group, an aryl group, and a heterocyclic group (including not only those having aromaticity but also those having no aromaticity).

The alicyclic group may be monocyclic or polycyclic and is preferably a monocyclic cycloalkyl group such as a cyclopentyl group, a cyclohexyl group, and a cyclooctyl group, or a polycyclic cycloalkyl group such as a norbornyl group, a tricyclodecanyl group, a tetracyclodecanyl group, a tetracyclododecanyl group, and an adamantyl group. Among those, an alicyclic group having a bulky structure having 7 or more carbon atoms, such as a norbornyl group, a tricyclodecanyl group, a tetracyclodecanyl group, a tetracyclododecanyl group, and an adamantyl group, is preferable in view that the diffusibility of the photoacid generator in the film in a heating step after exposure can be suppressed and mask error enhancement factor (MEEF) is further improved.

Examples of the aromatic ring group include a benzene ring, a naphthalene ring, a phenanthrene ring, and an anthracene ring.

Examples of the heterocyclic group include those derived from a furan ring, a thiophene ring, a benzofuran ring, a benzothiophene ring, a dibenzofuran ring, a dibenzothiophene ring, and a pyridine ring. Among those, heterocyclic groups derived from a furan ring, a thiophene ring and a pyridine ring are preferable.

Moreover, examples of the cyclic organic group include a lactone structure, and specific examples thereof include lactone structures represented by General Formulae (LC1-1) to (LC1-17).

The cyclic organic group may have a substituent. Examples of the substituent include an alkyl group (which may be in any one of linear, branched, and cyclic forms, and preferably has 1 to 12 carbon atoms), a cycloalkyl group (which may be either a monocycle or a polycycle, and in a case of the polycycle, may be a spiro ring, and which preferably has 3 to 20 carbon atoms), an aryl group (preferably having 6 to 14 carbon atoms), a hydroxyl group, an alkoxy group, an ester group, an amido group, a urethane group, a ureido group, a thioether group, a sulfonamido group, and a sulfonic acid ester group. Incidentally, the carbon constituting the cyclic organic group (the carbon contributing to ring formation) may be a carbonyl carbon.

In General Formula (ZII) and General Formula (ZIII), R₂₀₄ to R₂₀₇ each independently represent an aryl group, an alkyl group, or a cycloalkyl group.

The aryl group, the alkyl group, and the cycloalkyl group of each of R₂₀₄ to R₂₀₇ are the same as the groups described as the aryl group, the alkyl group, and the cycloalkyl group of each of R₂₀₁ to R₂₀₃, respectively, in General Formula (ZI).

The substituents which may be contained in the aryl group, the alkyl group, and the cycloalkyl group of each of R₂ to R₂₀₇ are the same as the substituents which may be contained in the aryl group, the alkyl group, and the cycloalkyl group of each of R₂₀₁ to R₂₀₃ in General Formula (ZI), and suitable aspects thereof are also the same.

Z⁻ represents a non-nucleophilic anion and has the same definition as Z⁻ in General Formula (ZI), and suitable aspects thereof are also the same.

Moreover, from the viewpoint that the diffusion of an acid generated upon exposure to the unexposed area is suppressed to improve a resolution, the photoacid generator is preferably a compound that generates an acid (more preferably sulfonic acid) having a volume of 130 Å³ or more upon irradiation with electron beams or extreme ultraviolet rays. Among those, the photoacid generator is more preferably a compound that generates an acid (more preferably sulfonic acid) having a volume of 190 Å³ or more, still more preferably a compound that generates an acid (more preferably sulfonic acid) having a volume of 270 Å³ or more, and particularly preferably a compound that generates an acid (more preferably sulfonic acid) having a volume of 400 Å³ or more. Meanwhile, from the viewpoint of the sensitivity or the solubility of a coating solvent, the volume is preferably 2,000 Å³ or less, and more preferably 1,500 Å³ or less. In addition, a value of the volume is obtained using “WinMOPAC” manufactured by FUJITSU.

In the calculation of a value of the volume, first, the chemical structure of an acid according to each example is input, the most stable steric conformation of each acid is then determined through a molecular field calculation using a molecular mechanics (MM) 3 method with the input chemical structure as an initial structure, and then, molecular orbital calculation is carried out on the most stable steric conformation using a PM3 method, whereby an “accessible volume” of each acid can be calculated.

Specific examples of an acid (an acid in which a proton is bonded to an anion moiety) generated by the photoacid generator and a volume thereof are set forth below, but the present invention is not limited thereto. In addition, the volumes shown in the following examples are computed values (unit: Å³). In addition, 1 Å is 1×10⁻¹⁰ m.

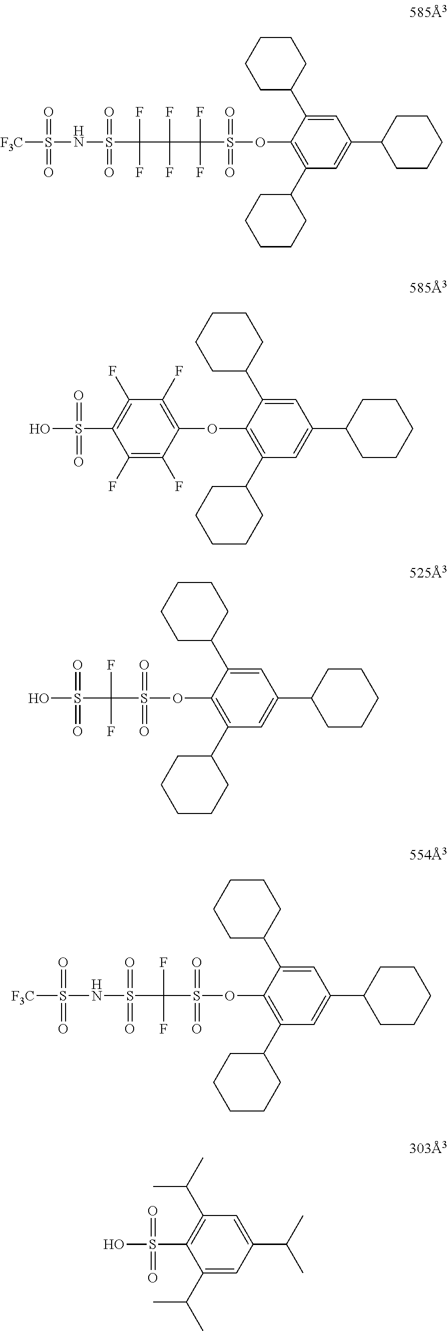

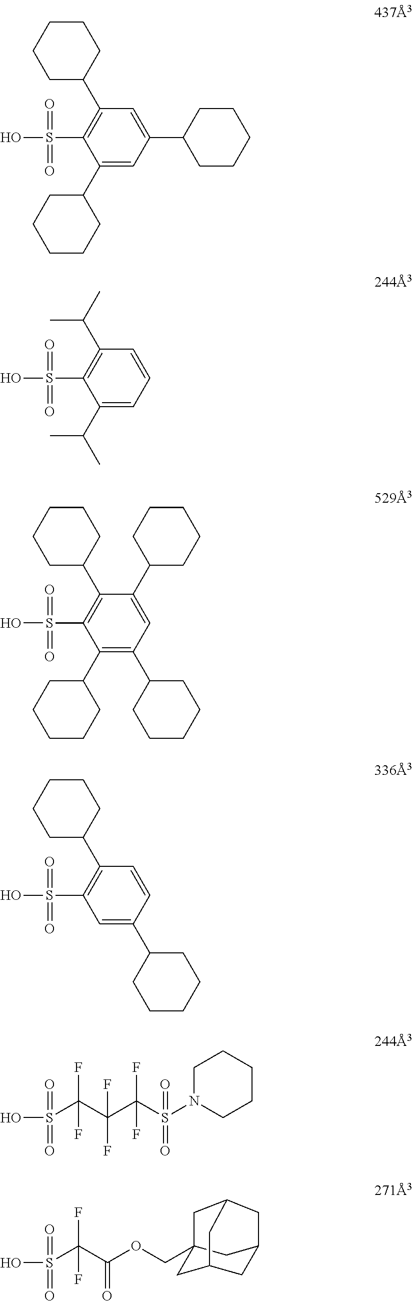

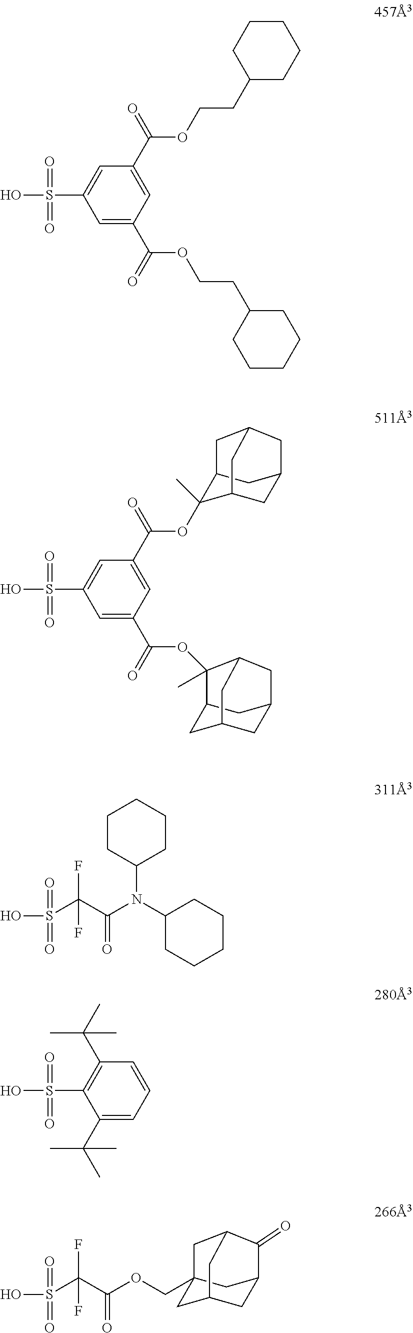 [SMILES: O=C(OCCC1CCCCC1)c1cc(C(=O)OCCC2CCCCC2)cc(S(=O)(=O)O)c1 ; CC1(OC(=O)c2cc(C(=O)OC3(C)C4CC5CC(C4)CC3C5)cc(S(=O)(=O)O)c2)C2CC3CC(C2)CC1C3 ; O=C(N(C1CCCCC1)C1CCCCC1)C(F)(F)S(=O)(=O)O ; CC(C)(C)c1cccc(C(C)(C)C)c1S(=O)(=O)O ; O=C1C2CC3CC1CC(COC(=O)C(F)(F)S(=O)(=O)O)(C3)C2]

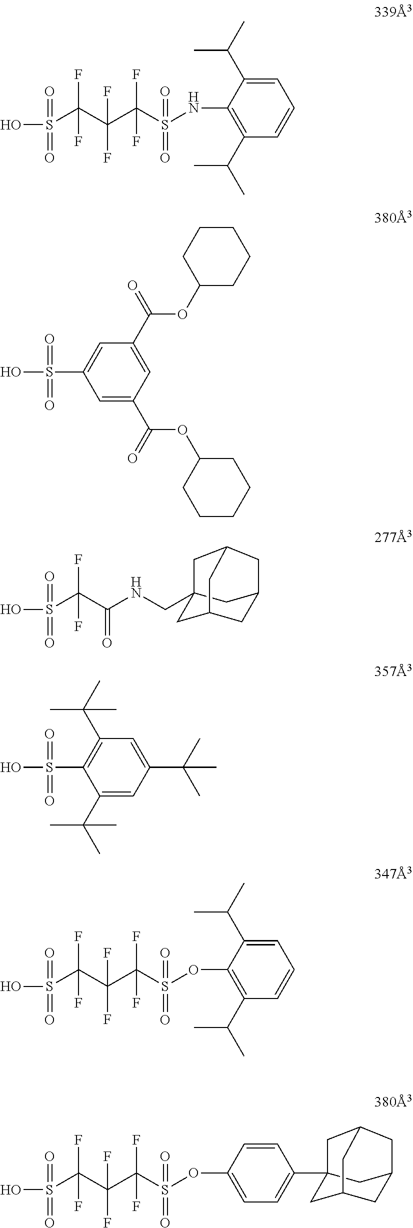

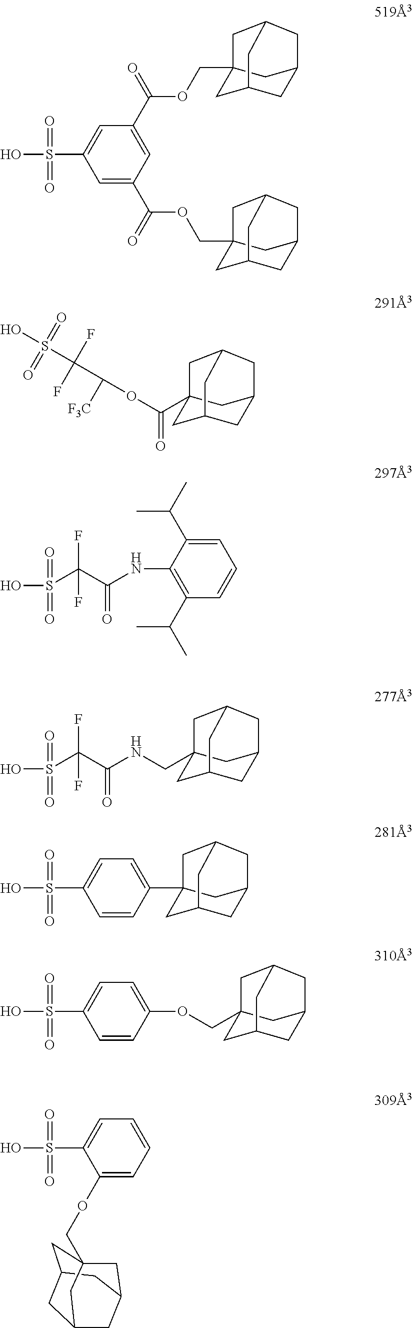

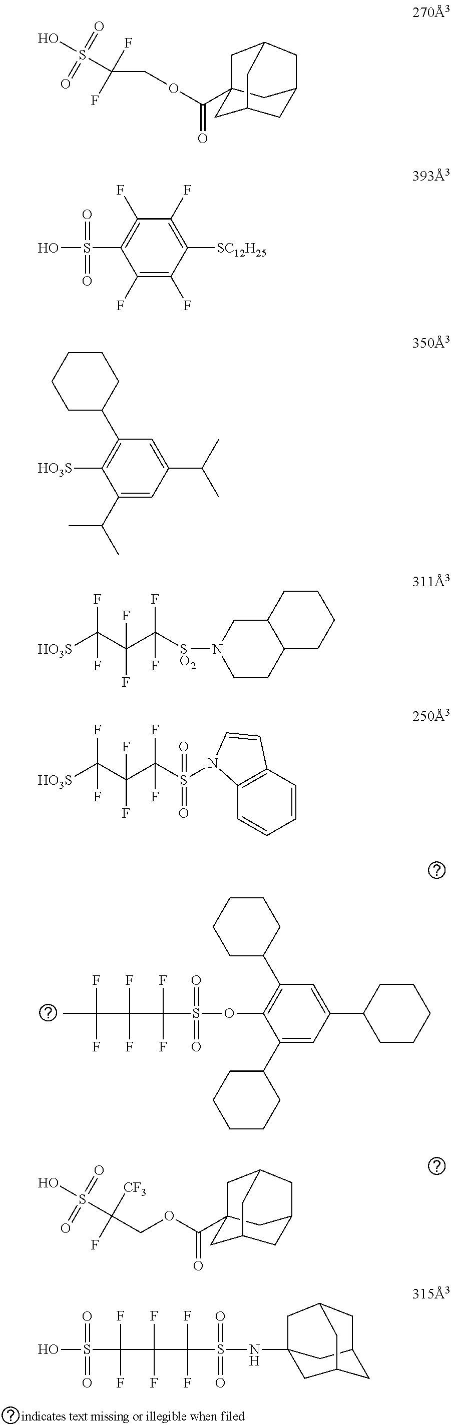

With regard to the photoacid generator, reference can be made to paragraphs <0368> to <0377> of JP2014-041328A and paragraphs <0240> to <0262> of JP2013-228681A (corresponding to paragraph <0339> of US2015/0004533A), the contents of which are incorporated herein by reference. In addition, specific preferred examples of the photoacid generator include, but are not limited to, the following compounds.

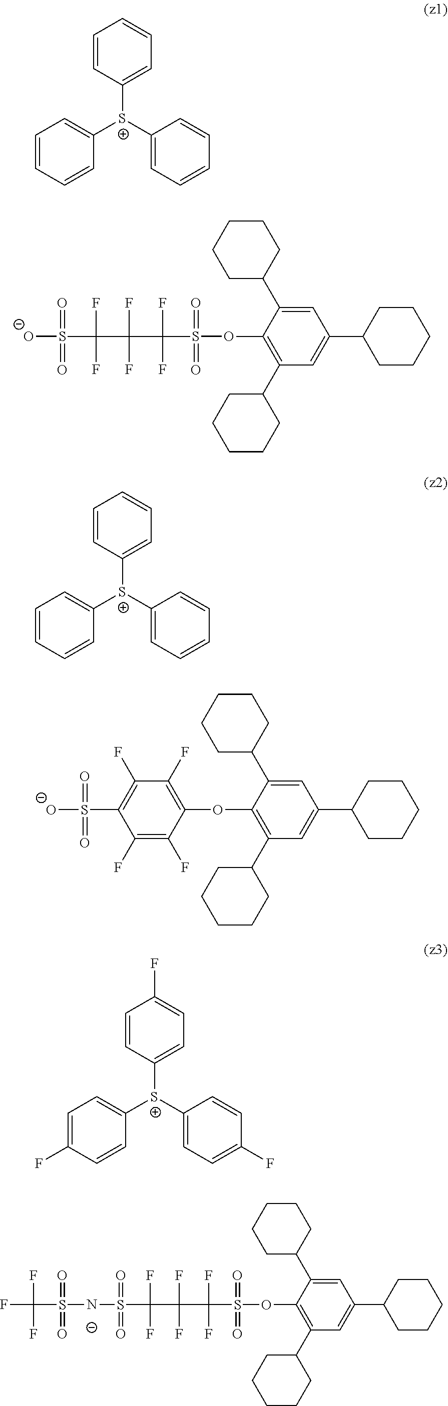 [SMILES: c1ccc([S+](c2ccccc2)c2ccccc2)cc1 ; O=S(=O)([O-])C(F)(F)C(F)(F)C(F)(F)S(=O)(=O)Oc1c(C2CCCCC2)cc(C2CCCCC2)cc1C1CCCCC1 ; c1ccc([S+](c2ccccc2)c2ccccc2)cc1 ; O=S(=O)([O-])c1c(F)c(F)c(Oc2c(C3CCCCC3)cc(C3CCCCC3)cc2C2CCCCC2)c(F)c1F ; Fc1ccc([S+](c2ccc(F)cc2)c2ccc(F)cc2)cc1 ; O=S(=O)(NS(=O)(=O)C(F)(F)C(F)(F)C(F)(F)S(=O)(=O)Oc1c(C2CCCCC2)cc(C2CCCCC2)cc1C1CCCCC1)C(F)(F)F]

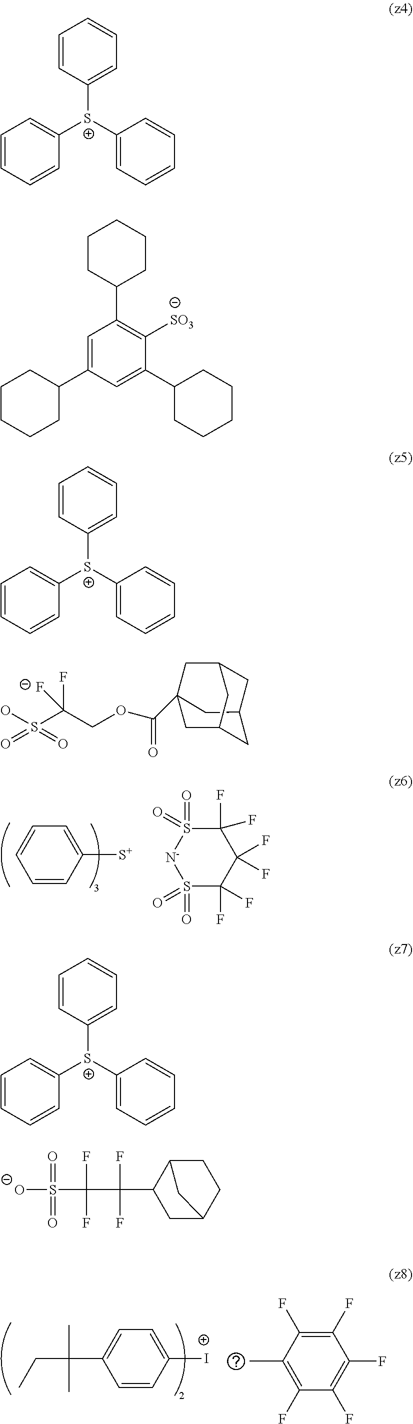

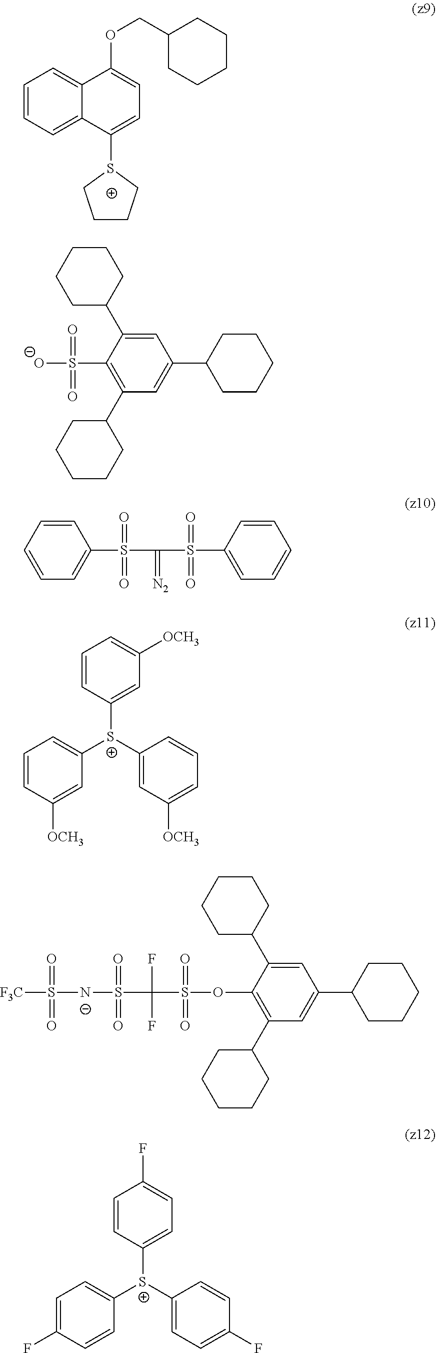

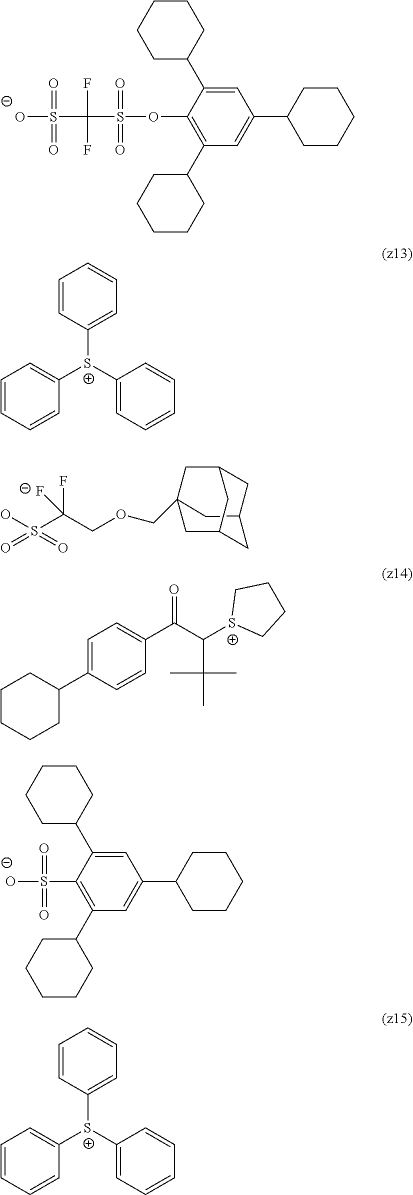

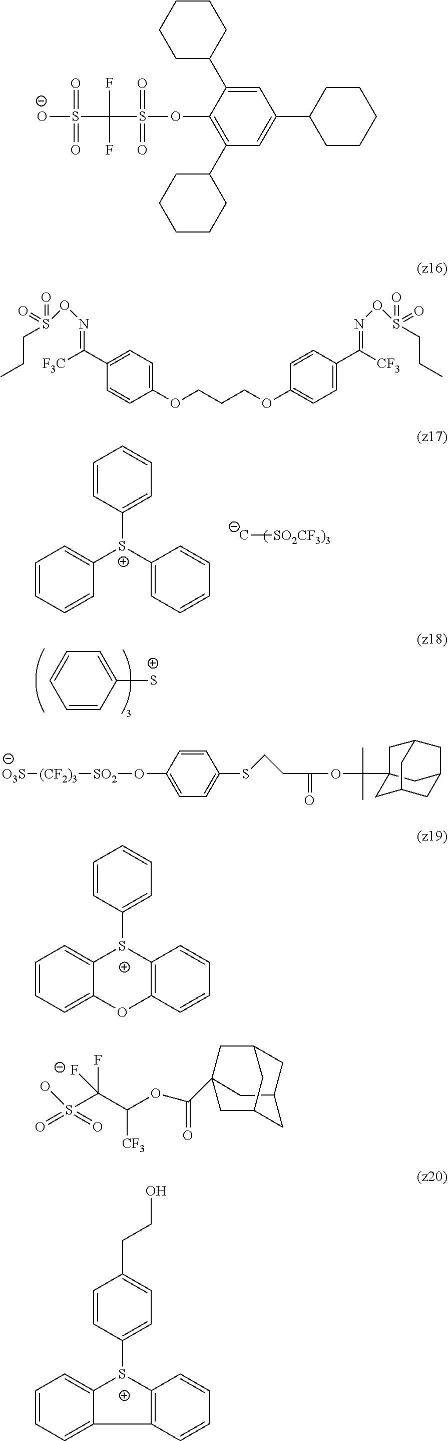

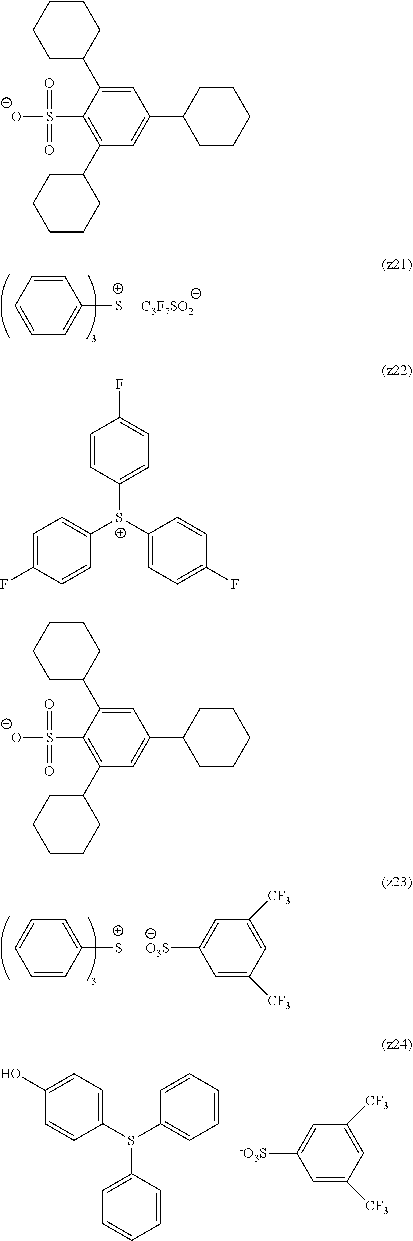

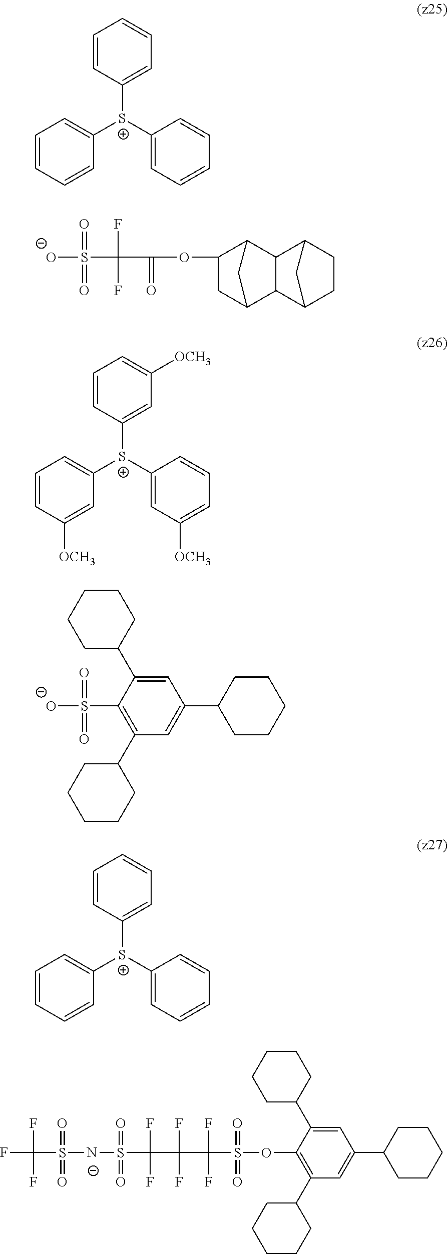 [SMILES: c1ccc([S+](c2ccccc2)c2ccccc2)cc1 ; O=C(OC1CC2CC1C1C3CCC(C3)C21)C(F)(F)S(=O)(=O)[O-] ; COc1cccc([S+](c2cccc(OC)c2)c2cccc(OC)c2)c1 ; O=S(=O)([O-])c1c(C2CCCCC2)cc(C2CCCCC2)cc1C1CCCCC1 ; c1ccc([S+](c2ccccc2)c2ccccc2)cc1 ; O=S(=O)([N-]S(=O)(=O)C(F)(F)C(F)(F)C(F)(F)S(=O)(=O)Oc1c(C2CCCCC2)cc(C2CCCCC2)cc1C1CCCCC1)C(F)(F)F]

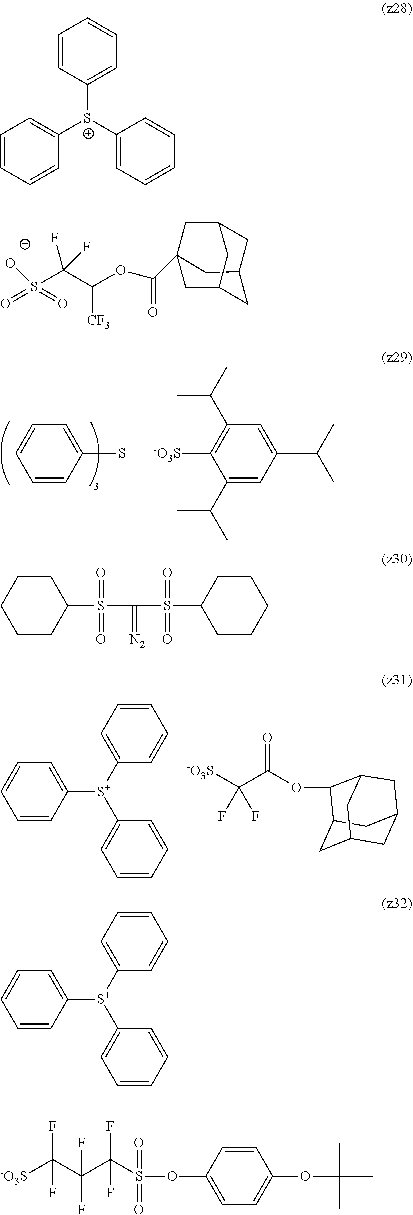

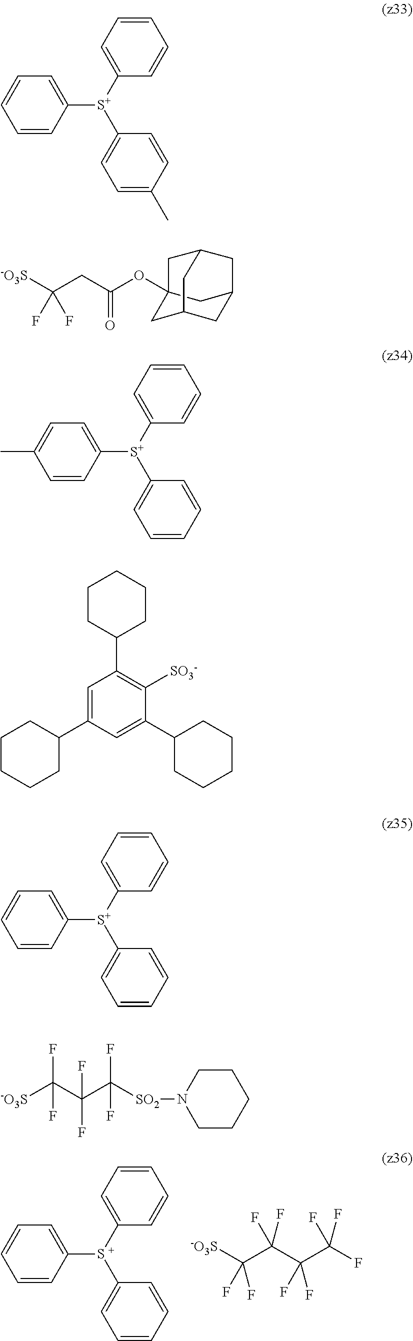

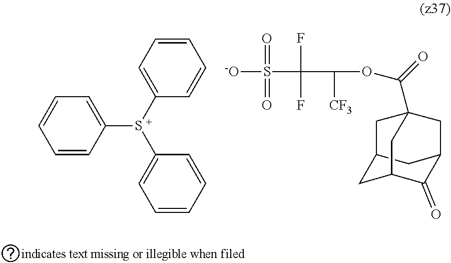

The photoacid generators may be used singly or in combination of two or more kinds thereof.

The content of the photoacid generator (a total content in a case where the acid diffusion control agents (D) are present in plural number) in the composition of the embodiment of the present invention is preferably 0.1% to 50% by mass, more preferably 5% to 40% by mass, and still more preferably 5% to 35% by mass, with respect to the total solid content of the composition.

<Acid Diffusion Control Agent>

The composition of the embodiment of the present invention preferably includes an acid diffusion control agent. The acid diffusion control agent acts as a quencher that suppresses a reaction of the acid-decomposable resin in the unexposed area by excessive generated acids by trapping the acids generated from a photoacid generator and the like upon exposure. For example, a basic compound (DA), a compound (DB) whose basicity is reduced or lost upon irradiation with actinic rays or radiation, or the like can be used as the acid diffusion control agent.

As the basic compound (DA), compounds having structures represented by Formulae (A) to (E) are preferable.

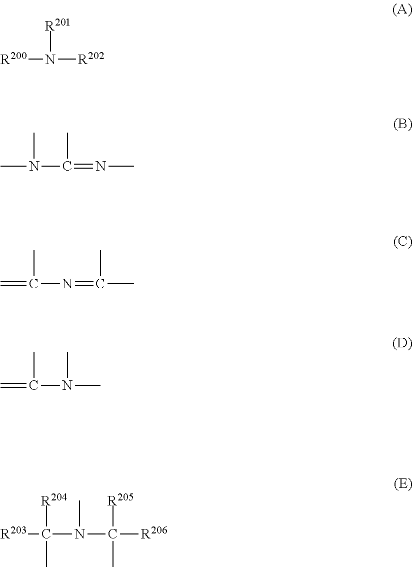

In General Formula (A), R²⁰⁰, R²⁰¹, and R²⁰² each independently represent a hydrogen atom, an alkyl group (preferably having 1 to 20 carbon atoms), a cycloalkyl group (preferably having 3 to 20 carbon atoms), or an aryl group (having 6 to 20 carbon atoms), and R₂₀₁ and R²⁰² may be bonded to each other to form a ring.

In General Formula (E), R²⁰³, R²⁰⁴, R²⁰⁵, and R²⁰⁶ each independently represent an alkyl group having 1 to 20 carbon atoms.

The alkyl group in each of General Formulae (A) and (E) may have a substituent or may be unsubstituted.

With regard to the alkyl group, the alkyl group having a substituent is preferably an aminoalkyl group having 1 to 20 carbon atoms, a hydroxyalkyl group having 1 to 20 carbon atoms, or a cyanoalkyl group having 1 to 20 carbon atoms.

The alkyl group in each of General Formulae (A) and (E) is more preferably unsubstituted.

As the basic compound (DA), guanidine, aminopyrrolidine, pyrazole, pyrazoline, piperazine, aminomorpholine, aminoalkylmorpholine, piperidine, or the like is preferable; and a compound having an imidazole structure, a diazabicyclo structure, an onium hydroxide structure, an onium carboxylate structure, a trialkylamine structure, an aniline structure, or a pyridine structure, an alkylamine derivative having a hydroxyl group and/or an ether bond, and an aniline derivative having a hydroxyl group and/or an ether bond, or the like is more preferable.

Examples of the compound having an imidazole structure include imidazole, 2,4,5-triphenylimidazole, and benzimidazole.

Examples of the compound having a diazabicyclo structure include 1,4-diazabicyclo[2,2,2]octane, 1,5-diazabicyclo[4,3,0]non-5-ene, and 1,8-diazabicyclo[5,4,0]undec-7-ene.

Examples of the compound having an onium hydroxide structure include triarylsulfonium hydroxide, phenacylsulfonium hydroxide, and sulfonium hydroxide having a 2-oxoalkyl group. Specific examples thereof include triphenylsulfonium hydroxide, tris(t-butylphenyl)sulfonium hydroxide, bis(t-butylphenyl)iodonium hydroxide, phenacylthiophenium hydroxide, and 2-oxopropylthiophenium hydroxide.

The compound having an onium carboxylate structure is formed by carboxylation of an anionic moiety of a compound having an onium hydroxide structure, and examples thereof include acetate, adamantane-1-carboxylate, and perfluoroalkyl carboxylate.

Examples of the compound having a trialkylamine structure include tri(n-butyl)amine and tri(n-octyl)amine.

Examples of the aniline compound include 2,6-diisopropylaniline, N,N-dimethylaniline, N,N-dibutylaniline, and N,N-dihexylaniline.

Examples of the alkylamine derivative having a hydroxyl group and/or an ether bond include ethanolamine, diethanolamine, triethanolamine, and tris(methoxyethoxyethyl)amine.

Examples of the aniline derivative having a hydroxyl group and/or an ether bond include N,N-bis(hydroxyethyl)aniline.

Moreover, a superorganic base can also be used as the basic compound (DA).

Examples of the superorganic base include guanidine bases (including guanidine and guanidine derivatives such as substituted forms thereof and polyguanides), amidine-based and guanidine-based polynitrogen polyheterocyclic compounds and polymer-supported strong bases thereof, typified by diazabicyclononene (DBN), diazabicycloundecene (DBU), triazabicyclodecene (TBD), N-methyltriazabicyclodecene (MTBD), and the like, phosphazene-based (Schweisinger) bases, and proazaphosphatran (Verkade) bases.

Moreover, as the basic compound (DA), an amine compound and an ammonium salt compound can also be used.

Examples of the amine compound include primary, secondary, and tertiary amine compounds, and the amine compound is preferably an amine compound in which at least one or more alkyl groups (preferably having 1 to 20 carbon atoms) are bonded to nitrogen atoms, and more preferably the tertiary amine compound among those.

Furthermore, in a case where the amine compound is the secondary or tertiary amine compound, examples of a group bonded to the nitrogen atom in the amine compound include, in addition to the above-mentioned alkyl groups, a cycloalkyl group (preferably having 3 to 20 carbon atoms) and an aryl group (preferably having 6 to 12 carbon atoms).

In addition, the amine compound preferably includes an oxyalkylene group. The number of the oxyalkylene groups contained in the amine compounds within the molecule is preferably 1 or more, more preferably 3 to 9, and still more preferably 4 to 6. Among those oxyalkylene groups, an oxyethylene group (—CH₂CH₂O—) or an oxypropylene group (—CH(CH₃)CH₂O— or —CH₂CH₂CH₂O—) is preferable, and the oxyethylene group is more preferable.

Examples of the ammonium salt compound include primary, secondary, tertiary, and quaternary ammonium salt compounds, and an ammonium salt compound in which at least one or more alkyl groups are bonded to nitrogen atoms is preferable.

Furthermore, in a case where the ammonium salt compound is a secondary, tertiary, or quaternary ammonium salt compound, examples of a group which is bonded to a nitrogen atom in the ammonium salt compound include, in addition to the above-mentioned alkyl groups, a cycloalkyl group (preferably having 3 to 20 carbon atoms) and an aryl group (preferably having 6 to 12 carbon atoms).

In addition, the ammonium salt compound preferably has an oxyalkylene group. The number of the oxyalkylene groups contained in the ammonium salt compound is preferably 1 or more, more preferably 3 to 9, and still more preferably 4 to 6 within the molecule. Among those oxyalkylene groups, an oxyethylene group (—CH₂CH₂O—) or an oxypropylene group (—CH(CH)CH₂O— or —CH₂CH₂CH₂O—) is preferable, and the oxyethylene group is more preferable.

Examples of the anion of the ammonium salt compound include a halogen atom, a sulfonate, a borate, and a phosphate, and among these, the halogen atom or the sulfonate is preferable.

As the halogen atom, a chlorine atom, a bromine atom, or an iodine atom is preferable.

As the sulfonate, an organic sulfonate having 1 to 20 carbon atoms is preferable, and preferred specific examples thereof include alkyl sulfonate and aryl sulfonate, having 1 to 20 carbon atoms. The alkyl group of the alkyl sulfonate may have a substituent, and examples of the substituent include a fluorine atom, a chlorine atom, a bromine atom, an alkoxy group, an acyl group, and an aromatic ring group. Examples of the alkyl sulfonate include methanesulfonate, ethanesulfonate, butanesulfonate, hexanesulfonate, octanesulfonate, benzyl sulfonate, trifluoromethanesulfonate, pentafluoroethanesulfonate, and nonafluorobutanesulfonate. In addition, examples of the aryl group of the aryl sulfonate include a benzene ring group, a naphthalene ring group, and an anthracene ring group. As the substituent which can be contained in the benzene ring group, the naphthalene ring group, and the anthracene ring group, a linear or branched alkyl group having 1 to 6 carbon atoms (which may be linear or branched) or a cycloalkyl group having 3 to 6 carbon atoms is preferable. Specific examples of the alkyl group and the cycloalkyl group include a methyl group, an ethyl group, an n-propyl group, an isopropyl group, an n-butyl group, an isobutyl group, a t-butyl group, an n-hexyl group, and a cyclohexyl group.

The alkyl group and the cycloalkyl group may further have another substituent, and examples of such another substituent include an alkoxy group having 1 to 6 carbon atoms, a halogen atom, a cyano group, a nitro group, an acyl group, and an acyloxy group.

Moreover, as the basic compound (DA), an amine compound having a phenoxy group or an ammonium salt compound having a phenoxy group can also be used.

The amine compound having a phenoxy group and the ammonium salt compound having a phenoxy group are each a compound having a phenoxy group at the terminal on the opposite side to the nitrogen atom of the alkyl group which is contained in the amine compound or the ammonium salt compound.

Examples of a substituent of the phenoxy group include an alkyl group, an alkoxy group, a halogen atom, a cyano group, a nitro group, a carboxyl group, a carboxylic acid ester group, a sulfonic acid ester group, an aryl group, an aralkyl group, an acyloxy group, and an aryloxy group. The substitution position of the substituent may be any of 2- to 6-positions. The number of the substituents may be any one of 1 to 5.

This compound preferably has at least one oxyalkylene group between the phenoxy group and the nitrogen atom. The number of the oxyalkylene groups within the molecule is preferably 1 or more, more preferably 3 to 9, and still more preferably 4 to 6. Among oxyalkylene groups, an oxyethylene group (—CH₂CH₂O—) or an oxypropylene group (—CH(CH)CH₂O— or —CH₂CH₂CH₂O—) is preferable, and the oxyethylene group is more preferable.

The amine compound having a phenoxy group can be obtained by heating a mixture of a primary or secondary amine having a phenoxy group and a haloalkyl ether to perform a reaction, then adding an aqueous solution of a strong base (for example, sodium hydroxide, potassium hydroxide, and tetraalkylammonium) to a reaction system, and extracting the reaction product with an organic solvent (for example, ethyl acetate and chloroform). Alternatively, the amine compound having a phenoxy group can also be obtained by heating a mixture of a primary or secondary amine and a haloalkyl ether having a phenoxy group at the terminal to perform a reaction, then adding an aqueous solution of a strong base to the reaction system, and extracting the reaction product with an organic solvent.

The compound (DB) whose basicity is reduced or lost upon irradiation with actinic rays or radiation (hereinafter also referred to as a “compound (DB)”) is a compound which has a proton-accepting functional group, and decomposes under irradiation with actinic rays or radiation to exhibit deterioration in proton-accepting properties, no proton-accepting properties, or a change from the proton-accepting properties to acidic properties.

The proton-accepting functional group refers to a functional group having a group or an electron which is capable of electrostatically interacting with a proton, and for example, means a functional group with a macrocyclic structure, such as a cyclic polyether, or a functional group having a nitrogen atom having an unshared electron pair not contributing to π-conjugation. The nitrogen atom having an unshared electron pair not contributing to π-conjugation is, for example, a nitrogen atom having a partial structure represented by the following general formula.

[symbol] [symbol] [symbol] Unshared electron pair

Preferred examples of the partial structure of the proton-accepting functional group include a crown ether structure, an azacrown ether structure, primary to tertiary amine structures, a pyridine structure, an imidazole structure, and a pyrazine structure.

The compound (DB) decomposes upon irradiation with actinic rays or radiation to generate a compound exhibiting deterioration in proton-accepting properties, no proton-accepting properties, or a change from the proton-accepting properties to acidic properties. Here, exhibiting deterioration in proton-accepting properties, no proton-accepting properties, or a change from the proton-accepting properties to acidic properties means a change of proton-accepting properties due to the proton being added to the proton-accepting functional group, and specifically a decrease in the equilibrium constant at chemical equilibrium in a case where a proton adduct is generated from the compound (DB) having the proton-accepting functional group and the proton.

The proton-accepting properties can be confirmed by performing pH measurement.

With regard to specific examples of the compound (DB), reference can be made to those described in paragraphs <0421> to <0428> of JP2014-041328A or paragraphs <0108> to <0116> of JP2014-134686A, the contents of which are incorporated herein by reference. Specific examples of the basic compound (DA) and the compound (DB) are set forth below, but the present invention is not limited.

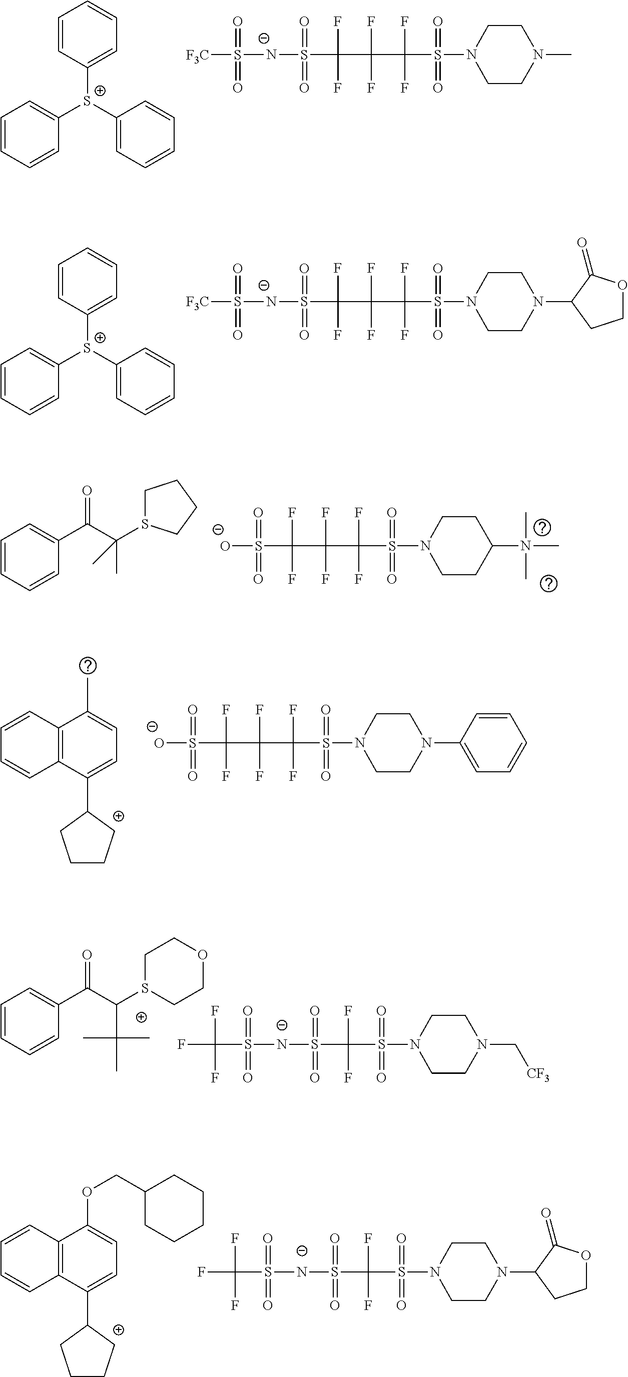

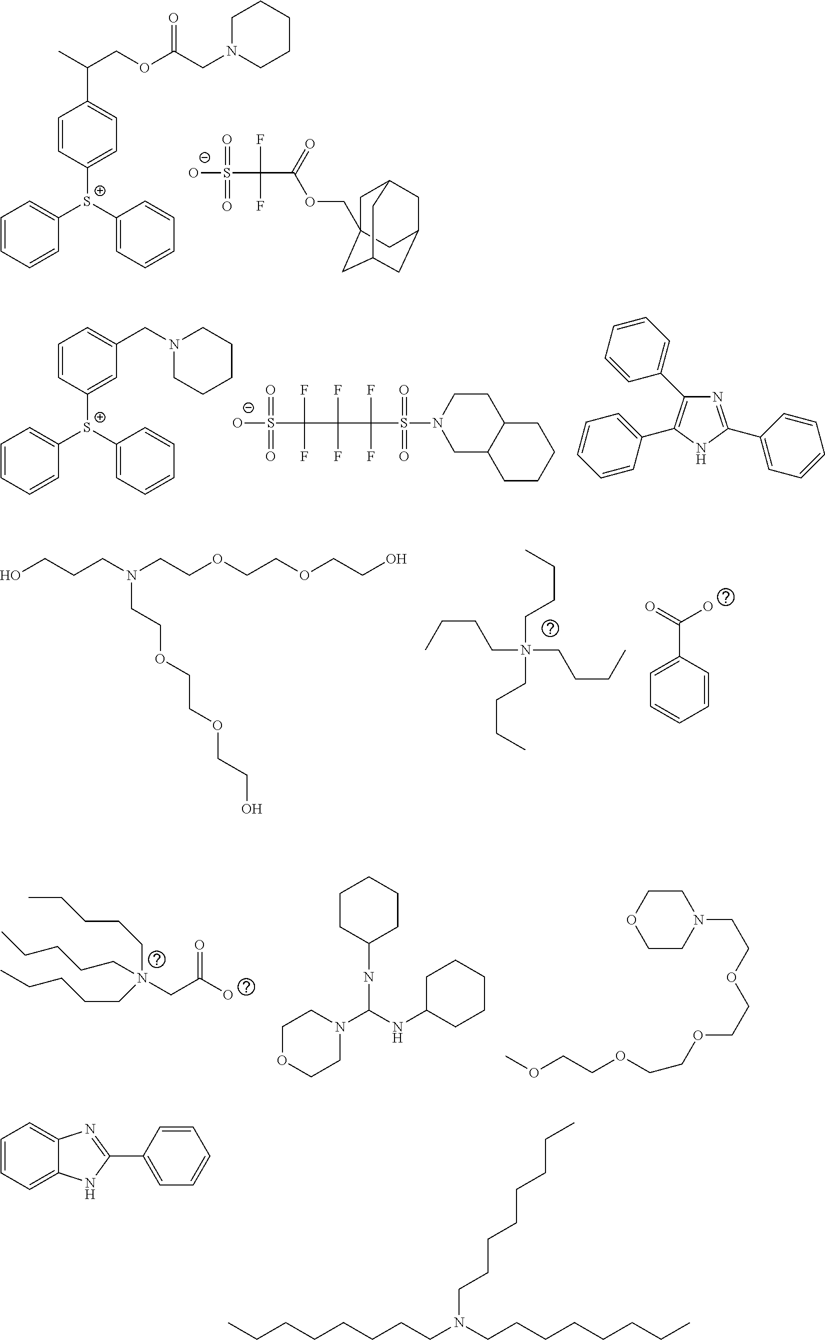

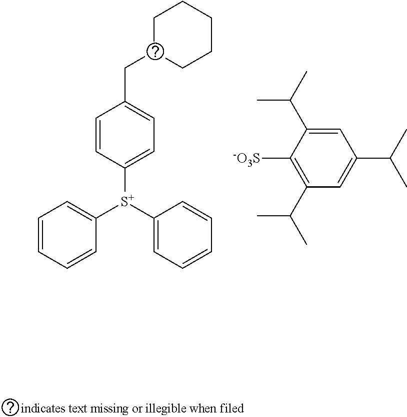

The acid diffusion control agents may be used singly or in combination of two or more kinds thereof.

The content of the acid diffusion control agent (a total content in a case where the acid diffusion control agents are present in plural number) in the composition of the embodiment of the present invention is preferably 0.001% to 10% by mass, and more preferably 0.01% to 7% by mass, with respect to the total solid content of the composition.

Moreover, as the acid diffusion control agent, for example, the compounds (amine compounds, amido group-containing compounds, urea compounds, nitrogen-containing heterocyclic compounds, and the like) described in paragraphs <0140> to <0144> of JP2013-011833A can also be used.

<Surfactant>

The composition of the embodiment of the present invention may include a surfactant. By incorporating the surfactant into the composition of the embodiment of the present invention, it becomes possible to provide a resist pattern having improved adhesiveness and decreased development defects with good sensitivity and resolution in a case where an exposure light source of 250 nm or less, and particularly 220 nm or less is used.

As the surfactant, fluorine-based and/or silicone-based surfactants are preferable.

Examples of the fluorine-based and/or silicone-based surfactants include the surfactants described in paragraph <0276> in US2008/0248425A. In addition, EFTOP EF301 and EF303 (manufactured by Shin-Akita Chemical Co., Ltd.): FLUORAD FC430, 431, and 4430 (manufactured by Sumitomo 3M Inc.); MEGAFACE F171, F173, F176, F189, F113, F110, F177, F120, and R08 (manufactured by DIC Corp.); SURFLON S-382, SC101, 102, 103, 104, 105, and 106 (manufactured by Asahi Glass Co., Ltd.), TROYSOL S-366 (manufactured by Troy Chemical Corp.); GF-300 and GF-150 (manufactured by Toagosei Chemical Industry Co., Ltd.); SURFLON S-393 (manufactured by Seimi Chemical Co., Ltd.); EFTOP EF121, EF122A, EF122B, RF122C, EF125M, EF135M, EF351, EF352, EF801, EF802, and EF601 (manufactured by JEMCO Inc.); PF636, PF656, PF6320, and PF6520 (manufactured by OMNOVA Solutions Inc.); KH-20 (manufactured by Asahi Kasei Co., Ltd.); or FTX-204G, 208G, 218G, 230G, 204D, 208D, 212D, 218D, and 222D (manufactured by NEOS Co., Ltd.) may be used. In addition, a polysiloxane polymer KP-341 (manufactured by Shin-Etsu Chemical Co., Ltd.) can also be used as the silicone-based surfactant.

Moreover, in addition to the known surfactants as shown above, a surfactant may be synthesized using a fluoro aliphatic compound manufactured using a telomerization method (also referred to as a telomer method) or an oligomerization method (also referred to as an oligomer method). Specifically, a polymer including a fluoro aliphatic group derived from fluoro aliphatic compound may be used as the surfactant. This fluoro aliphatic compound can be synthesized, for example, by the method described in JP2002-090991A.

In addition, a surfactant other than the fluorine-based surfactant and/or the silicone-based surfactants described in <0280> of US2008/0248425A may be used.

These surfactants may be used singly or in combination of two or more kinds thereof.

The content of the surfactant in the composition of the embodiment of the present invention is 0.0001% to 2% by mass, and more preferably 0.0005% to 1% by mass, with respect to the total solid content of the composition.

<Solvent>

The composition of the embodiment of the present invention may include a solvent.

The solvent preferably includes at least any one of the following component (M1) or the following component (M2), and among these, the solvent more preferably includes the following component (M1).

In a case where the solvent includes the following component (M1), it is preferable that the solvent is substantially formed of the component (M1) or is a mixed solvent including at least the component (M1) and the component (M2).

Hereinafter, the component (M1) and the component (M2) will be shown.

Component (M1): Propylene glycol monoalkyl ether carboxylate

Component (M2): A solvent selected from the following component (M2-1) or a solvent selected from the following component (M2-1)

Component (M2-1): Propylene glycol monoalkyl ether, lactic acid ester, acetic acid ester, butyl butyrate, alkoxypropionic acid ester, chained ketone, cyclic ketone, lactone, or alkylene carbonate

Component (M2-2): A solvent having a flash point of (hereinafter also referred to as a fp) of 37° C. or higher.

In case where the solvent and the above-mentioned resin (X) are used in combination, the coatability of the composition is improved and a pattern having a less number of development defects is obtained. Although a reason therefor is not necessarily clear, it is considered that the solvent has a good balance among the solubility, the boiling point, and the viscosity of the above-mentioned resin (X), and therefore, unevenness in the film thickness of a resist film, generation of precipitates during spin coating, and the like can be suppressed.

As the component (M1), at least one selected from the group consisting of propylene glycol monomethyl ether acetate (PGMEA), propylene glycol monomethyl ether propionate, and propylene glycol monoethyl ether acetate is preferable, and the propylene glycol monomethyl ether acetate (PGMEA) is more preferable.

As the component (M2-1), the following ones are preferable.

As the propylene glycol monoalkyl ether, propylene glycol monomethyl ether (PGME) or propylene glycol monoethyl ether is preferable.

As the lactic acid ester, ethyl lactate, butyl lactate, or propyl lactate is preferable.

As the acetic acid ester, methyl acetate, ethyl acetate, butyl acetate, isobutyl acetate, propyl acetate, isoamyl acetate, methyl formate, ethyl formate, butyl formate, propyl formate, or 3-methoxybutyl formate is preferable.

As the alkoxy propionic acid ester, methyl 3-methoxypropionate (MMP), or ethyl 3-ethoxypropionate (EEP) is preferable.

As the chained ketone, 1-octanone, 2-octanone, 1-nonanone, 2-nonanone, acetone, 2-heptanone, 4-heptanone, 1-hexanone, 2-hexanone, diisobutyl ketone, phenyl acetone, methyl ethyl ketone, methyl isobutyl ketone, acetyl acetone, acetonyl acetone, ionone, diacetonyl alcohol, acetyl carbinol, acetophenone, methyl naphthyl ketone, or methyl amyl ketone is preferable.

As the cyclic ketone, methyl cyclohexanone, isophorone, or cyclohexanone is preferable.

As the lactone, γ-butyrolactone is preferable.

As the alkylene carbonate, propylene carbonate is preferable.

As the component (M2-1), propylene glycol monomethyl ether (PGME), ethyl lactate, ethyl 3-ethoxypropionate, methyl amyl ketone, cyclohexanone, butyl acetate, pentyl acetate, γ-butyrolactone, or propylene carbonate is more preferable.

Specific examples of the component (M2-2) include propylene glycol monomethyl ether (fp: 47° C.), ethyl lactate (fp: 53° C.), ethyl 3-ethoxypropionate (fp: 49° C.), methyl amyl ketone (fp: 42° C.), cyclohexanone (fp: 44° C.), pentyl acetate (fp: 45° C.), methyl2-hydroxyisobutyrate (fp: 45° C.), γ-butyrolactone (fp: 101° C.), and propylene carbonate (fp: 132° C.). Among those, propylene glycol monoethyl ether, ethyl lactate, pentyl acetate, or cyclohexanone is preferable, and propylene glycol monoethyl ether or ethyl lactate is more preferable.

In addition, the “flash point” herein means the value described in a reagent catalog of Tokyo Chemical Industry Co., Ltd. or Sigma-Aldrich Co. LLC.

The mixing ratio (mass ratio: M1/M2) of the component (M1) to the component (M2) is preferably in the range of “100/0” to “15/85”, more preferably in the range of “100/0” to “40/60”, and still more preferably in the range of “100/0” to “60/40”, from the viewpoint that the number of development defects is further decreased.

Moreover, the solvent may include components other than the component (M1) and the component (M2). In this case, the content of the components other than the components (M1) and (M2) is preferably 5% to 30% by mass with respect to the total mass of the solvent.

Examples of such other solvents include ester-based solvents having 7 or more carbon atoms (preferably 7 to 14 carbon atoms, more preferably 7 to 12 carbon atoms, and still more preferably 7 to 10 carbon atoms) and 2 or less heteroatoms. Furthermore, the ester-based solvents having 7 or more carbon atoms and 2 or less heteroatoms do not include solvents corresponding to the above-mentioned component (M2).

As the ester-based solvents having 7 or more carbon atoms and 2 or less heteroatoms, amyl acetate, 2-methylbutyl acetate, 1-methylbutyl acetate, hexyl acetate, pentyl propionate, hexyl propionate, butyl propionate, isobutyl isobutyrate, heptyl propionate, butyl butanoate, or the like is preferable, and isoamyl acetate is more preferable.

<Other Additives>

The composition of the embodiment of the present invention may further include a dissolution inhibiting compound (a compound whose solubility in an organic developer decreases through decomposition by the action of an acid, with a molecular weight thereof being preferably 3,000 or less), a dye, a plasticizer, a light sensitizer, a light absorber, and/or a compound that accelerates dissolution in a developer (for example, a phenol compound having a molecular weight of 1,000 or less, or an alicyclic or aliphatic compound including a carboxy group).

<Preparation Method>

The concentration of the solid content in the composition of the embodiment of the present invention is preferably 0.5% to 30%/o by mass, more preferably 1% to 20% by mass, and still more preferably 1% to 10% by mass, from the viewpoint that the coatability is more excellent. The concentration of the solid content is a mass percentage of other resist components excluding the solvent with respect to the total mass of the composition.

In addition, the film thickness of a resist film (an actinic ray-sensitive or radiation-sensitive film) formed of the composition of the embodiment of the present invention is generally 200 nm or less, and more preferably 100 nm or less, from the viewpoint of improving resolving power. For example, it is preferable that the film thickness of a resist film thus formed is 80 nm or less in order to resolve a 1:1 line-and-space pattern with a line width of 20 nm or less. In a case where the film thickness is 80 nm or less, more excellent resolution performance is obtained due to suppressed pattern collapse upon application of a developing step which will be described later.

A more preferred range of the film thickness is from 15 to 60 nm. Such a film thickness can be obtained by setting to the concentration of the solid content in the composition to an appropriate range to provide the composition with a suitable viscosity and improve the coatability or film forming properties.

The composition of the embodiment of the present invention is used by dissolving the components in a predetermined organic solvent (preferably the mixed solvent), and preferably the mixed solvent, and filtering the solution through a filter and applying it onto a predetermined support (substrate). The pore size of a filter for use in filtration through the filter is preferably pore size of 0.1 μm or less, more preferably 0.05 μm or less, and still more preferably 0.03 μm or less. The filter is preferably a polytetrafluoroethylene-made, polyethylene-made, or nylon-made filter. In the filtration through a filter as shown in JP2002-062667A, circulating filtration may be performed or the filtration may be performed by connecting plural kinds of filters in series or in parallel. In addition, the composition may be filtered in plural times. Furthermore, the composition may be subjected to a deaeration treatment or the like before or after filtration through a filter.

<Applications>

The composition of the embodiment of the present invention relates to an actinic ray-sensitive or radiation-sensitive resin composition whose properties change by undergoing a reaction upon irradiation with actinic rays or radiation. More specifically, the composition of the embodiment of the present invention relates to an actinic ray-sensitive or radiation-sensitive resin composition which is used in a step of manufacturing a semiconductor such as an integrated circuit (IC), for manufacture of a circuit board for a liquid crystal, a thermal head, or the like, the manufacture of a mold structure for imprinting, other photofabrication steps, or production of a planographic printing plate or an acid-curable composition. A pattern formed in the present invention can be used in an etching step, an ion implantation step, a bump electrode forming step, a rewiring forming step, a microelectromechanical system (MEMS), or the like.

[Pattern Forming Method]

The present invention also relates to a pattern forming method using the actinic ray-sensitive or radiation-sensitive resin composition. Hereinafter, the pattern forming method of the embodiment of the present invention will be described. Further, the resist film of the embodiment of present invention will also be described, together with the pattern forming method.

The pattern forming method of an embodiment of the present invention includes:

(i) a step of forming a resist film (actinic ray-sensitive or radiation-sensitive film) on a support with the above-mentioned actinic ray-sensitive or radiation-sensitive resin composition (resist film forming step),

(ii) a step of exposing the resist film (irradiating actinic rays or radiation) (exposing step), and

(iii) a step of developing the exposed resist film with a developer (developing step).

The pattern forming method of the embodiment of the present invention is not particularly limited as long as it includes the steps (i) to (iii), and may further include the following steps.

In the pattern forming method of the embodiment of the present invention, the exposing method in the exposing step (ii) may be liquid immersion exposure.

The pattern forming method of the embodiment of the present invention preferably includes a prebaking (PB) step (iv) before the exposing step (ii).

The pattern forming method of the embodiment of the present invention preferably includes a post-exposure baking (PEB) step (v) after the exposing step (ii) and before the developing step (iii).

The pattern forming method of the embodiment of the present invention may include the exposing step (ii) a plurality of times.

The pattern forming method of the embodiment of the present invention may include the prebaking heating step (iv) a plurality of times.

The pattern forming method of the embodiment of the present invention may include the post-exposure baking step (v) a plurality of times.

In the pattern forming method of the embodiment of the present invention, the above-mentioned film forming step (i), exposing step (ii), and developing step (iii) can be performed by a generally known method.

In addition, a resist underlayer film (for example, spin on glass (SOG), spin on carbon (SOC), and an antireflection film) may be formed between the resist film and the support, as desired. As a material constituting the resist underlayer film, known organic or inorganic materials can be appropriately used.

A protective film (topcoat) may be formed on the upper layer of the resist film. As the protective film, a known material can be appropriately used. For example, the compositions for forming a protective film disclosed in US2007/0178407A, US2008/0085466A, US2007/0275326A, US2016/0299432A, US2013/0244438A. or the specification of WO2016/157988A can be suitably used. The composition for forming a protective film preferably includes the above-mentioned acid diffusion control agent.

The film thickness of the protective film is preferably 10 to 200 nm, more preferably 20 to 100 nm, and still more preferably 40 to 80 nm.

The support is not particularly limited, and a substrate which is generally used in a step of manufacturing a semiconductor such as an IC, and a process for manufacturing a circuit board for a liquid crystal, a thermal head, or the like, and other lithographic processes of photofabrication can be used. Specific examples of the support include an inorganic substrate such as silicone, SiO₂, and SiN.

For any of the prebaking step (iv) and the post-exposure baking step (v), the heating temperature is preferably 80° C. to 150° C., more preferably 80° C. to 140° C., and still more preferably 80° C. to 130° C.

For any of the prebaking step (iv) and the post-exposure baking step (v), the heating time is preferably 30 to 1,000 seconds, more preferably 60 to 800 seconds, and still more preferably 60 to 600 seconds.

Heating may be performed using a means comprised in an exposure device and a development device, or may also be performed using a hot plate or the like.

A light source wavelength used in the exposing step is not particularly limited, and examples thereof include infrared rays, visible light, ultraviolet rays, far ultraviolet rays, extreme ultraviolet rays (EUV), X-rays, and electron beams. Among those, far ultraviolet rays are preferable, whose wavelength is preferably 250 nm or less, more preferably 220 nm or less, and still more preferably 1 to 200 nm. Specific examples thereof include a KrF excimer laser (248 nm), an ArF excimer laser (193 nm), an F_{z} excimer laser (157 nm), X-rays, EUV (13 nm), and electron beams, the KrF excimer laser, the ArF excimer laser, EUV, or the electron beams are preferable, and EUV or the electron beams are more preferable.

In the developing step (iii), the developer may be either an alkali developer or a developer including an organic solvent (hereinafter also referred to as an organic developer), but the alkali development is preferable.

As an alkali component included in the alkali developer, a quaternary ammonium salt typified by tetramethylammonium hydroxide is usually used. In addition, an aqueous alkali solution including an alkali component such as an inorganic alkali, primary to tertiary amines, alcohol amines, and cyclic amines can also be used.

Furthermore, the alkali developer may include an appropriate amount of alcohols and/or a surfactant. The alkali concentration of the alkali developer is usually 0.1% to 20% by mass. The pH of the alkali developer is usually 10 to 15.

The time for performing the using the alkali developer is usually 10 to 300 seconds.

The alkali concentration, the pH, and the development time using the alkali developer can be appropriately adjusted depending on a pattern formed.

The organic developer is preferably a developer including at least one organic solvent selected from the group consisting of a ketone-based solvent, an ester-based solvent, an alcohol-based solvent, an amide-based solvent, an ether-based solvent, and a hydrocarbon-based solvent.

Examples of the ketone-based solvent include 1-octanone, 2-octanone, 1-nonanone, 2-nonanone, acetone, 2-heptanone (methyl amyl ketone), 4-heptanone, 1-hexanone, 2-hexanone, diisobutyl ketone, cyclohexanone, methylcyclohexanone, phenyl acetone, methyl ethyl ketone, methyl isobutyl ketone, acetyl acetone, acetonyl acetone, ionone, diacetonyl alcohol, acetyl carbinol, acetophenone, methyl naphthyl ketone, isophorone, and propylene carbonate.

Examples of the ester-based solvent include methyl acetate, butyl acetate, ethyl acetate, isopropyl acetate, pentyl acetate, isopentyl acetate, amyl acetate, propylene glycol monomethyl ether acetate, ethylene glycol monoethyl ether acetate, diethylene glycol monobutyl ether acetate, diethylene glycol monoethyl ether acetate, ethyl-3-ethoxypropionate, 3-methoxybutyl acetate, 3-methyl-3-methoxybutyl acetate, methyl formate, ethyl formate, butyl formate, propyl formate, ethyl lactate, butyl lactate, propyl lactate, butyl butanoate, methyl 2-hydroxyisobutyrate, isoamyl acetate, isobutyl isobutyrate, and butyl propionate.

As the alcohol-based solvent, the amide-based solvent, the ether-based solvent, and the hydrocarbon-based solvent, the solvents disclosed in paragraphs <0715> to <0718> of US2016/0070167A1 can be used.

A plurality of the solvents may be mixed or the solvent may be used in admixture with a solvent other than those described above or water. The moisture content in the entire developer is preferably less than 50% by mass, more preferably less than 20% by mass, and still more preferably less than 10% by mass, and particularly preferably, moisture is not substantially included.

The content of the organic solvent with respect to the organic developer is preferably 50% to 100% by mass, more preferably 80% to 100% by mass, still more preferably 90% to 100% by mass, and particularly preferably 95% to 100% by mass, with respect to the total amount of the developer.

The organic developer may include an appropriate amount of a known surfactant, as desired.

The content of the surfactant is usually 0.001% to 5% by mass, preferably 0.005% to 2% by mass, and still more preferably 0.01% to 0.5% by mass, with respect to the total amount of the developer.

The organic developer may include the above-mentioned acid diffusion control agent.

Examples of the developing method include a method in which a substrate is immersed in a tank filled with a developer for a certain period of time (a dip method), a method in which development is performed by heaping a developer up onto the surface of a substrate by surface tension, and then leaving it to stand for a certain period of time (a puddle method), a method in which a developer is sprayed on the surface of a substrate (a spray method), and a method in which a developer is continuously discharged onto a substrate spun at a constant rate while scanning a developer discharging nozzle at a constant rate (a dynamic dispense method).

A combination of a step of performing development using an aqueous alkali solution (an alkali developing step) and a step of performing development using a developer including an organic solvent (an organic solvent developing step) may be used. Thus, a finer pattern can be formed since a pattern can be formed by keeping only a region with an intermediate exposure intensity from not being dissolved.

It is preferable that a step of performing washing using a rinsing liquid (a rinsing step) is included after the developing step (iii).

As the rinsing liquid used in the rinsing step after the step of performing development with an alkali developer, for example, pure water can be used. Pure water may include an appropriate amount of a surfactant. In this case, after the developing step or the rinsing step, a treatment for removing the developer or the rinsing liquid adhering on a pattern by a supercritical fluid may be added. In addition, after the rinsing treatment or the treatment using a supercritical fluid, a heating treatment for removing moisture remaining in the pattern may be performed.

The rinsing liquid used in the rinsing step after the step of performing development using a developer including an organic solvent is not particularly limited as long as the rinsing liquid does not dissolve the resist pattern, and a solution including a common organic solvent can be used. As the rinsing liquid, a rinsing liquid including at least one organic solvent selected from the group consisting of a hydrocarbon-based solvent, a ketone-based solvent, an ester-based solvent, an alcohol-based solvent, an amide-based solvent, and an ether-based solvent is preferably used.

Specific examples of the hydrocarbon-based solvent, the ketone-based solvent, the ester-based solvent, the alcohol-based solvent, the amide-based solvent, and the ether-based solvent include the same solvents as those described for the developer including an organic solvent.

As the rinsing liquid used in the rinsing step in this case, a rinsing liquid including a monohydric alcohol is more preferable.

Here, examples of the monohydric alcohol used in the rinsing step include linear, branched, or cyclic monohydric alcohols. Specific examples thereof include 1-butanol, 2-butanol, 3-methyl-1-butanol, tert-butyl alcohol, 1-pentanol, 2-pentanol, 1-hexanol, 4-methyl-2-pentanol, 1-heptanol, 1-octanol, 2-hexanol, cyclopentanol, 2-heptanol, 2-octanol, 3-hexanol, 3-heptanol, 3-octanol, 4-octanol, and methyl isobutyl carbinol. Examples of the monohydric alcohol having 5 or more carbon atoms include 1-hexanol, 2-hexanol, 4-methyl-2-pentanol, 1-pentanol, 3-methyl-1-butanol, and methyl isobutyl carbinol.

The respective components in plural number may be mixed or the components may be used in admixture with an organic solvent other than the above solvents.

The moisture content in the rinsing liquid is preferably 10% by mass or less, more preferably 5% by mass or less, and still more preferably 3% by mass or less. By setting the moisture content to 10% by mass or less, good development characteristics are obtained.

The rinsing liquid may include an appropriate amount of a surfactant.

In the rinsing step, the substrate that has been subjected to development using an organic developer is subjected to a washing treatment using a rinsing liquid including an organic solvent. A method for the washing treatment method is not particularly limited, but examples thereof include a method in which a rinsing liquid is continuously discharged on a substrate rotated at a constant rate (a rotation application method), a method in which a substrate is immersed in a tank filled with a rinsing liquid for a certain period of time (a dip method), and a method in which a rinsing liquid is sprayed on a substrate surface (a spray method). Among those, it is preferable that a washing treatment is carried out using the rotation application method, and a substrate is rotated at a rotation speed of 2,000 to 4,000 rpm after washing, thereby removing the rinsing liquid from the substrate. Furthermore, it is also preferable that the method includes a baking step after the rinsing step (post-baking). The developer and the rinsing liquid remaining between and inside the patterns are removed by the baking step. In the heating step after the rinsing step, the heating temperature is usually 40° C. to 160° C., and preferably 70° C. to 95° C., and typically for 10 seconds to 3 minutes, and preferably for 30 seconds to 90 seconds.

It is preferable that various materials (for example, a resist solvent, a developer, a rinsing liquid, a composition for forming an antireflection film, and a composition for forming a topcoat) used in the actinic ray-sensitive or radiation-sensitive resin composition of the embodiment of the present invention, and the pattern forming method of the embodiment of the present invention do not include impurities such as metals. The content of the impurities included in these materials is preferably 1 ppm or less, more preferably 100 ppt or less, and still more preferably 10 ppt or less, and particularly preferably, the impurities are not substantially included (no higher than a detection limit of a measurement device).

Examples of a method for removing impurities such as metals from the various materials include filtration using a filter. As for the filter pore diameter, the pore size is preferably 10 nm or less, more preferably 5 nm or less, and still more preferably 3 nm or less. As for the materials of a filter, a polytetrafluoroethylene-made filter, a polyethylene-made filter, and a nylon-made filter are preferable. As the filter, a filter which had been washed with an organic solvent in advance may be used. In the step of filtration using a filter, plural kinds of filters connected in series or in parallel may be used. In a case of using the plural kinds of filters, a combination of filters having different pore diameters and/or materials may be used. In addition, various materials may be filtered plural times, and the step of filtering plural times may be a circulatory filtration step. As the filter, a filter having a reduced amount of elutes as disclosed in JP2016-201426A is preferable.

In addition to the filtration using a filter, removal of impurities by an adsorbing material may be performed, or a combination of filtration using a filter and an adsorbing material may be used. As the adsorbing material, known adsorbing materials can be used, and for example, inorganic adsorbing materials such as silica gel and zeolite, and organic adsorbing materials such as activated carbon can be used. Examples of the metal adsorbing agent include those disclosed in JP2016-206500A.

In addition, as a method for reducing the impurities such as metals included in various materials, metal content selects the less material as a raw material constituting the various materials, performing filtering using a filter of the raw material constituting the various materials, equipment the inner and a method such as performing distillation under conditions suppressing as much as possible equal to contamination is lined with TEFLON (registered trademark). Preferred conditions in the filtering using a filter to be performed on the raw material constituting the various materials are similar to the above-mentioned conditions.

In order to prevent impurities from being incorporated, it is preferable that various materials are stored in the container described in US2015/0227049A, JP2015-123351A, or the like.

A method for improving the surface roughness of a pattern may be applied to a pattern formed by the pattern forming method of the embodiment of the present invention. Examples of the method for improving the surface roughness of a pattern include the method of treating a pattern by plasma of a hydrogen-containing gas disclosed in US2015/0104957A. In addition, known methods as described in JP2004-235468A, US2010/0020297A, and Proc. of SPIE Vol. 832883280N-1 “EIUV Resist Curing Technique for LWR Reduction and Etch Selectivity Enhancement” may be applied.

In addition, a pattern formed by the method can be used as a core material (core) of the spacer process disclosed in, for example, JP1991-270227A (JP-H03-270227A) and US2013/0209941A.

[Method for Manufacturing Electronic Device]

Moreover, the present invention further relates to a method for manufacturing an electronic device, the method including the above-described pattern forming method. The electronic device manufactured by the method for manufacturing an electronic device of an embodiment of the present invention is suitably mounted on electric or electronic equipment (for example, home electronics, office automation (OA)-related equipment, media-related equipment, optical equipment, and telecommunication equipment).

### EXAMPLES

Hereinbelow, the present invention will be described in more detail with reference to Examples. The materials, the amounts of materials used, the proportions, the treatment details, the treatment procedure, and the like shown in the Examples below may be modified as appropriate as long as the modifications do not depart from the spirit of the present invention. Therefore, the scope of the present invention should not be construed as being limited to the Examples set forth below.

[Resin]

The respective repeating units in resins P-1 to P-29 shown in Table 1 are set forth below.

Moreover, in the respective repeating units set forth below, MA-3, MB-3, MB-4, MC-1, MC-3, MC-6, MC-7, and MC-8 each correspond to a repeating unit represented by General Formula (B-2).

Furthermore, MC-3 corresponds to a repeating unit (A), MB-3 and MB-4 each correspond to a repeating unit (B), and MA-3 corresponds to the above-mentioned repeating unit (C).

In addition, MA-3, MB-3, MB-4, MC-1, MC-3, and MC-6 each have a fluorine content of 10% by mass or more.

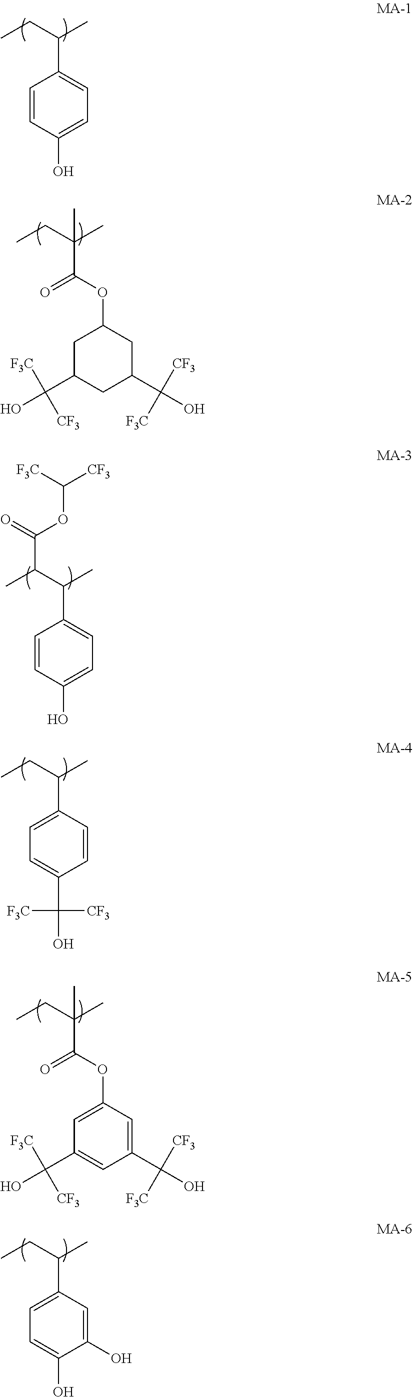

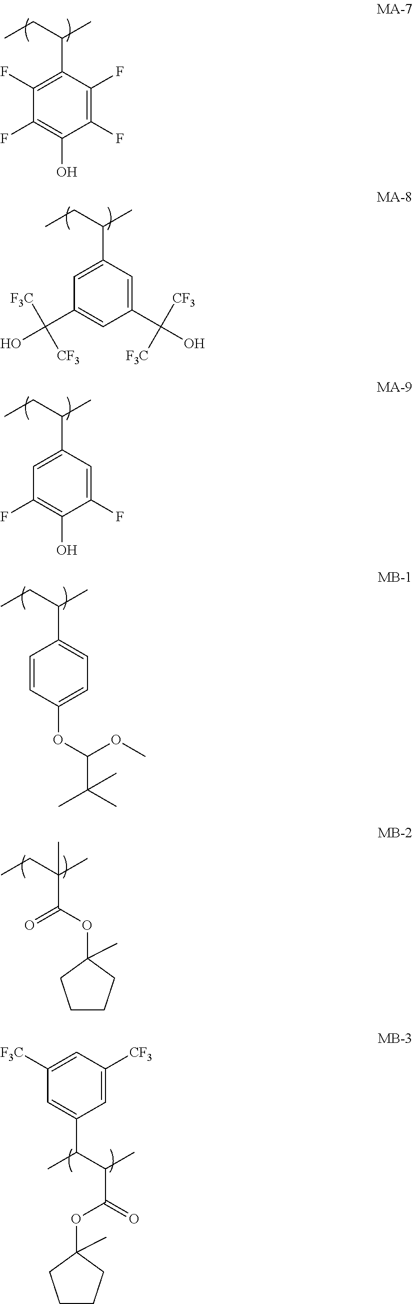

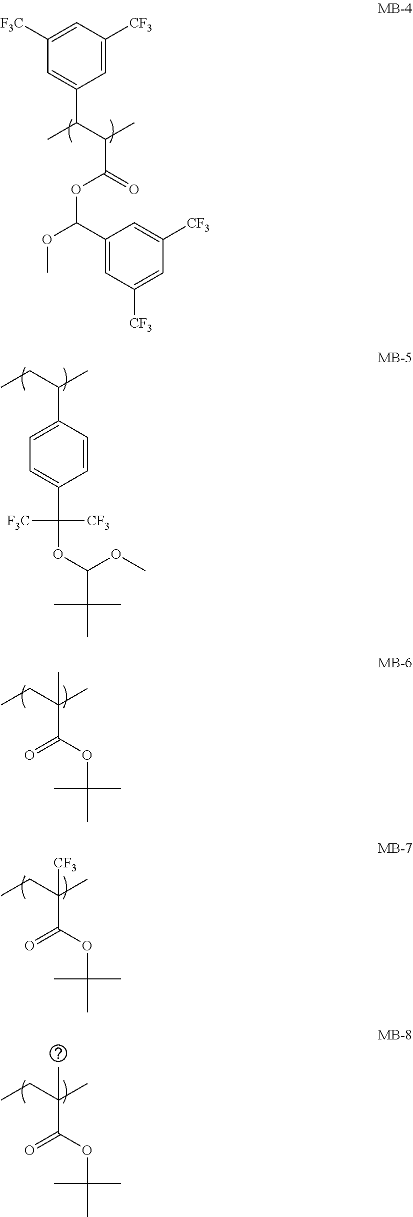

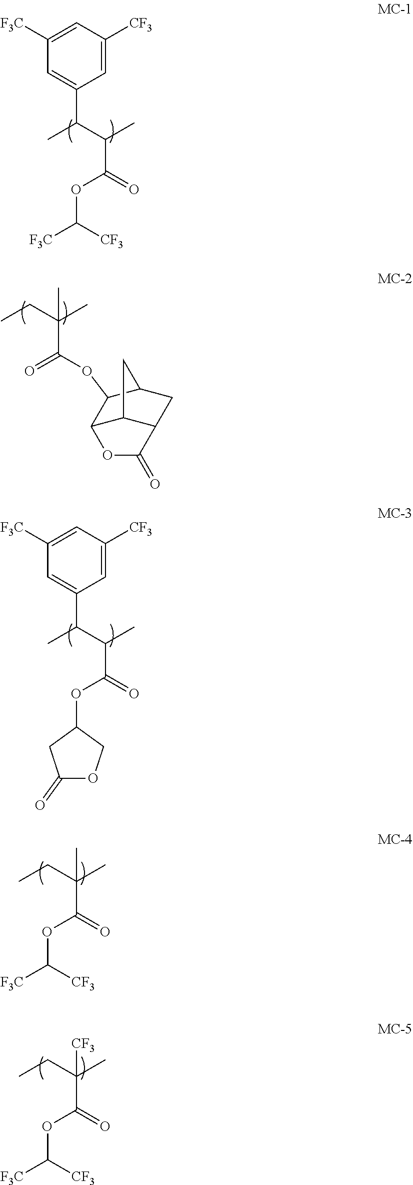

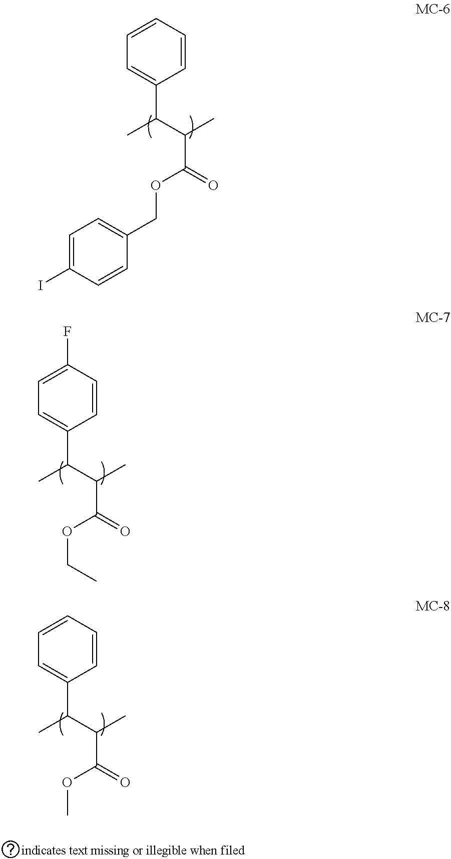

### Synthesis Example: Raw Material Monomer of Repeating Unit Represented by General Formula (B-1

In the repeating unit, Synthesis Examples for monomers serving as raw materials for the repeating unit represented by General Formula (B-1) are set forth.

Furthermore, ethyl 4-fluorocinnamate (manufactured by Tokyo Chemical Industry Co., Ltd.) was used as the monomer MC-7 and methyl cinnamate (manufactured by Tokyo Chemical Industry Co., Ltd.) was used as the monomer MC-8.

### Synthesis Example: Synthesis of Monomer MC-1

Under a nitrogen stream, 3,5-bis(trifluoromethyl)benzaldehyde (manufactured by Tokyo Chemical Industry Co., Ltd., 48.4 g), malonic acid (manufactured by Tokyo Chemical Industry Co., Ltd., 20.8 g), and pyridine (9.49 mL) were put into a three-necked flask and stirred. Next, piperidine (1.3 mL) was added thereto and the mixture was heated at 105° C. After performing a reaction for 5 hours, the reaction solution was returned to room temperature. Next, 250 mL of 2 M aqueous hydrochloric acid was added to the reaction solution. The precipitated white crystals were filtered, washed with 250 mL of water, and then dried to obtain MC-1m (53.1 g).

Subsequently, methylene chloride (175 mL), MC-1m (34.1 g), and 2,6-di-tert-butyl-p-cresol (BHT, 0.05 mg) were put into a three-necked flask and stirred in ice water. Next, 1,1,1,3,3,3-hexafluoro-2-propanol (30.2 g) was added thereto, and 4-dimethylaminopyridine (1.5 g) was further added thereto. While stirring, 1-(3-dimethylaminopropyl)-3-ethylcarbodiimide hydrochloride (27.7 g) was added portionwise thereto and the reaction was continued. After continuing the reaction for 3 hours, a liquid separation operation was performed three times with 1 M aqueous hydrochloric acid (300 mL) and then with water (300 mL), then the organic layer was concentrated under reduced pressure, and the crystallized with hexane to obtain a white crystal (35.0 g).

### Synthesis Example: Synthesis of Monomer MA-3

A monomer MA-3 was synthesized by the same method, except that trans-p-coumaric acid was used instead of MC-1m in the synthesis of the monomer MC-1.

### Synthesis Example: Synthesis of Monomer MB-3

A monomer MB-3 was synthesized by the same method, except that 1-methylcyclopentanol was used instead of 1,1,1,3,3,3-hexafluoro-2-propanol in the synthesis of the monomer MC-1.

### Synthesis Example: Synthesis of Monomer MB-4

3,5-Bis(trifluoromethyl)benzaldehyde (manufactured by Tokyo Chemical Industry Co., Ltd., 40.0 g) and trimethyl orthoformate (manufactured by Tokyo Chemical Industry Co., Ltd., 15.8 g) were put into a three-necked flask and stirred in an ice bath. Next, (+)-10-camphorsulfonic acid (0.07 g) was added thereto and the reaction was continued for 3 hours. The reaction solution (42.9 g) was transferred to another flask and stirred at room temperature. Next, acetyl chloride (8.17 g) was added dropwise thereto at room temperature. The reaction temperature was raised to 50° C. and the reaction was continued for 3 hours to obtain MB-4m.

Under a nitrogen stream, MC-1m (31.2 g), triethylamine (11.2 g), and tetrahydrofuran (THF; 350 mL) were put into a three-necked flask and stirred under ice-water. A mixed liquid of MB-4m (29.2 g) and THF (150 mL) was added dropwise thereto for 30 minutes. Thereafter, the reaction was continued at room temperature for 1 hour. After completion of the reaction, 200 mL of ethyl acetate and 200 mL of water were added thereto and a liquid separation operation was performed three times to concentrate the organic layer. Crystallization was performed with hexane to obtain a white crystal MB-4a (35.2 g).

### Synthesis Example: Synthesis of Monomer MC-3

A monomer MC-3 was synthesized by the same method, except that 3-hydroxy-γ-butyrolactone was used instead of 1,1,1,3,3,3-hexafluoro-2-propanol in the synthesis of the monomer MC-1.

### Synthesis Example: Synthesis of Monomer MC-6

A monomer MC-6 was synthesized by the same method, except that trans-cinnamic acid (manufactured by Tokyo Chemical Industry Co., Ltd.) was used instead of MC-1m and 4-iodobenzyl alcohol (manufactured by Tokyo Chemical Industry Co., Ltd.) was used instead of 1,1,3,3,3-hexafluoro-2-propanol in the synthesis of the monomer MC-1.

Resins P-1 to P-29 shown in Table 1 were synthesized using the monomer. A method for synthesizing the resin P-1 is set forth as one example.

### Synthesis Example: Synthesis of Resin P-1

16.7 g, 10.0 g, and 6.7 g of monomers corresponding to the respective repeating units (MA-1/MB-1/MC-1) of the resin P-1 in order from the left side, and a polymerization initiator V-601 (manufactured by Wako Pure Chemical Industries, Co., Ltd.) (4.61 g) were dissolved in cyclohexanone (54.6 g). A solution obtained as such was taken as a monomer solution.

Cyclohexanone (23.4 g) was put into a reaction container and the monomer solution was added dropwise into the reaction container which had been adjusted to 85° C. in the system, for 4 hours under a nitrogen gas atmosphere. The obtained reaction solution was stirred at 85° C. for 2 hours in the reaction container and then left to be cooled until the temperature reached room temperature.

The reaction solution after being left to be cooled was added dropwise to a mixed liquid of methanol and water (methanol/water=5/5 (mass ratio)) for 20 minutes and the obtained powder was collected by filtration. The obtained powder was dried to obtain the resin P-1 (21.6 g).

The compositional ratio (mass ratio) of the repeating units determined by a nuclear magnetic resonance (NMR) method was 50/30/20. In addition, the weight-average molecular weight (Mw) in terms of polystyrene as a standard and the dispersity (Mw/Mn) of the resin P-1 were 6,500 and 1.6, respectively. In addition, the weight-average molecular weight (Mw) and the dispersity (Mw/Mn) of the resin P-1 were measured by gel permeation chromatography (GPC) (carrier: tetrahydrofuran (THF)).

### Synthesis Example: Synthesis of Resins P-2 to P-29

The other resins were synthesized by the same procedure as for the resin P-1 or the procedure in the related art.

The compositional ratios (mass ratio), the weight-average molecular weights (Mw), and the dispersities (Mw/Mn) of the respective resins are shown in Table 1. The compositional ratios correspond to the respective repeating units from the left side.

TABLE 1

| | | Weight-average | |
|---|---|---|---|
| | Compositional ratio | molecular weight | Dispersity |
| Resin | (mass ratio) | (Mw) | (Mw/Ma) |
| P-1 | MA-1/MB-1/MC-1 = 50/30/20 | 6,500 | 1.6 |
| P-2 | MA-2/MB-2/MC-1 = 60/20/20 | 5,000 | 1.5 |
| P-3 | MA-2/MB-3/MC-2 = 60/20/20 | 5,500 | 1.4 |
| P-4 | MA-2/MB-1/MC-1 = 50/30/20 | 5,000 | 1.5 |
| P-5 | MA-3/MB-3/MC-3 = 60/20/20 | 5,300 | 1.5 |
| P-6 | MA-3/MB-1/MC-2 = 50/30/20 | 6,000 | 1.6 |
| P-7 | MA-2/MB-3/MC-3 = 60/20/20 | 5,500 | 1.4 |
| P-8 | MA-1/MB-1/MC-6 = 50/30/20 | 6,000 | 1.6 |
| P-9 | MA-1/MB-1/MC-1 = 50/30/20 | 3,000 | 1.5 |
| P-10 | MA-1/MB-1/MC-1 = 50/30/20 | 28,500 | 1.4 |
| P-11 | MA-1/MB-1/MC-7 = 50/30/20 | 5,500 | 1.5 |
| P-12 | MA-2/MB-3/MC-7 = 60/20/20 | 5,800 | 1.7 |
| P-13 | MA-2/MB-4/MC-3 = 50/30/20 | 6,000 | 1.5 |
| P-14 | MA-2/MB-1/MC-8 = 50/30/20 | 5,000 | 1.6 |
| P-15 | MA-4/MB-1/MC-1 = 50/30/20 | 5,500 | 1.6 |
| P-16 | MA-5/MB-1/MC-1 = 50/30/20 | 6,000 | 1.7 |
| P-17 | MA-6/MB-1/MC-1 = 40/30/30 | 5,000 | 1.6 |
| P-18 | MA-7/MB-1/MC-1 = 55/30/15 | 6,500 | 1.6 |
| P-19 | MA-8/MB-2/MC-1 = 60/30/10 | 6,000 | 1.6 |
| P-20 | MA-9/MB-1/MC-1 = 50/30/20 | 6,000 | 1.6 |
| P-21 | MA-2/MB-1/MC-1 = 40/30/30 | 5,500 | 1.6 |
| P-22 | MA-2/MB-5/MC-1 = 40/30/30 | 5,300 | 1.6 |
| P-23 | MA-2/MB-6/MC-1 = 60/20/20 | 6,500 | 1.7 |
| P-24 | MA-1/MB-7/MC-1 = 55/20/25 | 5,000 | 1.8 |
| P-25 | MA-1/MB-8/MC-1 = 60/20/20 | 5,500 | 1.7 |
| P-26 | MA-1/MB-5/MC-8 = 40/30/30 | 5,000 | 1.7 |
| P-27 | MA-1/MB-1/MC-4 = 50/30/20 | 6,000 | 1.5 |
| P-28 | MA-1/MB-1/MC-5 = 50/30/20 | 5,700 | 1.6 |
| P-29 | MA-1/MB-1/MC-8 = 50/30/20 | 5,500 | 1.5 |

[Photoacid Generator]

The structures of the photoacid generator shown in Table 2 are set forth below. In addition, the cation moieties and the anion moieties of the photoacid generator are each separately set forth below.

(Cation Moieties of Photoacid Generators)

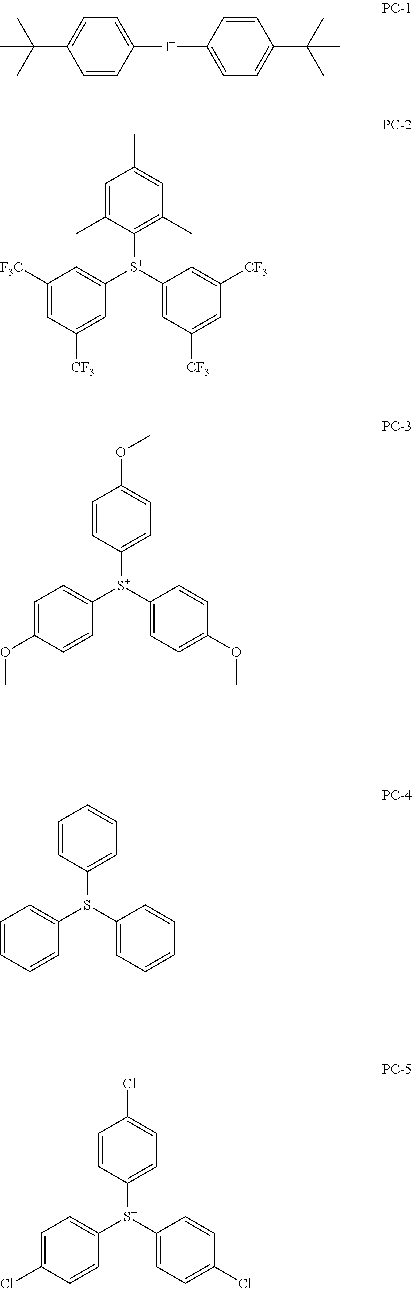 [SMILES: CC(C)(C)c1ccc([I+]c2ccc(C(C)(C)C)cc2)cc1 ; Cc1cc(C)c([S+](c2cc(C(F)(F)F)cc(C(F)(F)F)c2)c2cc(C(F)(F)F)cc(C(F)(F)F)c2)c(C)c1 ; COc1ccc([S+](c2ccc(OC)cc2)c2ccc(OC)cc2)cc1 ; c1ccc([S+](c2ccccc2)c2ccccc2)cc1 ; Clc1ccc([S+](c2ccc(Cl)cc2)c2ccc(Cl)cc2)cc1]

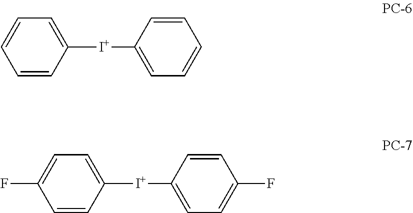 [SMILES: c1ccc([I+]c2ccccc2)cc1 ; Fc1ccc([I+]c2ccc(F)cc2)cc1]

(Anion Moieties of Photoacid Generators)

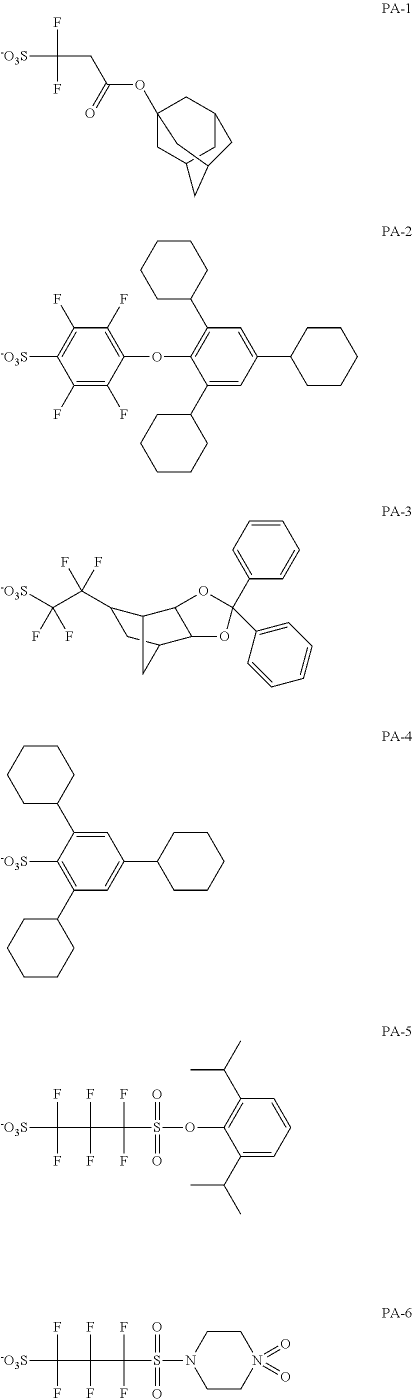

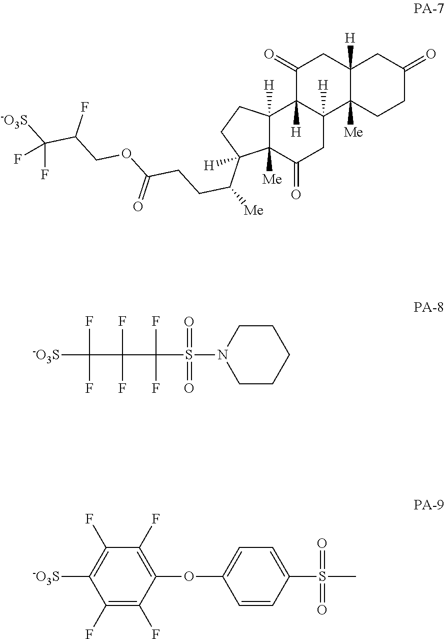

[Acid Diffusion Control Agent]

The structures of the acid diffusion control agent shown in Table 2 are set forth below.

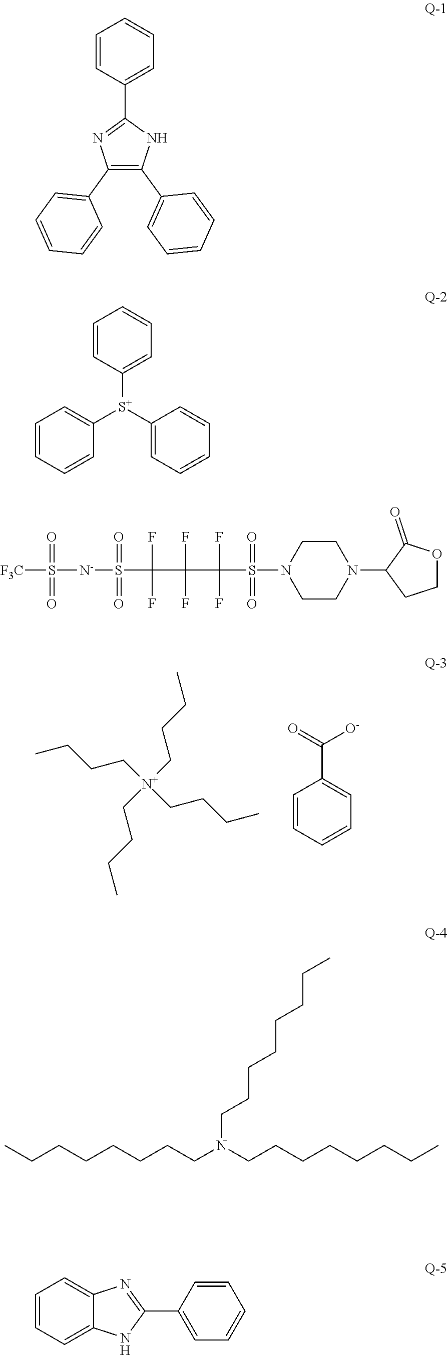

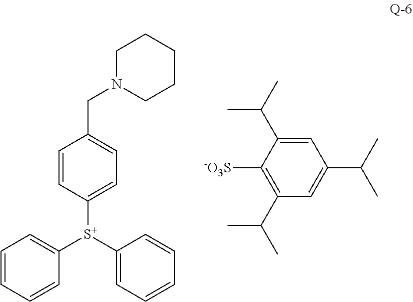

[Surfactant]

The surfactants shown in Table 2 are set forth below.

W-1: MEGAFACE F176 (manufactured by DIC Corporation; fluorine-based)

W-2: MEGAFACE R08 (manufactured by DIC Corporation; fluorine- and silicone-based)

[Solvent]

The solvents shown in Table 2 are set forth below.

SL-1: Propylene glycol monomethyl ether acetate (PGMEA)

SL-2: Propylene glycol monomethyl ether (PGME)

SL-3: Ethyl lactate

SL-4: γ-Butyrolactone

SL-5: Cyclohexanone

[Preparation of Resist Composition]

<Preparation of Actinic Ray-Sensitive or Radiation-Sensitive Resin Composition>

The respective components shown in Table 2 were mixed such that the concentration of the solid content described in Table 2 was obtained. Then, the obtained mixed liquid was filtered by a polyethylene filter having a pore size of 0.03 μm to prepare an actinic ray-sensitive or radiation-sensitive resin composition (hereinafter also referred to as a “resist composition”). In addition, in the resist composition, the solid content means all the components excluding the solvent. The obtained resist composition was used in Examples and Comparative Examples.

In addition, the contents of (% by mass) of the respective components described in the following sections of “Resin”, “Photoacid generator”, “Acid diffusion control agent”, and “Surfactant” indicate the ratios of the respective components with respect to the total solid content.

TABLE 2

| | | | Photoacid | | | Acid diffusion | | | | Concentration |
|---|---|---|---|---|---|---|---|---|---|---|
| | Resin | | generator | | | control agent | | Surfactant | | of solid |
| | | Content | | | Content | | Content | (content: | | content |
| Resist | | (% by | Cation | Anion | (% by | | (% by | % by | Solvent | (% by |
| composition | Type | mass) | moiety | moiety | mass) | Type | mass) | mass) | (mass ratio) | mass) |
| R1 | P-1 | 79.2 | PC-1 | PA-1 | 20.0 | Q-1 | 0.8 | — | SL-1/SL-2 = 80/20 | 1.5 |
| R2 | P-2 | 75.0 | PC-2 | PA-2 | 23.0 | Q-2 | 2.0 | — | SL-1/SL-2 = 80/20 | 1.6 |
| R3 | P-3 | 79.2 | PC-1 | PA-1 | 20.0 | Q-1 | 0.8 | — | SL-1/SL-2 = 80/20 | 1.3 |
| R4 | P-4 | 79.2 | PC-1 | PA-1 | 20.0 | Q-1 | 0.8 | — | SL-1/SL-2 = 80/20 | 1.2 |
| R5 | P-5 | 79.2 | PC-1 | PA-1 | 20.0 | Q-1 | 0.8 | — | SL-1/SL-2 = 80/20 | 1.4 |
| R6 | P-6 | 79.2 | PC-1 | PA-1 | 20.0 | Q-1 | 0.8 | — | SL-1/SL-2 = 80/20 | 1.4 |
| R7 | P-7 | 79.2 | PC-1 | PA-1 | 20.0 | Q-1 | 0.8 | — | SL-1/SL-2 = 80/20 | 1.5 |
| R8 | P-8 | 79.2 | PC-1 | PA-1 | 20.0 | Q-1 | 0.8 | — | SL-1/SL-2 = 80/20 | 1.7 |
| R9 | P-9 | 79.2 | PC-1 | PA-1 | 20.0 | Q-1 | 0.8 | — | SL-1/SL-2 = 80/20 | 2.1 |
| R10 | P-10 | 79.2 | PC-1 | PA-1 | 20.0 | Q-1 | 0.8 | — | SL-1/SL-2 = 80/20 | 1.5 |
| R11 | p-11 | 79.2 | PC-1 | PA-1 | 20.0 | Q-1 | 0.8 | — | SL-1/SL-2 = 80/20 | 1.5 |
| R12 | P-12 | 79.2 | PC-1 | PA-1 | 20.0 | Q-1 | 0.8 | — | SL-1/SL-2 = 80/20 | 1.6 |
| R13 | P-13 | 79.2 | PC-1 | PA-1 | 20.0 | Q-1 | 0.8 | — | SL-1/SL-2 = 80/20 | 1.9 |
| R14 | P-1 | 76.0 | PC-2 | PA-2 | 18.0 | Q-2 | 6.0 | — | SL-3/SL-4 = 95/5 | 1.5 |
| R15 | P-1 | 82.6 | PC-2 | PA-3 | 15.0 | Q-1 | 2.4 | — | SL-1/SL-4 = 90/10 | 1.6 |
| R16 | P-1 | 78.9 | PC-3 | PA-4 | 17.0 | Q-3 | 4.1 | — | SL-1/SL-2 = 70/30 | 1.7 |
| R17 | P-1 | 93.5 | PC-4 | PA-5 | 6.0 | Q-4 | 0.5 | — | SL-1/SL-3 = 80/20 | 1.5 |
| R18 | P-14 | 79.2 | PC-1 | PA-1 | 20.0 | Q-1 | 0.8 | — | SL-1/SL-3 = 60/40 | 1.5 |
| R19 | P-15 | 82.6 | PC-2 | PA-3 | 15.0 | Q-1 | 2.4 | — | SL-1/SL-2 = 60/40 | 1.6 |
| R20 | P-16 | 82.6 | PC-2 | PA-3 | 15.0 | Q-1 | 2.4 | — | SL-1/SL-2 = 90/10 | 1.4 |
| R21 | P-17 | 82.6 | PC-2 | PA-3 | 15.0 | Q-1 | 2.4 | — | SL-1/SL-2 = 80/20 | 1.8 |
| R22 | P-18 | 82.6 | PC-2 | PA-3 | 15.0 | Q-1 | 2.4 | — | SL-1/SL-2 = 80/20 | 1.7 |
| R23 | P-19 | 82.6 | PC-2 | PA-3 | 15.0 | Q-1 | 2.4 | — | SL-1/SL-2 = 80/20 | 1.6 |
| R24 | P-20 | 82.6 | PC-2 | PA-3 | 15.0 | Q-1 | 2.4 | — | SL-1/SL-2 = 80/20 | 2.0 |
| R25 | P-21 | 82.6 | PC-2 | PA-3 | 15.0 | Q-1 | 2.4 | — | SL-3/SL-5 = 80/20 | 1.8 |
| R26 | P-22 | 76.0 | PC-2 | PA-2 | 18.0 | Q-2 | 6.0 | — | SL-3/SL-4 = 95/5 | 1.7 |
| R27 | P-23 | 79.2 | PC-1 | PA-1 | 20.0 | Q-1 | 0.8 | — | SL-1/SL-2 = 80/20 | 1.5 |
| R28 | P-24 | 76.0 | PC-2 | PA-2 | 18.0 | Q-2 | 6.0 | — | SL-3/SL-4 = 95/5 | 1.6 |
| R29 | P-25 | 76.0 | PC-2 | PA-2 | 18.0 | Q-2 | 6.0 | — | SL-3/SL-4 = 95/5 | 2.2 |
| R30 | P-26 | 79.2 | PC-1 | PA-1 | 20.0 | Q-1 | 0.8 | — | SL-1/SL-2 = 80/20 | 2.1 |
| R31 | P-21 | 82.6 | PC-4 | PA-6 | 15.0 | Q-1 | 2.4 | — | SL-1/SL-2 = 80/20 | 1.7 |
| R32 | P-21 | 82.6 | PC-5 | PA-2 | 15.0 | Q-2 | 2.4 | — | SL-1/SL-2 = 80/20 | 1.9 |
| R33 | P-21 | 30.0 | PC-6 | PA-3 | 16.5 | Q-1 | 3.5 | — | SL-1/SL-2 = 80/20 | 1.8 |
| R34 | P-21 | 79.8 | PC-7 | PA-2 | 18.3 | Q-3 | 1.9 | — | SL-1/SL-2 = 80/20 | 2.1 |
| R35 | P-21 | 82.6 | PC-3 | PA-7 | 15.0 | Q-1 | 2.4 | — | SL-1/SL-2 = 80/20 | 1.0 |
| R36 | P-21 | 82.6 | PC-2 | PA-3 | 15.0 | Q-4 | 2.4 | — | SL-1/SL-2 = 80/20 | 1.8 |
| R37 | P-21 | 82.6 | PC-3 | PA-9 | 15.0 | Q-1 | 2.4 | — | SL-1/SL-2 = 80/20 | 1.7 |
| R38 | P-21 | 82.6 | PC-2 | PA-3 | 15.0 | Q-5 | 2.4 | — | SL-1/SL-2 = 80/20 | 2.2 |
| R39 | P-21 | 82.6 | PC-3 | PA-4 | 15.0 | Q-6 | 2.4 | — | SL-1/SL-2 = 80/20 | 2.0 |
| R40 | P-21 | 78.6 | PC-3 | PA-4 | 17.0 | Q-3 | 4.1 | W-1 (0.3) | SL-3 = 100 | 1.8 |
| R41 | P-21 | 78.4 | PC-3 | PA-4 | 17.0 | Q-3 | 4.1 | W-2 (0.5) | SL-1/SL-3 = 80/20 | 1.7 |
| R42 | P-27 | 79.2 | PC-1 | PA-1 | 20.0 | Q-1 | 0.8 | — | SL-1/SL-2 = 80/20 | 1.8 |
| R43 | P-28 | 79.2 | PC-1 | PA-1 | 20.0 | Q-1 | 0.8 | — | SL-1/SL-2 = 80/20 | 1.9 |
| R44 | P-29 | 79.2 | PC-1 | PA-1 | 20.0 | Q-1 | 0.8 | — | SL-1/SL-2 = 80/20 | 1.9 |
| R45 | P-27 | 76.0 | PC-2 | PA-2 | 18.0 | Q-2 | 6.0 | — | SL-1/SL-2 = 80/20 | 1.7 |

[Pattern Formation and Evaluation]

The underlayer films, the developers, and the rinsing liquids shown in Table 3 are set forth below.

<Developer and Rinsing Liquid>

D-1: 3.00%-by-mass Aqueous tetramethylammonium hydroxide solution

D-2: 2.38%-by-mass Aqueous tetramethylammonium hydroxide solution

D-3: 1.50%-by-mass Aqueous tetramethylammonium hydroxide solution

D-4: 1.00%-by-mass Aqueous tetramethylammonium hydroxide solution

D-5: 0.80%-by-mass Aqueous tetramethylammonium hydroxide solution

D-6: Pure water

D-7: FIRM Extreme 10 (manufactured by AZEM)

<Underlayer Film>

UL-1: AL412 (manufactured by Brewer Science Inc.)

UL-2: SHB-A940 (manufactured by Shin-Etsu Chemical Co., Ltd.)

<EUV Exposure>

A composition described in Table 3 was applied onto a silicon wafer (12 inches) having an underlayer film described in able 3 formed thereon, and the coating film was heated under the pre-baking (PB) condition described in (Condition for application of resist) to form a resist film having a film thickness described in Table 3, with which a silicon wafer having the resist film was obtained.

The silicon wafer having the obtained resist film was subjected to pattern irradiation using an EUV exposure device (manufactured by Exitech Ltd., Micro Exposure Tool, NA 0.3, Quadrupole, an outer sigma of 0.68, and an inner sigma of 0.36). Further, a mask with a line size=20 nm and a line:space=1:1 was used as a reticle.

Thereafter, the silicon wafer was post-exposure baked (PEB) under the condition shown in Table 3 below, then puddle-developed for 30 seconds using a developer shown in Table 3 below, and puddle-rinsed with a rinsing liquid shown in Table 3 below, and then the silicon wafer was rotated at a rotation speed of 4,000 rpm for 30 seconds and further baked at 90° C. for 60 seconds to obtain a line-and-space pattern with a pitch of 40 nm and a line width of 20 nm (a space width of 20 nm). The results are summarized in Table 3.

<Various Evaluations>

The resist pattern formed above was subjected to evaluations shown below.

(Sensitivity)

While changing an exposure dose, the line width of the line-and-space pattern was measured, and the exposure dose at which the line width reached 20 nm was determined and taken as a sensitivity (mJ/cm²). A smaller value thereof indicates a resist having a higher sensitivity and better performance.

The evaluation was performed in accordance with the following standard.

“A”: Sensitivity≤40 mJ/cm²

“B”: 40 mJ/cm²<Sensitivity≤50 mJ/cm²

“C”: 50 mJ/cm²<Sensitivity≤60 mJ/cm²

“D”: 60 mJ/cm²<Sensitivity

(LER)

With regard to the observation of the line-and-space pattern resolved at an optimal exposure dose, the pattern was observed from an upper part thereof using a critical dimension scanning electron microscope (SEM: CG-4100 manufactured by Hitachi High Technologies Corporation), and at this time, a distance from a center of the pattern to the edge was measured at any points and a measurement deviation thereof was evaluated as 3σ. A value thereof indicates better performance.

The evaluation was performed in accordance with the following standard.

“A”: LER≤2.5 nm

“B”: 2.5≤LER<3.0 nm

“C”: LER≥3.0 nm

(Collapse Suppressing Capability (Pattern Collapse Suppressing Capability))

While changing an exposure dose, the line width of the line-and-space pattern was measured. Here, a minimum line width with which the pattern was resolved without collapse over 10 μm² was defined as a collapse line width. A smaller value thereof indicates a wider margin of the pattern collapse and better performance.

The evaluation was performed in accordance with the following standard.

“A”: Line width≤13 nm

“B”: 13 nm<Line width≤17 nm

“C”: 17 nm<Line width≤20 nm

“D”: 20 nm<Line width

TABLE 3

| | | Condition for | | | | | | | | |
|---|---|---|---|---|---|---|---|---|---|---|
| | | application of resist | | | | | | Evaluation results | | |
| | Underlayer | | film | | | | Rinsing | | | Collapse |
| | film | | thickness | | PEB | Developer | liquid | Sensitivity | LER | performance |
| | Type | Composition | (nm) | PB | PEB | Type | Type | (mJ/cm²) | (nm) | (nm) |
| Example 1 | UL-1 | R1 | 30 | 100° C./60 sec | 120° C./60 sec | D-2 | D-6 | B | A | B |
| Example 2 | UL-1 | R2 | 35 | 100° C./60 sec | 120° C./60 sec | D-2 | D-6 | A | A | B |
| Example 3 | UL-1 | R3 | 25 | 100° C./60 sec | 120° C./60 sec | D-1 | D-6 | A | A | B |
| Example 4 | UL-1 | R4 | 30 | 100° C./60 sec | 120° C./60 sec | D-2 | D-7 | A | A | B |
| Example 5 | UL-1 | R5 | 35 | 100° C./60 sec | 120° C./60 sec | D-4 | D-6 | A | A | A |
| Example 6 | UL-2 | R6 | 30 | 100° C./60 sec | 120° C./60 sec | D-2 | D-6 | B | A | B |
| Example 7 | UL-1 | R7 | 35 | 100° C./60 sec | 120° C./60 sec | D-3 | D-7 | A | A | B |
| Example 8 | UL-1 | R8 | 30 | 100° C./60 sec | 120° C./60 sec | D-1 | D-6 | C | A | B |
| Example 9 | UL-1 | R9 | 35 | 100° C./60 sec | 120° C./60 sec | D-2 | D-6 | B | A | C |
| Example 10 | UL-1 | R10 | 35 | 100° C./60 sec | 120° C./60 sec | D-2 | D-6 | B | B | B |
| Example 11 | UL-1 | R11 | 30 | 100° C./60 sec | 120° C./60 sec | D-2 | D-6 | C | A | B |
| Example 12 | UL-1 | R12 | 35 | 100° C./60 sec | 120° C./60 sec | D-3 | D-6 | A | A | B |
| Example 13 | UL-1 | R13 | 30 | 100° C./60 sec | 120° C./60 sec | D-2 | D-7 | A | A | B |
| Example 14 | UL-2 | R14 | 30 | 100° C./60 sec | 120° C./60 sec | D-5 | D-6 | B | A | B |
| Example 15 | UL-1 | R15 | 30 | 100° C./60 sec | 120° C./60 sec | D-2 | D-6 | B | A | B |
| Example 16 | UL-1 | R16 | 35 | 100° C./60 see | 120° C./60 sec | D-2 | D-6 | B | A | B |
| Example 17 | UL-2 | R17 | 30 | 100° C./60 sec | 120° C./60 sec | D-2 | D-6 | B | A | B |
| Example 18 | UL-1 | R1 | 35 | 100° C./60 sec | 120° C./60 sec | D-2 | D-6 | B | A | B |
| Example 19 | UL-1 | R5 | 30 | 120° C./60 sec | 105° C./60 sec | D-2 | D-6 | A | A | B |
| Example 20 | UL-1 | R1 | 30 | 120° C./60 sec | 105° C./60 sec | D-2 | D-6 | B | A | B |
| Example 21 | UL-1 | R18 | 35 | 100° C./60 sec | 105° C./60 sec | D-2 | D-6 | B | A | B |
| Example 22 | UL-1 | R19 | 35 | 100° C./60 sec | 120° C./60 sec | D-2 | D-6 | A | A | B |
| Example 23 | UL-1 | R20 | 35 | 100° C./60 sec | 120° C./60 sec | D-2 | D-7 | A | A | B |
| Example 24 | UL-1 | R21 | 35 | 100° C./60 sec | 120° C./60 sec | D-2 | D-6 | B | A | B |
| Example 25 | UL-1 | R22 | 35 | 100° C./60 sec | 120° C./60 sec | D-2 | D-6 | A | A | B |
| Example 26 | UL-1 | R23 | 35 | 100° C./60 sec | 120° C./60 sec | D-2 | D-6 | A | A | B |
| Example 27 | UL-1 | R24 | 35 | 100° C./60 sec | 120° C./60 sec | D-2 | D-6 | A | A | B |
| Example 28 | UL-1 | R25 | 35 | 100° C./60 sec | 120° C./60 sec | D-2 | D-6 | A | A | B |
| Example 29 | UL-1 | R26 | 35 | 100° C./60 sec | 120° C./60 sec | D-2 | D-6 | A | A | B |
| Example 30 | UL-1 | R27 | 35 | 100° C./60 sec | 120° C./60 sec | D-2 | D-6 | A | A | B |
| Example 31 | UL-1 | R28 | 35 | 100° C./60 sec | 120° C./60 sec | D-2 | D-7 | B | A | B |
| Example 32 | UL-1 | R29 | 35 | 100° C./60 sec | 120° C./60 sec | D-2 | D-6 | B | A | B |
| Example 33 | UL-1 | R30 | 35 | 100° C./60 sec | 120° C./60 sec | D-2 | D-6 | C | A | B |
| Example 34 | UL-1 | R31 | 35 | 100° C./60 sec | 120° C./60 sec | D-2 | D-6 | A | A | B |
| Example 35 | UL-1 | R32 | 35 | 100° C./60 sec | 120° C./60 sec | D-2 | D-6 | A | A | B |
| Example 36 | UL-1 | R33 | 35 | 100° C./60 sec | 120° C./60 sec | D-2 | D-6 | A | A | B |
| Example 37 | UL-1 | R34 | 35 | 100° C./60 sec | 120° C./60 sec | D-2 | D-6 | A | A | B |
| Example 38 | UL-1 | R35 | 35 | 100° C./60 sec | 120° C./60 sec | D-2 | D-6 | A | A | B |
| Example 39 | UL-1 | R36 | 35 | 100° C./60 sec | 120° C./60 sec | D-2 | D-6 | A | A | B |
| Example 40 | UL-1 | R37 | 35 | 100° C./60 sec | 120° C./60 sec | D-2 | D-6 | A | A | B |
| Example 41 | UL-1 | R38 | 35 | 100° C./60 sec | 120° C./60 sec | D-2 | D-6 | A | A | B |
| Example 42 | UL-1 | R39 | 35 | 100° C./60 sec | 120° C./60 sec | D-2 | D-6 | A | A | B |
| Example 43 | UL-1 | R40 | 35 | 100° C./60 sec | 120° C./60 sec | D-2 | D-6 | A | A | B |
| Example 44 | UL-1 | R41 | 35 | 100° C./60 sec | 120° C./60 sec | D-2 | D-6 | A | A | B |
| Comparative | UL-1 | R42 | 30 | 100° C./60 sec | 120° C./60 sec | D-2 | D-6 | B | C | D |
| Example 1 | | | | | | | | | | |
| Comparative | UL-1 | R43 | 30 | 100° C./60 sec | 120° C./60 sec | D-2 | D-6 | B | C | D |
| Example 2 | | | | | | | | | | |
| Comparative | UL-1 | R44 | 35 | 100° C./60 sec | 120° C./60 sec | D-2 | D-6 | D | A | B |
| Example 3 | | | | | | | | | | |
| Comparative | UL-1 | R45 | 35 | 100° C./60 sec | 120° C./60 sec | D-2 | D-6 | B | C | D |
| Example 4 | | | | | | | | | | |

Moreover, the same good results were obtained even in a case where the acid diffusion control agent was changed to tetramethylguanidine in Example 16.

In addition, the same good results were obtained even in a case where the acid diffusion control agent was changed to each of the following compounds in Example 16.

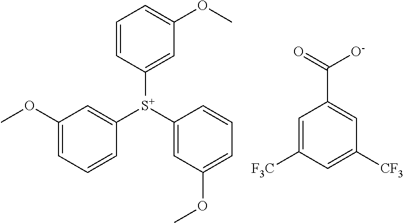

As shown in the tables, it was confirmed that in a case where the compositions of Examples were used, good performance was exhibited in the evaluation of EUV exposure. It was confirmed that in a case where the content of UV absorption element (F, 1) is larger, the performance of sensitivity is better. It is considered that such results were caused by alleviation of deterioration in the performance due to shot noise. In addition, Example 11 had a smaller content of specific halogen as compared with other Examples, and Comparative Example 3 did not include an element having high EUV light absorption, and as a result, the sensitivity was lower, as compared with other Examples. In addition, from the comparison between Example 8 and Example 1, it was confirmed that in a case where fluorine was used as an EUV absorption element, the performance of sensitivity was better.

From the results of Example 9 and Example 10, it was confirmed that in a case where the weight-average molecular weight of the resin is 3,500 to 25,000, LER and collapse suppressing capability are more excellent.

From the results of Example 21 and Example 33, it was confirmed that in a case where a specific halogen atom is introduced into an acid group, the sensitivity is more excellent, as compared with a case where the specific halogen atom is introduced into a leaving group.

From the results of Example 5, it was confirmed that in a case where the resin includes the above-mentioned repeating unit (A), the above-mentioned repeating unit (B), and the above-mentioned repeating unit (C) and the content of a specific halogen atom in these repeating units is 10% by mass or more, a pattern having a higher sensitivity and more excellent LER and collapse suppressing capability can be formed.

What is claimed is:

1. An actinic ray-sensitive or radiation-sensitive resin composition comprising:
a compound that generates an acid upon irradiation with actinic rays or radiation; and
a resin capable of increasing polarity by the action of an acid,
wherein the resin includes:
a repeating unit represented by General Formula (B-1), and
at least one halogen atom selected from the group consisting of a fluorine atom and an iodine atom, 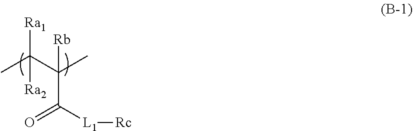
in General Formula (B-1), Ra₁ and Ra₂ each independently represent a hydrogen atom, an alkyl group, or an aryl group, provided that one of Ra₁ or Ra₂ represents a hydrogen atom, and the other represents an alkyl group or an aryl group, Rb represents a hydrogen atom or a monovalent organic group, L₁ represents a divalent linking group selected from the group consisting of —O—, and —N(R_{A})—, R_{A} represents a hydrogen atom or a monovalent organic group, and Rc represents a monovalent organic group.

2. The actinic ray-sensitive or radiation-sensitive resin composition according to claim 1,
wherein the halogen atom is included in the repeating unit represented by General Formula (B-1).

3. The actinic ray-sensitive or radiation-sensitive resin composition according to claim 1,
wherein the repeating unit represented by General Formula (B-1) is a repeating unit represented by General Formula (B-2), 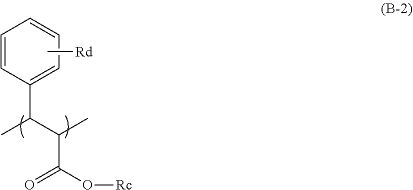
in General Formula (B-2), Rc represents a monovalent organic group, and Rd represents a hydrogen atom or a monovalent organic group.

4. The actinic ray-sensitive or radiation-sensitive resin composition according to claim 3,
wherein a content of the halogen atom in the repeating unit represented by General Formula (B-2) is 10% by mass or more.

5. The actinic ray-sensitive or radiation-sensitive resin composition according to claim 3,
wherein the repeating unit represented by General Formula (B-2) is at least one repeating unit selected from the group consisting of the following repeating unit (A), the following repeating unit (B), and the following repeating unit (C),
Repeating unit (A): Repeating unit represented by General Formula (B-2), in which Rc represents a group including a lactone structure,
Repeating unit (B): Repeating unit represented by General Formula (B-2), in which Rc represents a group that decomposes by the action of an acid to leave, and
Repeating unit (C): Repeating unit represented by General Formula (B-2), in which Rd represents an acid group.

6. The actinic ray-sensitive or radiation-sensitive resin composition according to claim 5,
wherein the resin includes at least two or more repeating units selected from the group consisting of the repeating unit (A), the repeating unit (B), and the repeating unit (C) as the repeating unit represented by General Formula (B-2).

7. The actinic ray-sensitive or radiation-sensitive resin composition according to claim 1,
wherein a weight-average molecular weight of the resin is 2,500 to 30,000.

8. A resist film formed with the actinic ray-sensitive or radiation-sensitive resin composition according to claim 1.

9. A pattern forming method comprising:
a resist film forming step of forming a resist film with the actinic ray-sensitive or radiation-sensitive resin composition according to claim 1;
an exposing step of exposing the resist film; and
a developing step of developing the exposed resist film with a developer.

10. A method for manufacturing an electronic device, the method comprising the pattern forming method according to claim 9.
